(19) United States
(12) Patent Application Publication
(10) Pub. No.: US 2022/0384446 A1
(43) Pub. Date: Dec. 1, 2022

(54) METHOD FOR MANUFACTURING MEMORY DEVICE USING SEMICONDUCTOR ELEMENT

(71) Applicant: Unisantis Electronics Singapore Pte. Ltd., Singapore (SG)

(72) Inventors: Nozomu HARADA, Tokyo (JP); Koji SAKUI, Tokyo (JP)

(21) Appl. No.: 17/840,323

(22) Filed: Jun. 14, 2022

Related U.S. Application Data
(63) Continuation-in-part of application No. 17/478,282, filed on Sep. 17, 2021.
Application No. 17/478,282 is a continuation of application No. PCT/JP2020/048952, filed on Dec. 25, 2020.

(30) Foreign Application Priority Data
Jun. 15, 2021 (JP) PCT/JP2021/022617

(51) Int. Cl. H01L 27/108

(52) U.S. Cl. CPC H01L 27/10802

(57) ABSTRACT

A first impurity layer 101a and a second impurity layer 101b are formed on a substrate Sub at both ends of a Si pillar 100 standing in a vertical direction and having a circular or rectangular horizontal cross-section. Then, a first gate insulating layer 103a and a second gate insulating layer 103b surrounding the Si pillar 100, a first gate conductor layer 104a surrounding the first gate insulating layer 103a, and a second gate conductor layer 104b surrounding the second gate insulating layer 103b are formed. Then, a voltage is applied to the first impurity layer 101a, the second impurity layer 101b, the first gate conductor layer 104a, and the second gate conductor layer 104b to generate an impact ionization phenomenon in a channel region 102 by current flowing between the first impurity layer 101a and the second impurity layer 101b. Of generated electrons and positive holes, the electrons are discharged from the channel region 102 to perform a memory write operation for holding some of the positive holes in the channel region 102, and the positive holes held in the channel region 102 are discharged from one or both of the first impurity layer 101a and the second impurity layer 101b to perform a memory erase operation.

### RELATED APPLICATIONS

The present application is a continuation-in-part application of Ser. No. 17/478,282, filed Sep. 17, 2021, which is a continuation of PCT/JP2020/048952, filed on Dec. 25, 2020. The present application also claims priority under 35 U.S.C. § 119 to PCT/JP2021/022617, filed on Jun. 15, 2021, the entire contents of which are incorporated herein by reference.

### TECHNICAL FIELD

The present invention relates to a method for manufacturing a memory device using a semiconductor element.

### BACKGROUND ART

Recent development of LSI (Large Scale Integration) technology requires high integration and high performance of memory elements.

In typical planar MOS transistors, a channel extends in a horizontal direction along an upper surface of a semiconductor substrate. In contrast, a channel of SGTs extends in a direction vertical to the upper surface of the semiconductor substrate (see, for example, PTL 1 and NPL 1). This enables the SGTs to achieve a high-density semiconductor device compared with the planar MOS transistors. Such SGTs can be used as selection transistors to implement high-integration memories such as a DRAM (Dynamic Random Access Memory, see, for example, NPL 2) to which a capacitor is connected, a PCM (Phase Change Memory, see, for example, NPL 3) to which a resistance change element is connected, an RRAM (Resistive Random Access Memory, see, for example, NPL 4), and an MRAM (Magneto-resistive Random Access Memory, see, for example, NPL 5) in which a change in magnetic spin orientation is induced by current to change resistance. Further, a capacitorless DRAM memory cell (see NPLs 6 and 7) constituted by a single MOS transistor, and the like are available. The present application relates to a method for manufacturing a dynamic flash memory that does not include a resistance change element or a capacitor and that can be constituted only by MOS transistors.

FIG. 16A to FIG. 16D illustrate a write operation of the capacitorless DRAM memory cell described above, which is constituted by a single MOS transistor, FIG. 17A and FIG. 17B illustrate a problem in the operation of the capacitorless DRAM memory cell, and FIG. 18A to FIG. 18C illustrate a read operation of the capacitorless DRAM memory cell (see NPLs 7 to 10). FIG. 16A illustrates a “1” write state. Here, the memory cell is formed on an SOI substrate 1100 and is constituted by a source N⁺ layer 1103 to which a source line SL is connected, a drain N⁺ layer 1104 to which a bit line BL is connected, a gate conductive layer 1105 to which a word line WL is connected, and a floating body 1102 of a MOS transistor 1110a; the capacitorless DRAM memory cell is constituted by the single MOS transistor 1110a. A SiO₂ layer 1101 of the SOI substrate 1100 is immediately below and in contact with the floating body 1102. To write “1” to the memory cell constituted by the single MOS transistor 1110a, the MOS transistor 111a is operated in a saturation region. That is, an electron channel 1107 extending from the source N⁺ layer 1103 has a pinch-off point 1108 and does not reach the drain N⁺ layer 1104 to which the bit line BL is connected. When the MOS transistor 1110a is operated such that the bit line BL connected to the drain N+layer 1104 and the word line WL connected to the gate conductive layer 1105 are both set to be at a high voltage and the gate voltage is set to about ½ of the drain voltage, the electric field strength is maximized at the pinch-off point 1108 near the drain N⁺ layer 1104. As a result, accelerated electrons flowing from the source N⁺ layer 1103 toward the drain N⁺ layer 1104 collide with a Si lattice, and the kinetic energy lost at this time causes generation of pairs of electrons and positive holes (impact ionization phenomenon). Most of the generated electrons (not illustrated) reach the drain N⁺ layer 1104. A very small number of electrons, which are very hot, jump over a gate oxide film 1109 and reach the gate conductive layer 1105. Positive holes 1106, which are generated at the same time, charge the floating body 1102. In this case, the generated positive holes 1106 contribute as an increment of the majority carriers because the floating body 1102 is made of P-type Si. When the floating body 1102 is filled with the generated positive holes 1106 and the voltage of the floating body 1102 becomes higher than that of the source N⁺ layer 1103 by Vb or more, the generated positive holes 1106 are further discharged to the source N⁺ layer 1103. Here, Vb is the built-in voltage across a PN junction between the source N⁺ layer 1103 and the P-layer floating body 1102 and is about 0.7 V. FIG. 16B illustrates a state in which the floating body 1102 is charged to saturation with the generated positive holes 1106.

Next, a “0” write operation of a memory cell 1110b will be described with reference to FIG. 16C. A selected word line WL is common to the memory cell 1110a for writing “1” and the memory cell 1110b for writing “0”, which are present randomly. FIG. 16C illustrates a state of rewriting from the “1” write state to a “0” write state. To write “0”, the voltage of the bit line BL is set to a negative bias, and the PN junction between the drain N⁺ layer 1104 and the P-layer floating body 1102 is forward biased. As a result, the positive holes 1106 in the floating body 1102, which are generated in advance in the previous cycle, flow into the drain N⁺ layer 1104 connected to the bit line BL. At the completion of the write operation, the following two memory cell states are obtained: the memory cell 1110a filled with the generated positive holes 1106 (FIG. 16B) and the memory cell 1110b from which the generated positive holes 1106 are injected (FIG. 16C). The floating body 1102 of the memory cell 1110a filled with the positive holes 1106 has a higher potential than the floating body 1102 having no generated positive holes. Thus, a threshold voltage of the memory cell 1110a is lower than a threshold voltage of the memory cell 1110b. This state is illustrated in FIG. 16D.

Next, a problem in the operation of the memory cell constituted by the single MOS transistor will be described with reference to FIGS. 17A and 17B. As illustrated in FIG. 17A, the floating body 1102 has a capacitance CFB, which is the sum of a capacitance C_{WL} between the gate conductive layer 1105 to which the word line WL is connected and the floating body 1102, a junction capacitance C_{SL} of the PN junction between the source N⁺ layer 1103 to which the source line SL is connected and the floating body 1102, and a junction capacitance CBL of the PN junction between the drain N⁺ layer 1104 to which the bit line BL is connected and the floating body 1102. The capacitance CFB is expressed by the following equation.

C_{FB}=C_{WL}+C_{BL}+C_{SL} (1)

Accordingly, an oscillation of a word line voltage VWL at the time of writing affects the voltage of the floating body 1102 serving as a storage node (contact) of the memory cell. This state is illustrated in FIG. 17B. In response to an increase in the word line voltage V_{WL} from 0 V to V_{ProgWL} at the time of writing, a voltage V_{FB} of the floating body 1102 increases from a voltage V_{FB}1 in the initial state before the change in the word line voltage V_{WL} to V_{FB2} due to capacitive coupling with the word line WL. The amount of voltage change ΔV_{FB} is expressed by the following equation.

$$Δ {V}_{VB} = {V}_{FB 2} - {V}_{FB 1} = {C}_{WL} / ( {C}_{WL} + {C}_{BL} + {C}_{SL} ) \times {V}_{ProgWL} \\ Here , \qquad ( 2 )$$

$$β = {C}_{WL} / ( {C}_{WL} + {C}_{BL} + {C}_{SL} ) \qquad ( 3 )$$

β represents a coupling ratio. In such a memory cell, the contribution ratio of C_{WL} is high, and, for example, C_{WL}:C_{BL}:C_{SL}=8:1:1. In this case, β is equal to 0.8. For example, when the word line WL changes from 5 V at the time of writing to 0 V after the completion of writing, the floating body 1102 is subjected to an amplitude noise of 5V×β=4 V due to the capacitive coupling between the word line WL and the floating body 1102. This causes a problem that a sufficient potential difference margin is not provided between the “1” potential and the “0” potential of the floating body 1102 at the time of writing.

FIG. 18A and FIG. 18B illustrate the read operation, with FIG. 18A illustrating the “1” write state and FIG. 18B illustrating the “0” write state. Actually, however, even if Vb is written in the floating body 1102 by “1” writing, the floating body 1102 is lowered to a negative bias when the word line WL returns to 0 V in response to the completion of writing. When “0” is written, the floating body 1102 is lowered to a further negative bias, which makes it difficult to provide a sufficiently large potential difference margin between “1” and “0” at the time of writing. As a result, it is difficult to actually commercialize a capacitorless DRAM memory cell.

### CITATION LIST

### Patent Literature

[PTL 1] Japanese Unexamined Patent Application Publication No. 2−188966

### Non Patent Literature

[NPL 1] Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573−578 (1991)

[NPL 2] H. Chung, H. Kim, H. Kim, K. Kim, S. Kim, K. Dong, J. Kim, Y. C. Oh, Y. Hwang, H. Hong, G. Jin, and C. Chung: “4F2 DRAM Cell with Vertical Pillar Transistor(VPT),” 2011 Proceeding of the European Solid-State Device Research Conference, (2011)

[NPL 3] H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No 12, December, pp. 2201−2227 (2010)

[NPL 4] T. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped Ni0 ReRAM under the Unipolar Voltage Source of less than 3V,” IEDM (2007)

[NPL 5] W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1−9 (2015)

[NPL 6] M. G. Ertosum, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405−407 (2010)

[NPL 7] J. Wan, L. Rojer, A. Zaslaysky, and S. Critoloveanu: “A Compact Capacitor-Less High-Speed DRAM Using Field Effect-Controlled Charge Regeneration,” Electron Device Letters, Vol. 35, No. 2, pp. 179−181 (2012)

[NPL 8] T. Ohsawa, K. Fujita, T. Higashi, Y. Iwata, T. Kajiyama, Y. Asao, and K. Sunouchi: “Memory design using a one-transistor gain cell on SOI,” IEEE JSSC, vol. 37, No. 11, pp1510−1522 (2002).

[NPL 9] T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006).

[NPL 10] E. Yoshida: “A Capacitorless 1T-DRAM Technology Using Gate-Induced Drain-Leakage (GIDL) Current for Low-Power and High-Speed Embedded Memory,” IEEE IEDM (2006).

[NPL 11] J. Y. Song, W. Y. Choi, J. H. Park, J. D. Lee, and B-G. Park: “Design Optimization of Gate-All-Around (GAA) MOSFETs,” IEEE Trans. Electron Devices, vol. 5, no. 3, pp. 186−191, May 2006.

[NPL 12] N. Loubet, et al.: “Stacked Nanosheet Gate-All-Around Transistor to Enable Scaling Beyond FinFET,” 2017 IEEE Symposium on VLSI Technology Digest of Technical Papers, T17−5, T230-T231, June 2017.

[NPL 13] H. Jiang, N. Xu, B. Chen, L. Zengl, Y. He, G. Du, X. Liu and X. Zhang: “Experimental investigation of self heating effect (SHE) in multiple-fin SOI FinFETs,” Semicond. Sci. Technol. 29 (2014) 115021 (7pp).

[NPL 14] E. Yoshida, and T. Tanaka: “A Capacitorless 1T-DRAM Technology Using Gate-Induced Drain-Leakage (GIDL) Current for Low-Power and High-Speed Embedded Memory,” IEEE Transactions on Electron Devices, Vol. 53, No. 4, pp. 692−697, April 2006.

### SUMMARY OF INVENTION

### Technical Problem

A capacitorless single-transistor DRAM (gain cell) in a memory device has a problem that oscillation of the potential of the word line at the time of reading or writing data is directly transmitted as noise to a floating SGT body because the capacitive coupling between the word line and the SGT body is large. This causes a problem of erroneous reading or erroneous rewriting of stored data, and makes it difficult to put a capacitorless single-transistor DRAM (gain cell) into practical use. Another issue is to increase the degree of integration of the memory device.

### Solution to Problem

To address the problem described above, a method for manufacturing a memory device using a semiconductor element according to the present invention is a method for manufacturing a memory device, the memory device being configured to control voltages to be applied to a first gate conductor layer, a second gate conductor layer, a first impurity layer, and a second impurity layer to perform a data write operation, a data read operation, and a data erase operation, the method including the steps of:

forming a first mask material layer on top of a semiconductor layer;

etching the semiconductor layer by using the first mask material layer as a mask to form a first semiconductor pillar standing in a vertical direction;

forming a first gate insulating layer surrounding a side surface of the first semiconductor pillar;

forming the first gate conductor layer, the first gate conductor layer surrounding a side surface of the first gate insulating layer and having an upper surface positioned below a top portion of the first semiconductor pillar;

forming a second gate insulating layer connected to the first gate insulating layer and surrounding an upper side surface of the first semiconductor pillar;

forming the second gate conductor layer so as to surround a side surface of the second gate insulating layer;

forming the first impurity layer before or after forming the first semiconductor pillar such that the first impurity layer is connected to a bottom portion of the first semiconductor pillar; and

forming the second impurity layer at the top portion of the first semiconductor pillar before or after forming the first semiconductor pillar (first aspect of the invention).

In the first aspect of the invention described above, the method further includes the steps of:

forming a third insulating layer so as to surround the first semiconductor pillar;

forming the first gate conductor layer such that the first gate conductor layer surrounds the third insulating layer in a lower portion of the first semiconductor pillar;

forming a fourth insulating layer surrounding the first gate conductor layer and having an upper end surface located above the first gate conductor layer; and

forming the second gate conductor layer such that the second gate conductor layer surrounds the third insulating layer in an upper portion of the first semiconductor pillar, and

a portion of the third insulating layer that is surrounded by the first gate conductor layer is the first gate insulating layer, and a portion of the third insulating layer that is surrounded by the second gate conductor layer is the second gate insulating layer (second aspect of the invention).

In the first aspect of the invention described above, the method further includes the step of after forming the first gate conductor layer, forming the second gate insulating layer such that the second gate insulating layer surrounds an exposed portion of the first semiconductor pillar above the upper surface of the first gate conductor layer in the vertical direction and is connected to the upper surface of the first gate conductor layer (third aspect of the invention).

In the first aspect of the invention described above, the method further includes the steps of:

forming the first gate insulating layer and a first conductor layer surrounding the first gate insulating layer;

forming the second gate insulating layer so as to surround an upper surface of the first conductor layer and a portion of the first semiconductor pillar above the first conductor layer;

forming a second conductor layer surrounding the side surface of the second gate insulating layer and having an upper surface positioned near a lower end of the second impurity layer;

forming a second mask material layer surrounding side surfaces of the second impurity layer and the first mask material layer; and

etching the second conductor layer, the second gate insulating layer, and the first conductor layer by using the first mask material layer and the second mask material layer as a mask, and

the etched first conductor layer serves as the first gate conductor layer, and the etched second conductor layer serves as the second gate conductor layer (fourth aspect of the invention).

In the fourth aspect of the invention described above, the method further includes the step of oxidizing a surface layer of the first conductor layer to form a first oxide layer (fifth aspect of the invention).

In the fourth aspect described above, the method further includes the steps of:

after forming the first conductor layer, exposing the side surface of the first semiconductor pillar; and

oxidizing a surface layer of the first conductor layer to form a first oxide layer, and simultaneously oxidizing the exposed surface layer of the first semiconductor pillar to form a second oxide layer (sixth aspect of the invention).

In the sixth aspect of the invention described above, the method further includes the step of, after forming the first oxide layer and the second oxide layer, forming a fifth insulating layer covering the first oxide layer and the second oxide layer, and

the second gate insulating layer is formed of the second oxide layer and the fifth insulating layer (seventh aspect of the invention).

In the fourth aspect of the invention described above, the method further includes the steps of:

forming a third mask material layer such that the third mask material layer is laid on top of the second mask material layer in plan view and extends in a first direction in plan view; and

etching the second conductor layer, the second gate insulating layer, and the first conductor layer by using the first mask material layer, the second mask material layer, and the third mask material layer as a mask (eighth aspect of the invention).

In the eighth aspect of the invention described above, the third mask material layer has an outer periphery that is located inside an outer periphery of the second mask material layer in a second direction perpendicular to the first direction in plan view (ninth aspect of the invention).

In the first aspect of the invention described above, the method further includes the steps of:

after forming the second gate conductor layer, forming a sixth insulating layer surrounding side surfaces of the second impurity layer and the first mask material layer;

etching the first mask material layer by using the sixth insulating layer as a mask to form a first contact hole in an upper surface of the second impurity layer; and

forming a first wiring conductor layer connected to an upper surface of the sixth insulating layer and the second impurity layer through the first contact hole (tenth aspect of the invention).

In the tenth aspect of the invention described above, the first wiring conductor layer is formed to be perpendicular to the second gate conductor layer in plan view (eleventh aspect of the invention).

In the first aspect of the invention described above, the method further includes the steps of:

forming a second contact hole such that the second contact hole is adjacent to the first gate conductor layer and the second gate conductor layer in plan view, extends in parallel to the first gate conductor layer and the second gate conductor layer in plan view, and has a bottom portion in contact with the first impurity layer; and

forming a third conductor layer at the bottom portion of the second contact hole (twelfth aspect of the invention).

In the twelfth aspect of the invention described above, the method further includes the step of forming a seventh insulating layer in the second contact hole on top of the third conductor layer, the seventh insulating layer having or not having a void (thirteenth aspect of the invention).

In the thirteenth aspect of the invention described above, the seventh insulating layer is a low-dielectric-constant material layer (fourteenth aspect of the invention).

In the tenth aspect of the invention described above, the method further includes the steps of:

forming an eighth insulating layer surrounding side surfaces of the second impurity layer and the first wiring conductor layer;

forming a third contact hole in the eighth insulating layer so as to be adjacent to the second impurity layer and the first wiring conductor layer; and

forming a ninth insulating layer in the third contact hole, the ninth insulating layer having or not having a void (fifteenth aspect of the invention).

In the fifteenth aspect of the invention described above, the eighth insulating layer is a low-dielectric-constant material layer (sixteenth aspect of the invention).

In the first aspect of the invention described above, the first gate conductor layer and the second gate conductor layer are formed such that one of the first gate conductor layer and the second gate conductor layer is connected to a plate line and the other of the first gate conductor layer and the second gate conductor layer is connected to a word line (seventeenth aspect of the invention).

In the first aspect of the invention described above, the first gate conductor layer, the second gate conductor layer, the first impurity layer, and the second impurity layer are formed so that the voltages to be applied to the first gate conductor layer, the second gate conductor layer, the first impurity layer, and the second impurity layer are controlled to perform the data write operation for holding, in the first semiconductor pillar, positive holes or electrons serving as majority carriers in the first semiconductor pillar, the positive holes or electrons being generated by an impact ionization phenomenon or a gate induced drain leakage current, and to perform the data erase operation for discharging, from within the first semiconductor pillar, the positive holes or electrons serving as majority carriers in the first semiconductor pillar (eighteenth aspect of the invention).

### BRIEF DESCRIPTION OF DRAWINGS

FIG. 1 is a structural diagram of a dynamic flash memory device according to a first embodiment.

FIGS. 2AA, 2AB, and 2AC are diagrams for describing an erase operation mechanism of the dynamic flash memory device according to the first embodiment.

FIG. 2B is a diagram for describing the erase operation mechanism of the dynamic flash memory device according to the first embodiment.

FIGS. 3AA, 3AB, and 3AC are diagrams for describing a write operation mechanism of the dynamic flash memory device according to the first embodiment.

FIGS. 3BA, 3BB, and 3BC are diagrams for describing the write operation mechanism of the dynamic flash memory device according to the first embodiment.

FIGS. 3CA and 3CB are diagrams for describing the write operation mechanism of the dynamic flash memory device according to the first embodiment.

FIG. 3D is a diagram for describing the write operation mechanism of the dynamic flash memory device according to the first embodiment.

FIG. 3E is a diagram for describing the write operation mechanism of the dynamic flash memory device according to the first embodiment.

FIGS. 4AA, 4AB, and 4AC are diagrams for describing a read operation mechanism of the dynamic flash memory device according to the first embodiment.

FIG. 4B is a diagram for describing the read operation mechanism of the dynamic flash memory device according to the first embodiment.

FIGS. 4CA, 4CB, 4CC, and 4CD are diagrams for describing the read operation mechanism of the dynamic flash memory device according to the first embodiment.

FIG. 5A is a diagram for describing a write operation mechanism of a dynamic flash memory device according to a second embodiment.

FIG. 5B is a diagram for describing the write operation mechanism of the dynamic flash memory device according to the second embodiment.

FIG. 6 is a structural diagram of a dynamic flash memory device according to a third embodiment.

FIGS. 7AA, 7AB, and 7AC are a plan view and sectional structural views for describing a method for manufacturing a dynamic flash memory device according to a fourth embodiment.

FIGS. 7BA, 7BB, and 7BC are a plan view and sectional structural views for describing the method for manufacturing a dynamic flash memory device according to the fourth embodiment.

FIGS. 7CA, 7CB, and 7CC are a plan view and sectional structural views for describing the method for manufacturing a dynamic flash memory device according to the fourth embodiment.

FIGS. 7DA, 7DB, and 7DC are a plan view and sectional structural views for describing the method for manufacturing a dynamic flash memory device according to the fourth embodiment.

FIGS. 7EA, 7EB, and 7EC are a plan view and sectional structural views for describing the method for manufacturing a dynamic flash memory device according to the fourth embodiment.

FIGS. 7FA, 7FB, and 7FC are a plan view and sectional structural views for describing the method for manufacturing a dynamic flash memory device according to the fourth embodiment.

FIGS. 7GA, 7GB, and 7GC are a plan view and sectional structural views for describing the method for manufacturing a dynamic flash memory device according to the fourth embodiment.

FIGS. 7HA, 7HB, and 7HC are a plan view and sectional structural views for describing the method for manufacturing a dynamic flash memory device according to the fourth embodiment.

FIGS. 7IA, 7IB, and 7IC are a plan view and sectional structural views for describing the method for manufacturing a dynamic flash memory device according to the fourth embodiment.

FIGS. 7JA, 7JB, and 7JC are a plan view and sectional structural views for describing the method for manufacturing a dynamic flash memory device according to the fourth embodiment.

FIGS. 7KA, 7KB, and 7KC are a plan view and sectional structural views for describing the method for manufacturing a dynamic flash memory device according to the fourth embodiment.

FIGS. 7LA, 7LB, and 7LC are a plan view and sectional structural views for describing the method for manufacturing a dynamic flash memory device according to the fourth embodiment.

FIGS. 7MA, 7MB, and 7MC are a plan view and sectional structural views for describing the method for manufacturing a dynamic flash memory device according to the fourth embodiment.

FIGS. 8AA, 8AB, 8AC, and 8AD are circuit block diagrams and a timing operation waveform diagram for describing a block erase operation of a dynamic flash memory device according to a fifth embodiment.

FIG. 8B is a diagram for describing the block erase operation of the dynamic flash memory device according to the fifth embodiment.

FIGS. 9AA and 9AB are a circuit block diagram and a timing operation waveform diagram for describing a page write operation of a dynamic flash memory device according to a sixth embodiment.

FIG. 9B is a diagram for describing the page write operation of the dynamic flash memory device according to the sixth embodiment.

FIGS. 10AA and 10AB are a circuit block diagram and a timing operation waveform diagram for describing a page read operation of a dynamic flash memory device according to a seventh embodiment.

FIG. 10B is a diagram for describing the page read operation of the dynamic flash memory device according to the seventh embodiment.

FIGS. 11AA and 11AB are circuit block diagrams and a timing operation waveform diagram for describing a block refresh operation of a dynamic flash memory device according to an eighth embodiment.

FIG. 11B is a diagram for describing the block refresh operation of the dynamic flash memory device according to the eighth embodiment.

FIGS. 12AA and 12AB are a circuit block diagram and a timing operation waveform diagram for describing a page erase operation of a dynamic flash memory device according to a ninth embodiment.

FIG. 12B is a diagram for describing the page erase operation of the dynamic flash memory device according to the ninth embodiment.

FIGS. 13AA, 13AB, and 13AC are a plan view and sectional structural views for describing a method for manufacturing a dynamic flash memory device according to a tenth embodiment.

FIGS. 13BA, 13BB, and 13BC are a plan view and sectional structural views for describing the method for manufacturing a dynamic flash memory device according to the tenth embodiment.

FIGS. 13CA, 13CB, and 13CC are a plan view and sectional structural views for describing the method for manufacturing a dynamic flash memory device according to the tenth embodiment.

FIGS. 13DA, 13DB, and 13DC are a plan view and sectional structural views for describing the method for manufacturing a dynamic flash memory device according to the tenth embodiment.

FIGS. 13EA, 13EB, and 13EC are a plan view and sectional structural views for describing the method for manufacturing a dynamic flash memory device according to the tenth embodiment.

FIGS. 14AA, 14AB, and 14AC are a plan view and sectional structural views for describing a method for manufacturing a dynamic flash memory device according to an eleventh embodiment.

FIGS. 14BA, 14BB, and 14BC are a plan view and sectional structural views for describing the method for manufacturing a dynamic flash memory device according to the eleventh embodiment.

FIGS. 14CA, 14CB, and 14CC are a plan view and sectional structural views for describing the method for manufacturing a dynamic flash memory device according to the eleventh embodiment.

FIG. 15 is a sectional structural view for describing a method for manufacturing a two-layer well structure to be disposed in a P-layer substrate 1 of a dynamic flash memory according to a twelfth embodiment.

FIGS. 16A, 16B, 16C, and 16D are diagrams illustrating a write operation of a capacitorless DRAM memory cell of the related art.

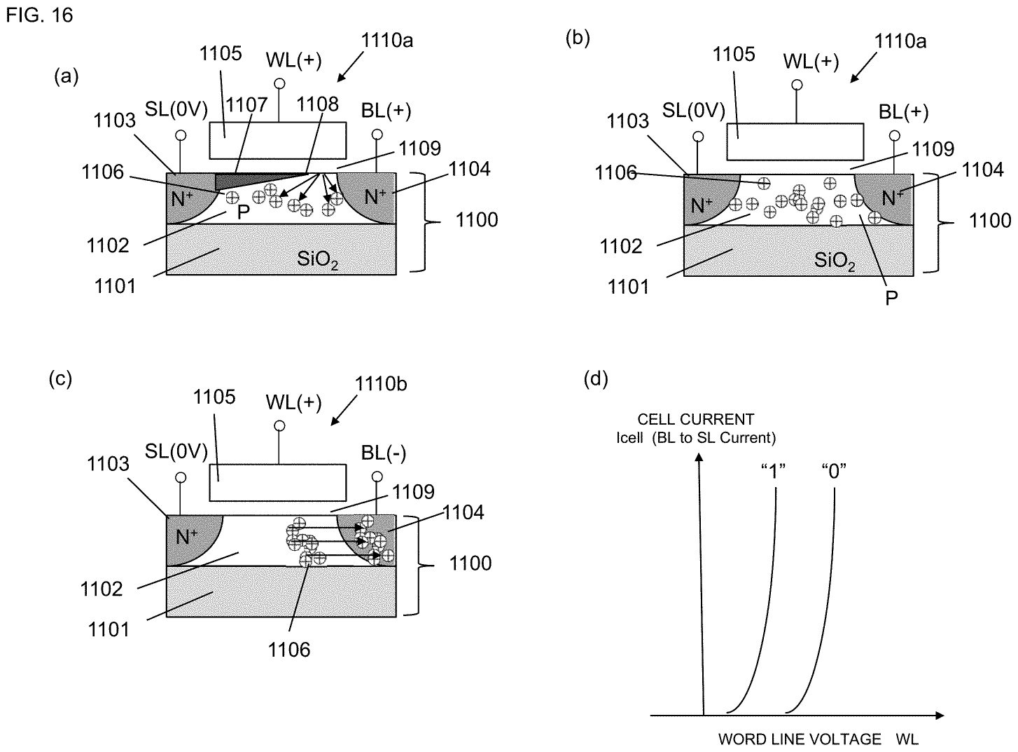

FIGS. 17A and 17B are diagrams for describing a problem in the operation of the capacitorless DRAM memory cell of the related art.

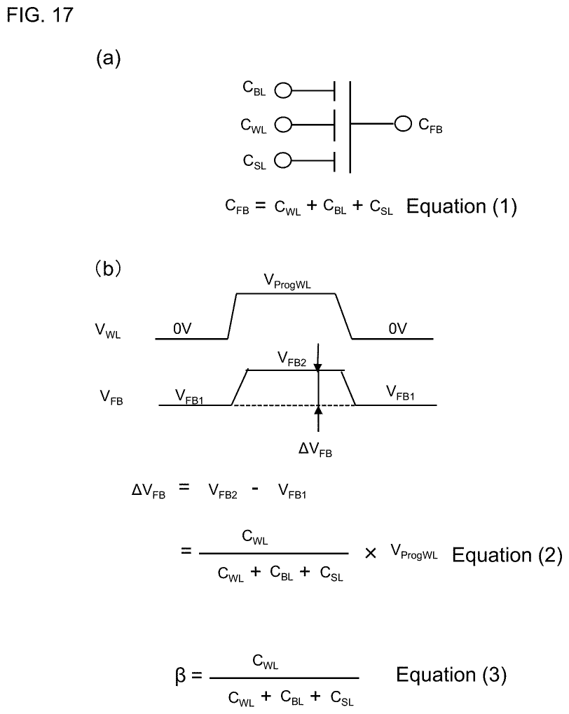

FIGS. 18A, 18B, and 18C are diagrams illustrating a read operation of the capacitorless DRAM memory cell of the related art.

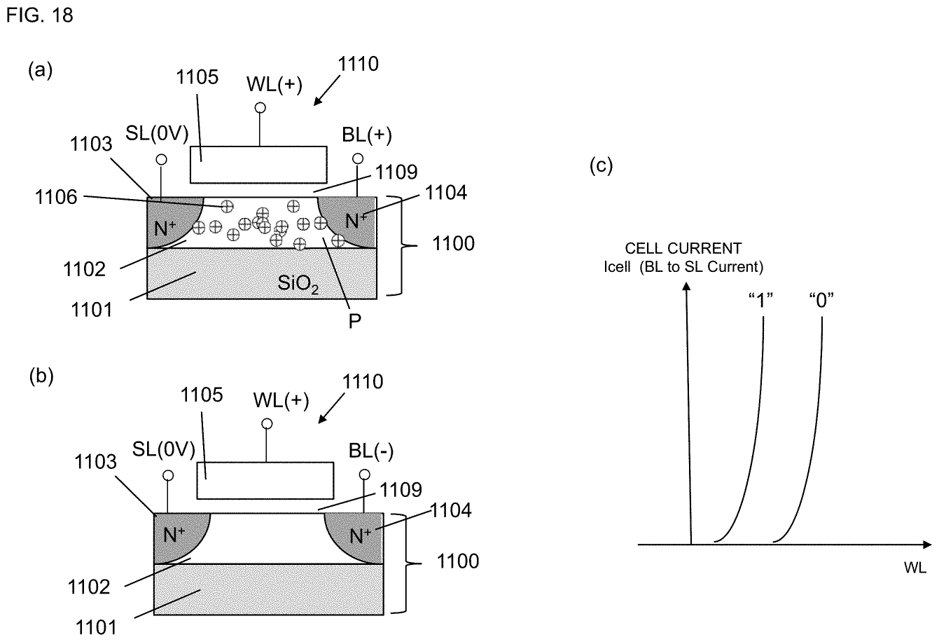

### DESCRIPTION OF EMBODIMENTS

Hereinafter, a method for manufacturing an embodiment of a memory device (hereinafter referred to as a dynamic flash memory) according to the present invention will be described with reference to the drawings.

### First Embodiment

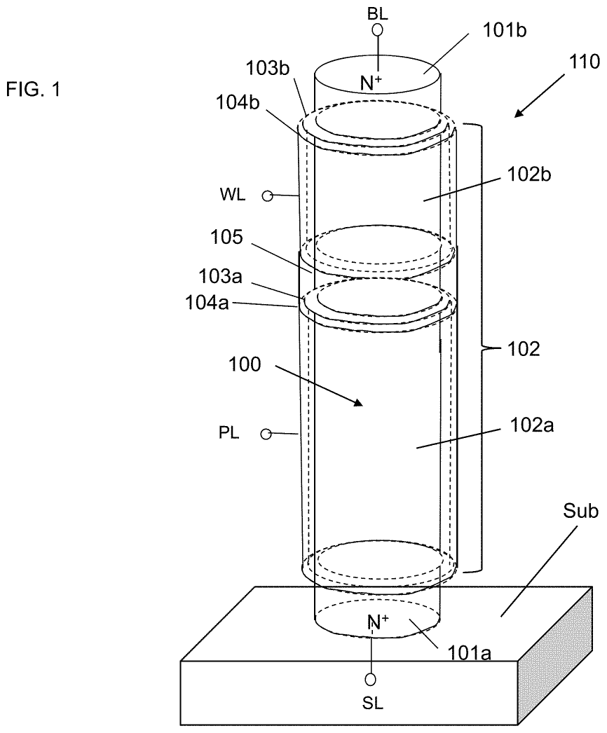

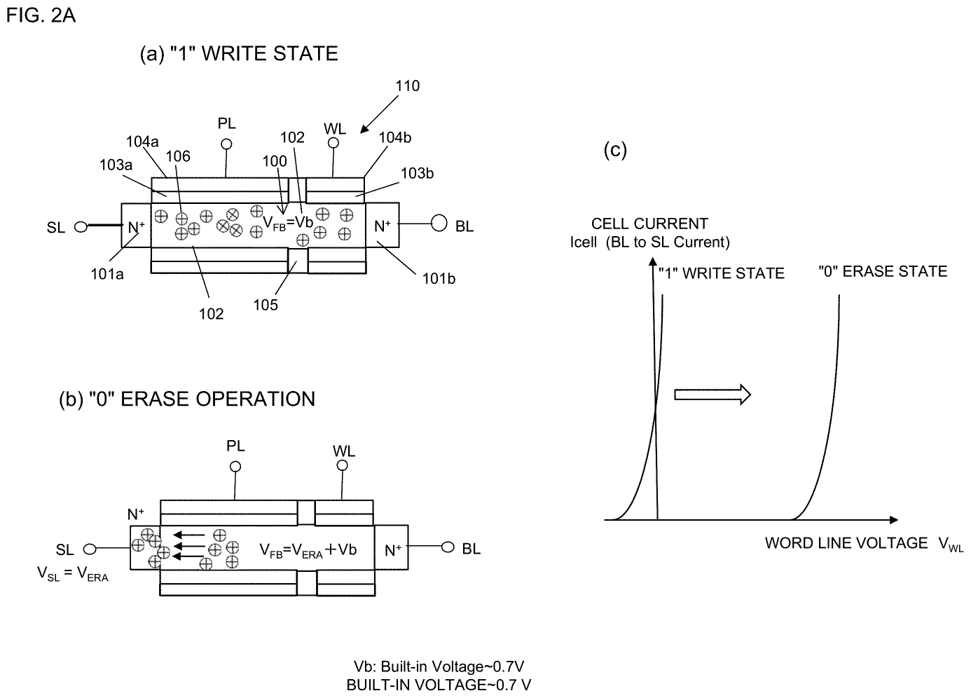

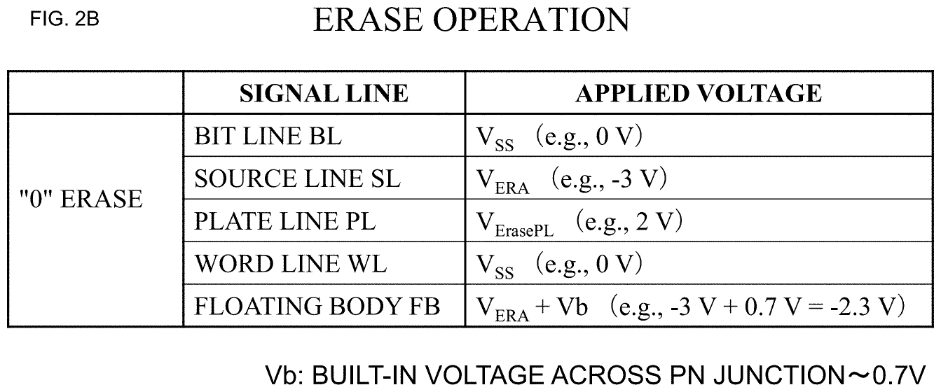

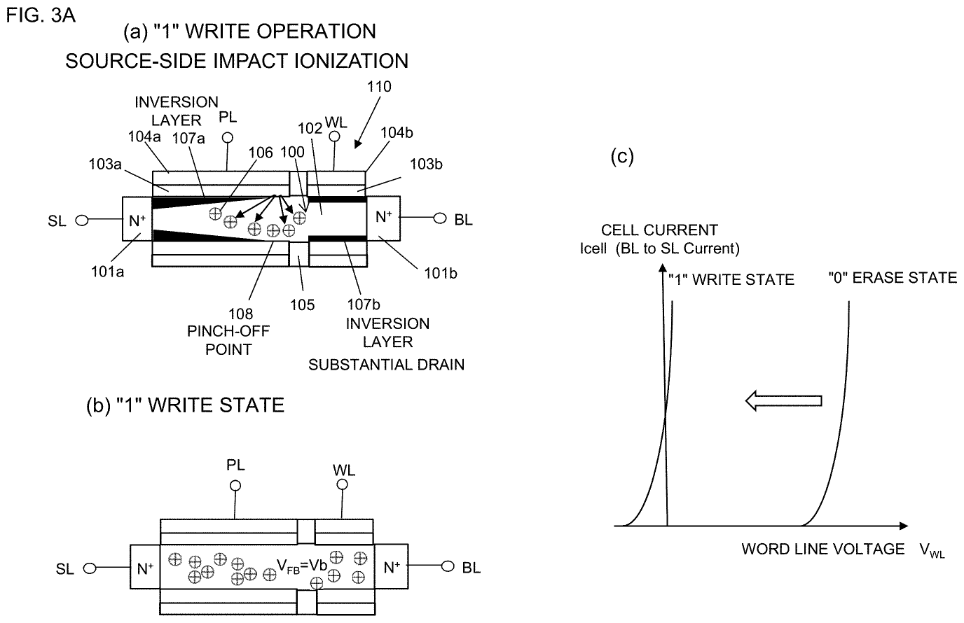

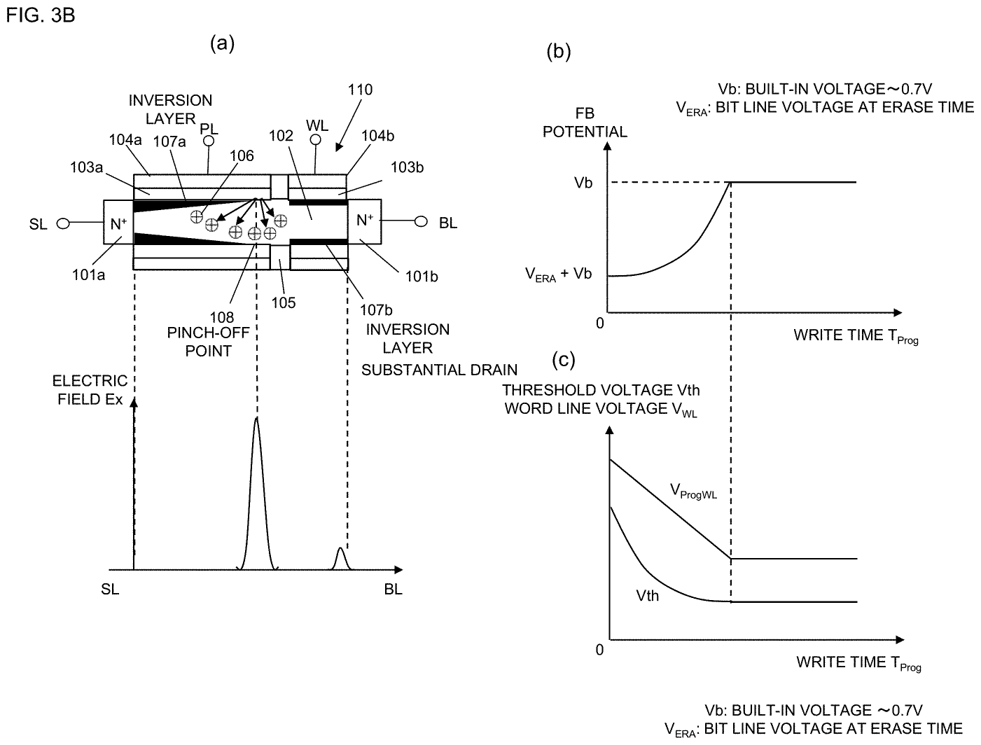

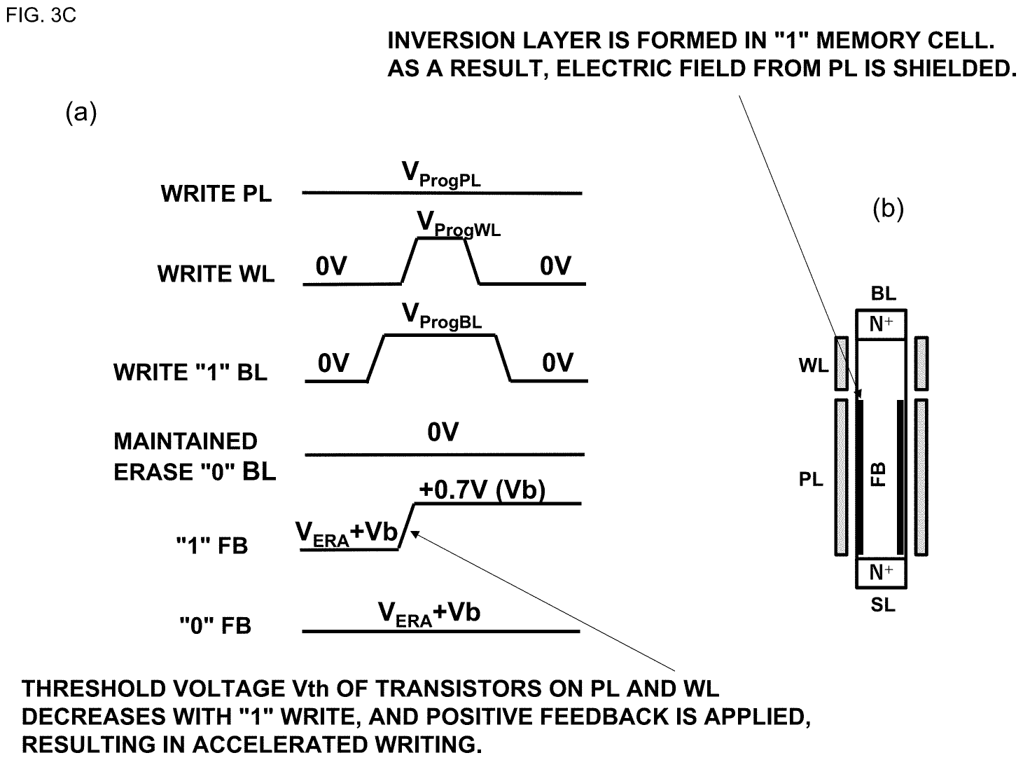

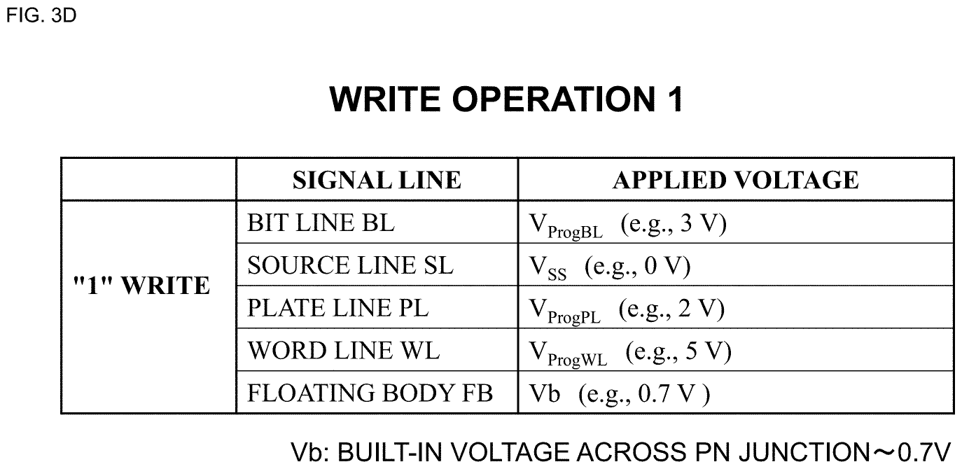

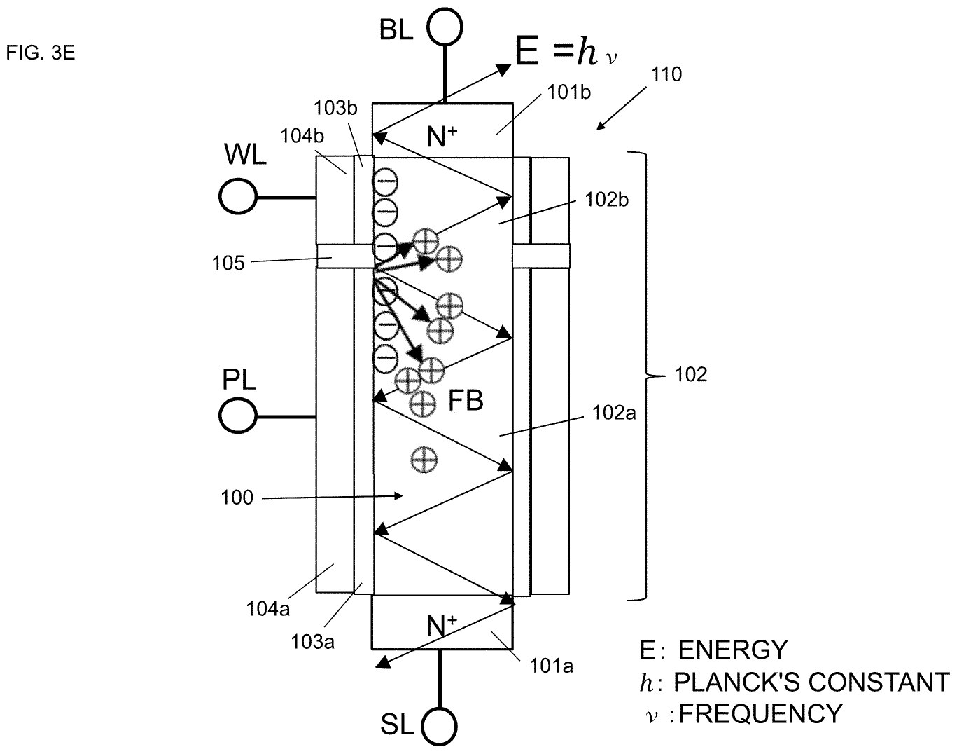

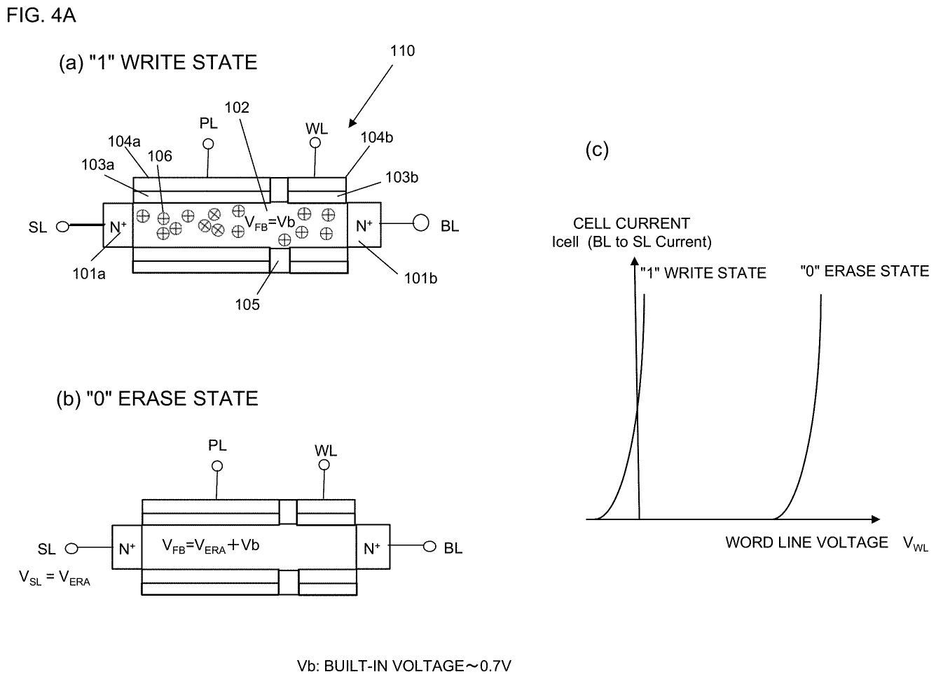

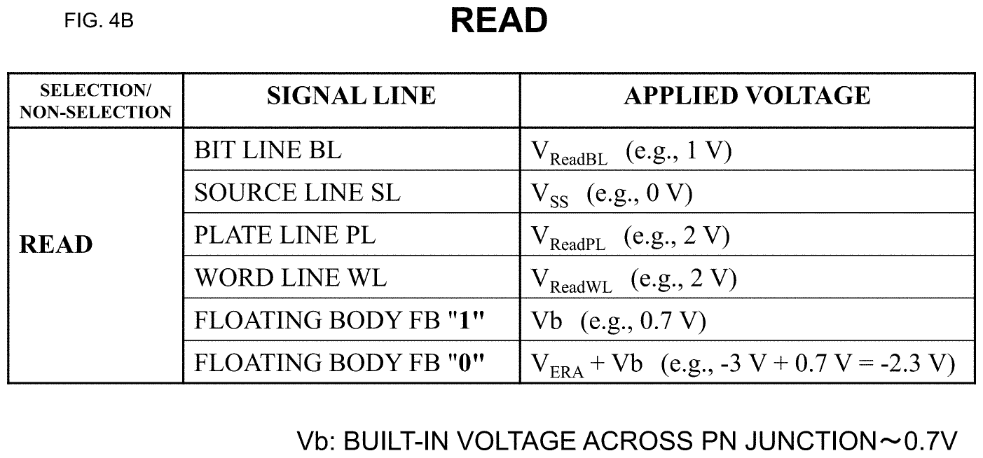

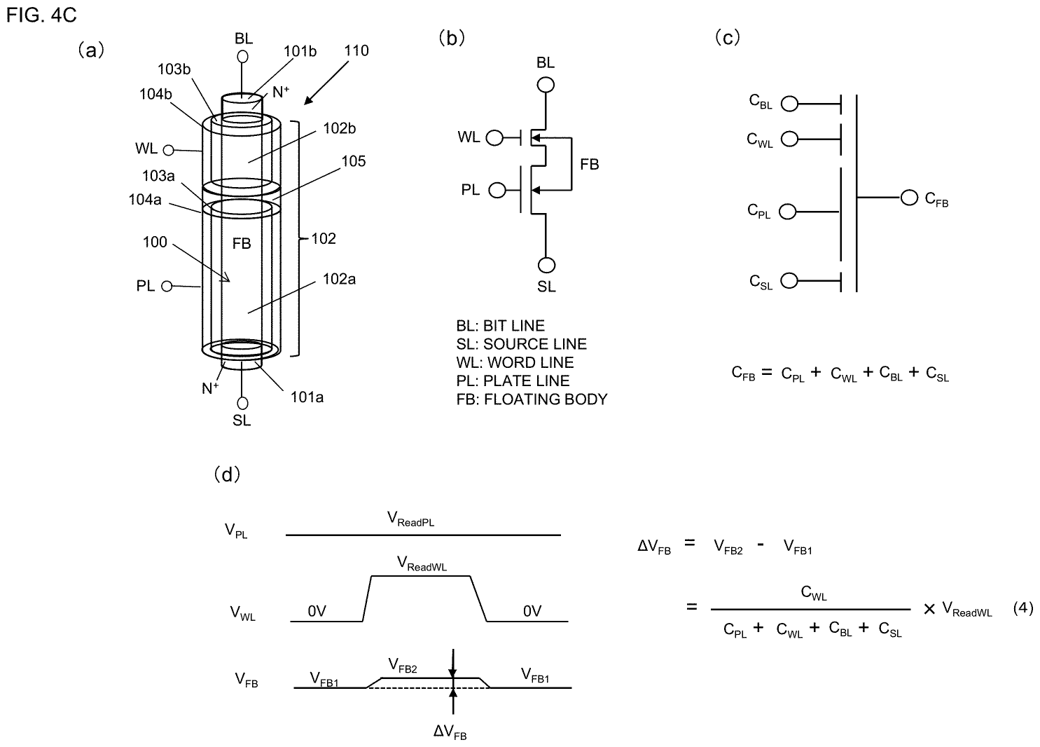

The structure and operation mechanism of a dynamic flash memory cell according to a first embodiment of the present invention will be described with reference to FIGS. 1 to 4CD. The structure of the dynamic flash memory cell will be described with reference to FIG. 1. A data erasing mechanism will be described with reference to FIG. 2, a data writing mechanism will be described with reference to FIGS. 3AA to 3E, and a data reading mechanism will be described with reference to FIGS. 4AA to 4CD.

FIG. 1 illustrates the structure of the dynamic flash memory cell according to the first embodiment of the present invention. A substrate Sub has formed thereon a silicon semiconductor pillar 100 (a silicon semiconductor pillar is hereinafter referred to as “Si pillar”) having a P conductivity type or an i (intrinsic) conductivity type. The Si pillar 100 has at upper and lower positions thereof semiconductor layers 101a and 101b containing donor impurities at high concentrations (semiconductor layers containing donor impurities at high concentrations are hereinafter referred to as “N⁺ layers”) (an example of a “first impurity layer” and a “second impurity layer” in the claims) such that one of the semiconductor layers 101a and 101b serves as a source and the other serves as a drain. The portion of the Si pillar 100 between the N⁺ layers 101a and 101b serving as the source and the drain is a channel region 102. A first gate insulating layer 103a (an example of a “first gate insulating layer” in the claims) and a second gate insulating layer 103b (an example of a “second gate insulating layer” in the claims) are formed so as to surround the channel region 102. The first gate insulating layer 103a and the second gate insulating layer 103b are in contact with or close to the N⁺ layers 101a and 101b serving as the source and the drain, respectively. A first gate conductor layer 104a (an example of a “first gate conductor layer” in the claims) and a second gate conductor layer 104b (an example of a “second gate conductor layer” in the claims) are formed so as to surround the first gate insulating layer 103a and the second gate insulating layer 103b, respectively. The first gate conductor layer 104a and the second gate conductor layer 104b are isolated from each other by an insulating layer 105. The channel region 102, which is the portion of the Si pillar 100 between the N⁺ layers 101a and 101b, is composed of a first channel region 102a surrounded by the first gate insulating layer 103a and a second channel region 102b surrounded by the second gate insulating layer 103b. Accordingly, a dynamic flash memory cell 110 composed of the N⁺ layers 101a and 101b serving as the source and the drain, the channel region 102, the first gate insulating layer 103a, the second gate insulating layer 103b, the first gate conductor layer 104a, and the second gate conductor layer 104b is formed. The N⁺ layer 101a serving as the source is connected to a source line SL, the N⁺ layer 101b serving as the drain is connected to a bit line BL, the first gate conductor layer 104a is connected to a plate line PL (an example of a “plate line” in the claims), and the second gate conductor layer 104b is connected to a word line WL (an example of a “word line” in the claims). It is desirable to achieve a structure in which the first gate conductor layer 104a to which the plate line PL is connected has a larger gate capacitance than the second gate conductor layer 104b to which the word line WL is connected.

In FIG. 1, the first gate conductor layer 104a connected to the plate line PL has a longer gate length than the second gate conductor layer 104b connected to the word line WL so that the gate capacitance of the first gate conductor layer 104a can be larger than the gate capacitance of the second gate conductor layer 104b. Alternatively, the gate length of the first gate conductor layer 104a is not set to be longer than the gate length of the second gate conductor layer 104b, but the thicknesses of the respective gate insulating layers may be changed such that a gate insulating film of the first gate insulating layer 103a has a smaller thickness than a gate insulating film of the second gate insulating layer 103b. The dielectric constant of the gate insulating film of the first gate insulating layer 103a may be set to be higher than the dielectric constant of the gate insulating film of the second gate insulating layer 103b by changing the dielectric constants of the materials of the respective gate insulating layers.

A data erase operation mechanism will be described with reference to FIGS. 2AA to 2AC and FIG. 2B. The channel region 102 between the N⁺ layers 101a and 101b is electrically isolated from the substrate Sub and serves as a floating body. FIG. 2AA illustrates a state in which positive holes 106, which are generated by impact ionization in the previous cycle and are majority carriers in the channel region 102, are stored in the channel region 102 before a data erase operation is performed. At the time of the data erase operation, as illustrated in FIG. 2AB, the voltage of the source line SL is set to a negative voltage V_{ERA}. Here, V_{ERA} is −3 V, for example. As a result, the PN junction between the channel region 102 and the N⁺ layer 101a serving as the source to which the source line SL is connected is forward biased regardless of the value of an initial potential of the channel region 102. As a result, the positive holes 106 generated by impact ionization in the previous cycle and stored in the channel region 102 are drawn into the N⁺ layer 101a corresponding to the source portion, and the channel region 102 has a potential V_{FB}, which is given by V_{FB}=V_{ERA}+Vb. Here, Vb is the built-in voltage across the PN junction and is about 0.7 V. When V_{ERA}=−3 V, the potential of the channel region 102 is −2.3 V. This value corresponds to the potential state of the channel region 102 in a data erase state. If the potential of the channel region 102 serving as the floating body becomes a negative voltage, the threshold voltage of an N-channel MOS transistor of the dynamic flash memory cell 110 increases due to a substrate bias effect. This increases the threshold voltage of the second gate conductor layer 104b to which the word line WL is connected, as illustrated in FIG. 2AC. The data erase state of the channel region 102 corresponds to logical storage data “0”. FIG. 2B illustrates an example of voltage conditions for the main node contacts at the time of the data erase operation described above.

FIGS. 3AA to 3AC illustrate a data write operation of the dynamic flash memory cell according to the first embodiment of the present invention. As illustrated in FIG. 3AA, for example, 0 V is input to the N⁺ layer 101a to which the source line SL is connected, for example, 3 V is input to the N⁺ layer 101b to which the bit line BL is connected, for example, 2 V is input to the first gate conductor layer 104a to which the plate line PL is connected, and, for example, 5 V is input to the second gate conductor layer 104b to which the word line WL is connected. As a result, as illustrated in FIG. 3AA, an annular inversion layer 107a is formed on the inner periphery of the first gate conductor layer 104a to which the plate line PL is connected, and a first N-channel MOS transistor region constituted by the first channel region 102a surrounded by the first gate conductor layer 104a is operated in the saturation region. This results in generation of a pinch-off point 108 in the inversion layer 107a on the inner periphery of the first gate conductor layer 104a to which the plate line PL is connected. In contrast, a second N-channel MOS transistor region constituted by the second channel region 102b surrounded by the second gate conductor layer 104b to which the word line WL is connected is operated in a linear region. This results in formation of an inversion layer 107b, without any pinch-off point, over the entire inner periphery of the second gate conductor layer 104b to which the word line WL is connected. The inversion layer 107b formed over the entire inner periphery of the second gate conductor layer 104b to which the word line WL is connected serves as a substantial drain of the first N-channel MOS transistor region. As a result, the electric field is maximized in the boundary region of the channel region 102 between the first N-channel MOS transistor region including the first gate conductor layer 104a and the second N-channel MOS transistor region including the second gate conductor layer 104b, which are connected in series, and an impact ionization phenomenon occurs in this region. This impact ionization phenomenon causes electrons to flow from the N⁺ layer 101a to which the source line SL is connected toward the N⁺ layer 101b to which the bit line BL is connected. The accelerated electrons collide with lattice Si atoms, and the kinetic energy of the collision generates pairs of electrons and positive holes. Some of the generated electrons flow to the first gate conductor layer 104a and the second gate conductor layer 104b, but most of them flow to the N⁺ layer 101b to which the bit line BL is connected (not illustrated). The generated positive holes 106, which are majority carriers in the channel region 102, charge the channel region 102 to a positive bias (FIG. 3AB). Since the N⁺ layer 101a to which the source line SL is connected is at 0 V, the channel region 102 is charged to the built-in voltage Vb (about 0.7 V) of the PN junction between the channel region 102 and the N⁺ layer 101a to which the source line SL is connected. Upon the channel region 102 being charged to a positive bias, the threshold voltages of the first N-channel MOS transistor region and the second N-channel MOS transistor region are decreased due to the substrate bias effect. This results in a decrease in the threshold voltage of the second N-channel MOS transistor region to which the word line WL is connected, as illustrated in FIG. 3AC. The write state of the channel region 102 is assigned to the logical storage data “1”.

At the time of the data write operation, pairs of electrons and positive holes may be generated by the impact ionization phenomenon in a second boundary region between a first impurity layer and a first channel semiconductor layer or in a third boundary region between a second impurity layer and a second channel semiconductor layer, instead of the boundary region described above, and the channel region 102 may be charged with the generated positive holes 106. In “1” writing, pairs of electrons and positive holes may be generated using a gate induced drain leakage (GIDL) current, and the floating body FB (see FIG. 2B) may be filled with the generated positive holes (see NPL 14).

FIG. 3BA illustrates a diagram for describing the electric field strength at the time of the data write operation of the dynamic flash memory cell according to the first embodiment of the present invention. FIG. 3BA illustrates a state in which the electric field strength is maximized between two gate conductor layers connected in series, that is, the first gate conductor layer 104a to which the plate line PL is connected and the second gate conductor layer 104b to which the word line WL is connected, by a source-side impact ionization phenomenon. At this time, the electric field also increases in the vicinity of the N⁺ layer 101b corresponding to the drain portion to which the bit line BL is connected although the amount of increase in electric field is very small.

FIG. 3BB illustrates a state in which the channel region 102, which is a floating body, is charged at the data writing time and increases in voltage. The channel region 102 has an initial value given by (V_{ERA}+Vb) because the data has been erased before writing. In response to the start of writing, the voltage of the channel region 102 increases to Vb in accordance with the writing time. When the voltage of the channel region 102 becomes greater than or equal to Vb, the PN junction between the N⁺ layer 101a to which the source line SL is connected and the channel region 102 of the P layer is forward biased, and the positive holes 106 generated by the source-side impact ionization phenomenon are emitted from the channel region 102 of the P layer to the source line SL connected to the N⁺ layer 101a. This results in limiting the charging of the channel region 102 of the P layer, and the channel region 102 is maintained at the potential Vb.

FIGS. 3CA and 3CB are diagrams for describing changes in the threshold voltages of both the second N-channel MOS transistor region to which the word line WL is connected and the first N-channel MOS transistor region to which the plate line PL is connected. As the voltage of the channel region 102 increases, the threshold voltage of the second N-channel MOS transistor region including the second gate conductor layer 104b to which the word line WL is connected decreases. As illustrated in FIG. 3AA, in the process of gradually changing the state of the floating body of the channel region 102 from the erase state “0” to the write state “1”, the generated positive holes are accumulated in the channel region 102. That is, the threshold voltages of both the second N-channel MOS transistor region to which the word line WL is connected and the first N-channel MOS transistor region to which the plate line PL is connected decrease. As illustrated in FIG. 3BC, the decrease in the threshold voltages can result in a decrease in the voltage of the word line WL at the time of writing. As illustrated in FIG. 3CA, the positive holes 106 are accumulated in the channel region 102 to which “1” is written, and accordingly, the threshold voltages of both the second N-channel MOS transistor region to which the word line WL is connected and the first N-channel MOS transistor region to which the plate line PL is connected decrease. As a result, positive feedback is applied, which increases the flow of current from the bit line BL to the source line SL. The impact ionization phenomenon becomes more remarkable, and the page write operation is accelerated.

In response to a change in the potential of the channel region 102 at the time of the write operation of the dynamic flash memory cell according to the first embodiment of the present invention, as illustrated in FIG. 3CB, an inversion layer is formed on an outer periphery portion of the channel region 102 at the time of the write operation. As a result, the electric field from the first gate conductor layer 104a to which the plate line PL is connected and to which a fixed voltage is always applied is shielded, and the characteristic of holding the positive holes in the channel region 102 is improved.

In response to a change in the potential of the channel region 102 at the time of the write operation of the dynamic flash memory cell according to the first embodiment of the present invention, as illustrated in FIG. 3D, for example, the voltage of the word line WL is as high as 5 V at the beginning of the write operation to cause the second N-channel MOS transistor region including the second gate conductor layer 104b to operate in the saturation region. As the write operation progresses, the voltage of the word line WL can be decreased to about 2 V, for example. FIG. 3D summarizes an example of voltage conditions for the main node contacts at the time of the write operation. As a result, for example, even if the voltage of the word line WL is reset to 0 V at the completion of writing, the effect of lowering the potential of the channel region 102 to which the second gate conductor layer 104b is capacitively coupled is reduced.

The impact ionization phenomenon induced in the write operation of the dynamic flash memory cell according to the first embodiment of the present invention causes generation of photons in addition to pairs of electrons and positive holes, as illustrated in FIG. 3E. The generated photons are repeatedly reflected by the first gate conductor layer 104a and the second gate conductor layer 104b of the Si pillar 100, and travel toward the central axis of the Si pillar 100. As described above, the generated photons are repeatedly reflected by the first gate conductor layer 104a to which the plate line PL is connected and the second gate conductor layer 104b to which the word line WL is connected using the Si pillar 100 as a waveguide, and travel in the vertical direction of the Si pillar 100. At this time, the first gate conductor layer 104a and the second gate conductor layer 104b have a light shielding effect in which the photons generated at the time of writing do not destroy the data in adjacent memory cells.

FIGS. 4AA to 4CD are diagrams for describing a read operation of the dynamic flash memory cell according to the first embodiment of the present invention. As illustrated in FIG. 4AA, upon the channel region 102 being charged to the built-in voltage Vb (about 0.7 V), the threshold voltages of the N-channel MOS transistors are decreased due to the substrate bias effect. This state is assigned to the logical storage data “1”. As illustrated in FIG. 4AB, when the memory block to be selected before writing is performed is in the erase state “0” in advance, the channel region 102 is at a floating voltage V_{FB}, which is given by V_{ERA}+Vb. Through the write operation, the write state “1” is stored randomly. As a result, logical storage data of logic “0” and “1” is created for the word line WL. As illustrated in FIG. 4AC, the difference between the two threshold voltages for the word line WL is used to perform reading by using a sense amplifier. In data reading, the voltage to be applied to the first gate conductor layer 104a connected to the plate line PL is set to be higher than the threshold voltage at the time of logical storage data “1” and lower than the threshold voltage at the time of logical storage data “0”, whereby a characteristic is obtained in which no current flows even when the voltage of the word line WL is increased in reading of the logical storage data “0”. FIG. 4B summarizes an example of voltage conditions for the main node contacts at the time of the read operation. The condition of the voltages to be applied to the bit line BL, the source line SL, the word line WL, and the plate line PL, described above, is an example for performing the data read operation, and other operation conditions under which the data read operation can be performed may be used. For example, the data read operation may be performed with a voltage difference applied between the bit line BL and the source line SL. Alternatively, the data read operation may be performed by a bipolar operation.

FIGS. 4CA to 4CD are structural diagrams illustrating the magnitude relationship of the gate capacitance between the first gate conductor layer 104a and the second gate conductor layer 104b at the time of the read operation of the dynamic flash memory cell according to the first embodiment of the present invention. The gate capacitance of the second gate conductor layer 104b to which the word line WL is connected is desirably designed to be smaller than the gate capacitance of the first gate conductor layer 104a to which the plate line PL is connected. As illustrated in FIG. 4CA, the vertical length of the first gate conductor layer 104a to which the plate line PL is connected is set to be longer than the vertical length of the second gate conductor layer 104b to which the word line WL is connected to make the gate capacitance of the second gate conductor layer 104b to which the word line WL is connected smaller than the gate capacitance of the first gate conductor layer 104a to which the plate line PL is connected. FIG. 4CB illustrates an equivalent circuit of one cell of the dynamic flash memory illustrated in FIG. 4CA. FIG. 4CC illustrates a coupling capacitance relationship of the dynamic flash memory. Here, C_{WL} is the capacitance of the second gate conductor layer 104b, C_{PL} is the capacitance of the first gate conductor layer 104a, C_{BL} is the capacitance of the PN junction between the second channel region 102b and the N⁺ layer 101b serving as the drain, and C_{SL} is the capacitance of the PN junction between the first channel region 102a and the N⁺ layer 101a serving as the source. An oscillation of the voltage of the word line WL affects the channel region 102 as noise. A potential variation ΔV_{FB} of the channel region 102 at this time is expressed by the following equation.

ΔV_{FB}=C_{WL}/(C_{PL}+C_{WL}+C_{BL}+C_{SL})×V_{ReadWL} (4)

Here, V_{ReadWL} is the oscillating potential of the word line WL at the time of reading. As is apparent from Equation (4), a reduction in the contribution ratio of C_{WL} compared with the total capacitance C_{PL}+C_{WL}+C_{BL}+C_{SL} of the channel region 102 decreases ΔV_{FB}. C_{BL}+C_{SL} is the capacitance of the PN junction, and is considered to be increased by, for example, increasing the diameters of the Si pillar 100.

However, this is not desirable for the miniaturization of the memory cell. By contrast, the vertical length of the first gate conductor layer 104a to which the plate line PL is connected can further be set to be longer than the vertical length of the second gate conductor layer 104b to which the word line WL is connected to further decrease ΔV_{FB} without reducing the degree of integration of memory cells in plan view.

It is desirable that the vertical length of the first gate conductor layer 104a to which the plate line PL is connected be set to be longer than the vertical length of the second gate conductor layer 104b to which the word line WL is connected such that C_{PL}>C_{W} is satisfied. However, only addition of the plate line PL results in a reduction in the capacitive coupling ratio of the word line WL to the channel region 102 (C_{WL}/(C_{PL}+C_{WL}+C_{BL}+C_{SL})). As a result, the potential variation ΔV_{FB} of the channel region 102 of the floating body is reduced.

For example, a fixed voltage of 2 V may be applied as a voltage V_{ErasePL} of the plate line PL regardless of each operation mode, or, for example, 0 V may be applied as the voltage V_{ErasePL} of the plate line PL only at the time of erasing.

Further, the dynamic flash memory operation described in this embodiment can be implemented regardless of whether the cross-sectional shape of the Si pillar 100 is circular, elliptical, or rectangular. In addition, circular, elliptical, and rectangular dynamic flash memory cells may be disposed on the same chip in a mixed manner.

As described in the description of this embodiment, the present dynamic flash memory element has a structure satisfying the condition that the positive holes 106 generated by the impact ionization phenomenon are held in the channel region 102. To this end, the channel region 102 has a floating body structure separated from the substrate Sub. Accordingly, for example, GAA (Gate All Around: see, for example, NPL 11) technology or Nanosheet technology (see, for example, NPL 12), which is one of SGT technologies, can be used to implement the dynamic flash memory operation described above. Alternatively, a device structure using SOI (Silicon On Insulator) (see, for example, NPLs 7 to 10) may be used. In this device structure, a channel region has a bottom portion that is in contact with an insulating layer of an SOI substrate, and another channel region is surrounded by a gate insulating layer and an element isolation insulating layer. Also in this structure, the channel region has a floating body structure. As described above, the dynamic flash memory element provided in this embodiment satisfies the condition that the channel region has a floating body structure. Alternatively, a structure in which Fin transistors (see, for example, NPL 13) are formed on an SOI substrate can implement the present dynamic flash operation as long as the channel region has a floating body structure. Alternatively, GAA transistors or Nanosheet elements can be stacked in multiple stages to form a dynamic flash memory element. Alternatively, dynamic flash memory cells each illustrated in FIG. 1 can be stacked in multiple stages to form a dynamic flash memory element.

Further, the channel region 102 is formed such that, in the vertical direction, the potential distributions of the first channel region 102a and the second channel region 102b are connected to each other in the portion of the channel region 102 surrounded by the insulating layer 105 serving as the first insulating layer. Accordingly, the first channel region 102a and the second channel region 102b are connected to each other in the vertical direction in a region surrounded by the insulating layer 105 serving as the first insulating layer.

In the description and the claims, the term “covering” in the phrase “a gate insulating layer, a gate conductor layer, or the like covering a channel or the like” is meant to include surrounding the entirety, like an SGT or a GAA, surrounding a part, like a Fin transistor, and being laid on top of a planar region, like a planar transistor.

FIGS. 2AA to 2AC and FIG. 2B illustrate an example of the erase operation conditions. Alternatively, the voltages to be applied to the source line SL, the plate line PL, the bit line BL, and the word line WL may be changed if the positive holes 106 in the channel region 102 can be discharged from one or both of the N⁺ layer 101a and the N⁺ layer 101b.

In FIG. 1, both or one of the first gate conductor layer 104a and the second gate conductor layer 104b may be divided into two or more portions, and the two or more portions may be operated synchronously or asynchronously while each of the two or more portions serves as a conductive electrode for the plate line PL or the word line WL. This also allows a dynamic flash memory operation to be performed.

The condition of the voltages to be applied to the bit line BL, the source line SL, the word line WL, and the plate line PL, described above, and the voltage of the floating body are an example for performing the basic operations of the erase operation, the write operation, and the read operation, and other voltage conditions under which the basic operations can be performed may be used.

In FIG. 1, even a structure in which the N⁺ layers 101a and 101b and the P-layer Si pillar 100 have conductivity types reversed in polarity from that described above can also implement the dynamic flash memory operation. In this case, electrons are majority carriers in the N-type Si pillar 100. Accordingly, the electrons generated by impact ionization are stored in the channel region 102, and the “1” state is set.

This embodiment has the following features.

### (Feature 1)

In the dynamic flash memory cell according to this embodiment, the N⁺ layers 101a and 101b serving as the source and the drain, the channel region 102, the first gate insulating layer 103a, the second gate insulating layer 103b, the first gate conductor layer 104a, and the second gate conductor layer 104b are formed into a pillar shape as a whole. The N⁺ layer 101a serving as the source is connected to the source line SL, the N⁺ layer 101b serving as the drain is connected to the bit line BL, the first gate conductor layer 104a is connected to the plate line PL, and the second gate conductor layer 104b is connected to the word line WL. A characteristic structure is obtained in which the gate capacitance of the first gate conductor layer 104a to which the plate line PL is connected is larger than the gate capacitance of the second gate conductor layer 104b to which the word line WL is connected. In the present dynamic flash memory cell, the first gate conductor layer 104a and the second gate conductor layer 104b are stacked on one another in a vertical direction. Thus, even the structure in which the gate capacitance of the first gate conductor layer 104a to which the plate line PL is connected is larger than the gate capacitance of the second gate conductor layer 104b to which the word line WL is connected does not result in an increase in the size of the memory cell in plan view. Accordingly, high performance and high integration of the dynamic flash memory cell can be simultaneously realized.

### (Feature 2)

As illustrated in FIG. 3BA, in the write operation, the first N-channel MOS transistor region including the first gate conductor layer 104a connected to the plate line PL, which is adjacent to the source line SL, is operated in the linear region, and the second N-channel MOS transistor region including the second gate conductor layer 104b connected to the word line WL, which is disposed adjacent to the N⁺ layer 101b serving as the drain, is operated in the saturation region. As a result, the inversion layer 107b formed on the entire surface immediately below the second gate conductor layer 104b to which the word line WL is connected serves as a substantial drain of the second N-channel MOS transistor region including the second gate conductor layer 104b. As a result, the electric field between the first N-channel MOS transistor region including the first gate conductor layer 104a and the second N-channel MOS transistor region including the second gate conductor layer 104b, which are connected in series, is maximized, and impact ionization occurs in this region, resulting in generation of pairs of electrons and positive holes. As described above, the location where impact ionization is generated can be set in the channel between the first N-channel MOS transistor region including the first gate conductor layer 104a and the second N-channel MOS transistor region including the second gate conductor layer 104b, which are connected in series.

### (Feature 3)

In the write operation, the first N-channel MOS transistor region including the first gate conductor layer 104a to which the plate line PL is connected, which is disposed adjacent to the N⁺ layer 101a serving as the source, is operated in the linear region, and the second N-channel MOS transistor region including the second gate conductor layer 104b to which the word line WL is connected, which is disposed adjacent to the N⁺ layer 101b serving as the drain, is operated in the saturation region, thereby generating the inversion layer 107b serving as a substantial drain portion extending from the N⁺ layer 101b serving as the drain. As a result, the source-side impact ionization phenomenon maximizes the electric field strength between two gate conductor layers connected in series, that is, the first gate conductor layer 104a to which the plate line PL is connected and the second gate conductor layer 104b to which the word line WL is connected. A source-side injection flash memory using this operation mechanism is known. The writing of the flash memory requires an energy of 3.9 eV or more to inject electrons into the floating gate beyond the barrier of the oxide film as thermoelectrons generated by the impact ionization phenomenon. However, the writing of the dynamic flash memory, in which only the positive holes are accumulated in the channel region 102, requires a lower electric field than the writing of the flash memory. As a result, the impact ionization phenomenon can be used as an operation mechanism of writing, multiple bits can be simultaneously written, and a higher writing speed and lower power consumption can be realized than in the flash memory.

### (Feature 4)

In the dynamic flash memory cell according to the first embodiment of the present invention, the threshold voltages of the second N-channel MOS transistor region including the second gate conductor layer 104b to which the word line WL is connected and the first N-channel MOS transistor region including the first gate conductor layer 104a to which the plate line PL is connected decrease as the potential of the channel region 102 increases in the write operation. The decrease in the threshold voltages can result in a decrease in the voltage of the word line WL at the time of writing. When the generated positive holes are accumulated in the channel region 102 at the time of writing, positive feedback is applied and the page write operation is accelerated. This reduces the data write time.

### (Feature 5)

In the dynamic flash memory cell according to the first embodiment of the present invention, an inversion layer is formed on an outer periphery portion of the channel region 102 of the Si pillar 100 in the write operation as the potential of the channel region 102 increases in the write operation. As a result, the electric field from the plate line PL to which a fixed voltage is always applied is shielded. This improves the characteristic of holding the positive holes in the channel region 102.

### (Feature 6)

In the dynamic flash memory cell according to the first embodiment of the present invention, as the potential of the channel region 102 increases in the write operation, the initial voltage of the word line WL at the start of writing can be reduced while the second N-channel MOS transistor region including the second gate conductor layer 104b is kept operating in the saturation region. As a result, even if the voltage of the word line WL is reset to 0 V at the completion of writing, the effect of lowering the potential of the floating body 100 to which the second gate conductor layer 104b is capacitively coupled is reduced. This leads to a stable operation due to an increase in the operation margin of the dynamic flash memory cell.

(Feature 7)

In the dynamic flash memory cell according to the first embodiment of the present invention, the impact ionization phenomenon induced in the write operation causes generation of photons in addition to pairs of electrons and positive holes. The generated photons are repeatedly reflected by the first gate conductor layer 104a and the second gate conductor layer 104b of the Si pillar 100, and travel through the Si pillar 100 toward the central axis. At this time, the first gate conductor layer 104a and the second gate conductor layer 104b have a shielding effect for the photons generated at the time of writing, and prevent destruction of data in horizontally adjacent memory cells.

### (Feature 8)

The first gate conductor layer 104a to which the plate line PL of the dynamic flash memory cell according to the first embodiment of the present invention is connected has the following functions (1) to (5).

(1) In the write or read operation of the dynamic flash memory cell, the voltage of the word line WL oscillates up and down. At this time, the plate line PL serves to reduce the capacitive coupling ratio between the word line WL and the channel region 102. This results in a significant reduction in the influence of the change in voltage across the channel region 102 caused by the up and down oscillation of the voltage of the word line WL. Accordingly, the difference between the threshold voltages of an SGT transistor on the word line WL that indicate logic “0” and logic “1” can be increased. This leads to an increase in the operation margin of the dynamic flash memory cell.

(2) In the erase, write, and read operations of the dynamic flash memory cell, both the first gate conductor layer 104a to which the plate line PL is connected and the second gate conductor layer 104b to which the word line WL is connected act as gates of the SGT transistor. In the flow of current from the bit line BL to the source line SL, a short channel effect of the SGT transistor can be suppressed. As described above, the first gate conductor layer 104a to which the plate line PL is connected suppresses the short channel effect. As a result, the data retention characteristics can be improved.

(3) In response to the start of the write operation of the dynamic flash memory cell, positive holes are gradually accumulated in the channel region 102, and the threshold voltages of the first MOS transistor having the plate line PL and the second MOS transistor having the word line WL decrease. At this time, the decrease in the threshold voltage of the first MOS transistor having the plate line PL promotes the impact ionization phenomenon in the write operation. As a result, the plate line PL exerts positive feedback at the time of writing, and a high-speed write operation is achieved.

(4) In the dynamic flash memory cell to which “1” is written, the threshold voltage of the first MOS transistor having the plate line PL is decreased. As a result, in response to a positive bias being applied to the plate line PL, an inversion layer is always formed immediately below the first gate conductor layer 104a connected to the plate line PL. As a result, the layer of electrons accumulated in the inversion layer formed immediately below the first gate conductor layer 104a connected to the plate line PL serves as a conductive radio wave shielding layer. Thus, the dynamic flash memory cell to which “1” is written is shielded from disturbance noise therearound.

(5) In the write operation of the dynamic flash memory cell, an impact ionization phenomenon causes generation of photons. The generated photons are repeatedly reflected by the first gate conductor layer 104a and the second gate conductor layer 104b, and travel toward the central axis of the Si pillar 100. At this time, the plate line PL has a light shielding effect for photons such that the photons generated at the time of writing do not destroy data in horizontally adjacent memory cells.

### Second Embodiment

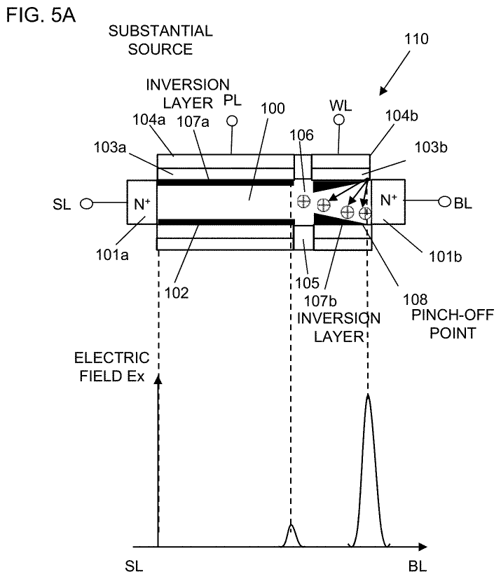

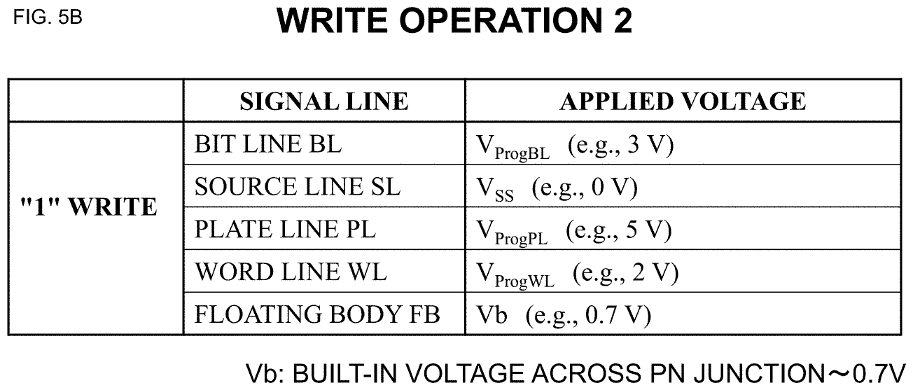

A second embodiment will be described with reference to FIG. 5A and FIG. 5B.

FIG. 5A and FIG. 5B illustrate a write operation. As illustrated in FIG. 5A, for example, 0 V is input to the N⁺ layer 101a serving as the source to which the source line SL is connected, for example, 3 V is input to the N⁺ layer 101b serving as the drain to which the bit line BL is connected, for example, 5 V is input to the first gate conductor layer 104a to which the plate line PL is connected, and, for example, 2 V is input to the second gate conductor layer 104b to which the word line WL is connected. As a result, as illustrated in FIG. 5A, an inversion layer 107a is formed on the entire surface immediately below the first gate conductor layer 104a to which the plate line PL is connected, and the first N-channel MOS transistor region including the first gate conductor layer 104a is operated in a saturation region. As a result, the inversion layer 107a immediately below the first gate conductor layer 104a to which the plate line PL is connected has no pinch-off point and serves as a substantial source of the second N-channel MOS transistor region including the second gate conductor layer 104b. In contrast, the second N-channel MOS transistor region including the second gate conductor layer 104b to which the word line WL is connected is operated in a linear region. As a result, an inversion layer 107b formed immediately below the second gate conductor layer 104b to which the word line WL is connected has a pinch-off point 108. As a result, the electric field is maximized in the vicinity of the N⁺ layer 101b serving as the drain of the second N-channel MOS transistor region including the second gate conductor layer 104b to which the word line WL is connected, and impact ionization occurs in this region. The impact ionization phenomenon causes the floating body 100 to be charged to Vb, and the write state “1” is obtained.

FIG. 5B summarizes an example of voltage conditions for the main node contacts at the time of the write operation. For example, the voltage of the plate line PL can be set to be high such as 5 V, and the voltage of the word line WL can be set to be fixed at a lower voltage such as 2 V.

This embodiment has the following features.

In the first embodiment, as illustrated in FIG. 3AA, impact ionization occurs in a region, adjacent to the word line WL, of the first N-channel MOS transistor region including the first gate conductor layer 104a to which the plate line PL is connected. In this embodiment, in contrast, impact ionization occurs in the vicinity of the N⁺ layer 101b serving as the drain of the second N-channel MOS transistor region including the second gate conductor layer 104b to which the word line WL is connected. Accordingly, the dynamic flash memory operation can be performed in a manner similar to that in the first embodiment.

### Third Embodiment

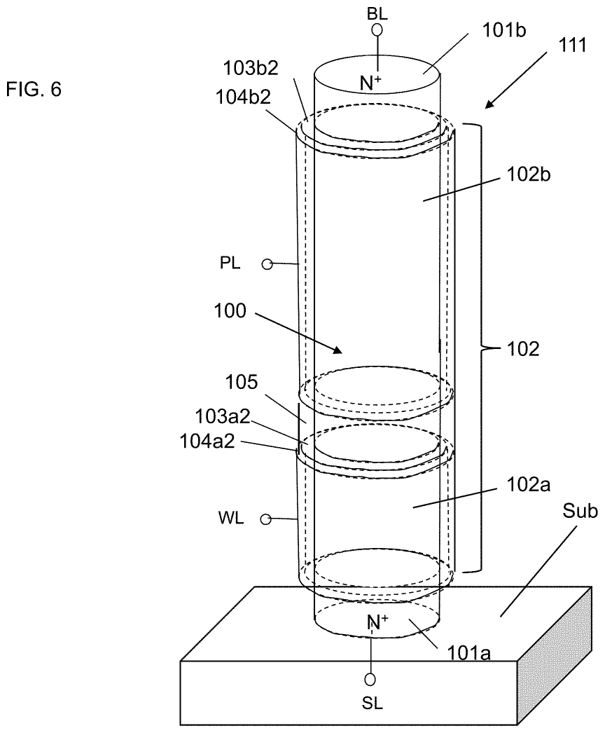

A third embodiment will be described with reference to a structural diagram illustrated in FIG. 6.

As illustrated in FIG. 6, the connection positional relationships between the word line WL and the Si pillar 100 and between the plate line PL and the Si pillar 100 are reversed upside down from those in the structure illustrated in FIG. 1. Here, the portion of the Si pillar 100 between the N⁺ layers 101a and 101b serving as the source and the drain is a channel region 102. A first gate insulating layer 103a2 and a second gate insulating layer 103b2 are formed so as to surround the channel region 102. A first gate conductor layer 104a 2 and a second gate conductor layer 104b2 are formed so as to surround the first gate insulating layer 103a2 and the second gate insulating layer 103b2, respectively. In a dynamic flash memory cell, the N⁺ layers 101a and 101b serving as the source and the drain, the channel region 102, the first gate insulating layer 103a2, the second gate insulating layer 103b2, the first gate conductor layer 104a2, and the second gate conductor layer 104b2 are formed into a pillar shape as a whole. An insulating layer 105 is formed between the first gate conductor layer 104a2 and the second gate conductor layer 104b2 to isolate the first gate conductor layer 104a2 and the second gate conductor layer 104b2 from each other. The N⁺ layer 101a serving as the source is connected to the source line SL, the N⁺ layer 101b serving as the drain is connected to the bit line BL, the first gate conductor layer 104a2 is connected to the word line WL, and the second gate conductor layer 104b2 is connected to the plate line PL.

As illustrated in FIG. 6, a characteristic structure is obtained in which the second gate conductor layer 104b2 to which the plate line PL is connected has a larger gate capacitance than the first gate conductor layer 104a2 to which the word line WL is connected. Here, the gate length of the second gate conductor layer 104b2 is set to be longer than the gate length of the first gate conductor layer 104a2 by changing the respective gate lengths.

This embodiment has the following features.

In the first embodiment, as illustrated in FIG. 1, the first N-channel MOS transistor region including the first gate conductor layer 104a to which the plate line PL is connected, which is disposed adjacent to the N⁺ layer 101a serving as the source, and the second N-channel MOS transistor region including the second gate conductor layer 104b to which the word line WL is connected, which is disposed adjacent to the N⁺ layer 101b serving as the drain, are connected in series. According to this embodiment, as illustrated in FIG. 6, the connection positional relationships between the word line WL and the Si pillar 100 and between the plate line PL and the Si pillar 100 are reversed upside down from those in the structure illustrated in FIG. 1. As illustrated in FIG. 6, furthermore, a characteristic structure is obtained in which the gate length of the second gate conductor layer 104b2 is set to be longer than the gate length of the first gate conductor layer 104a2 by changing the respective gate lengths such that the second gate conductor layer 104b2 to which the plate line PL is connected has a larger gate capacitance than the first gate conductor layer 104a2 to which the word line WL is connected.

### Fourth Embodiment

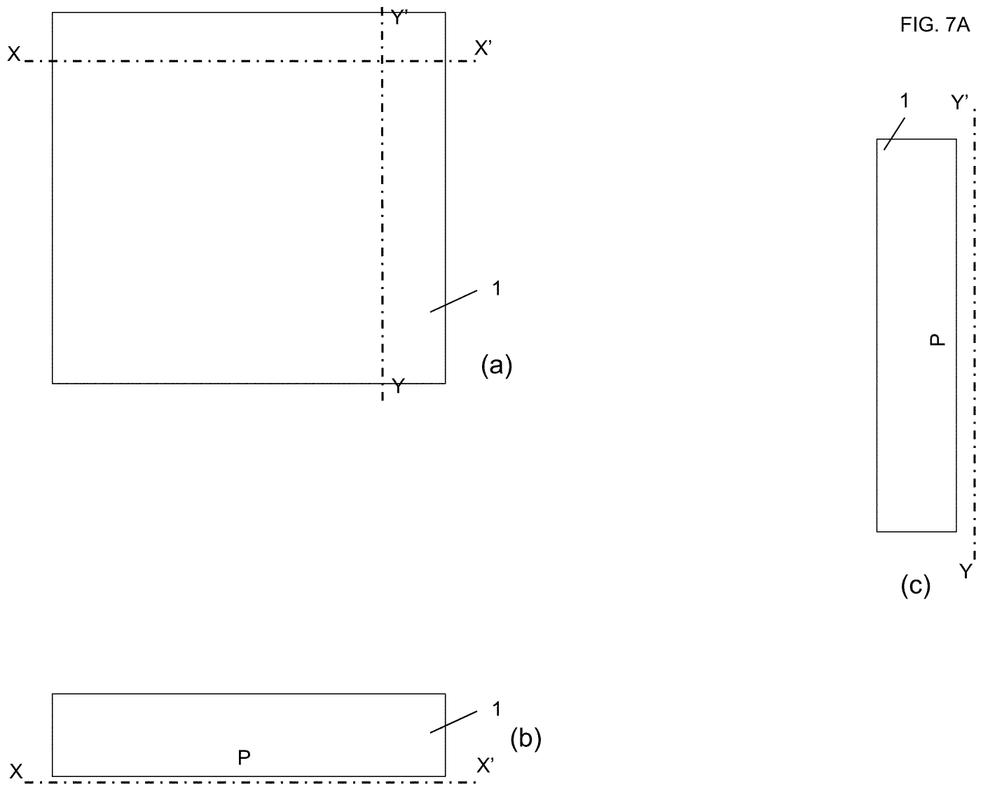

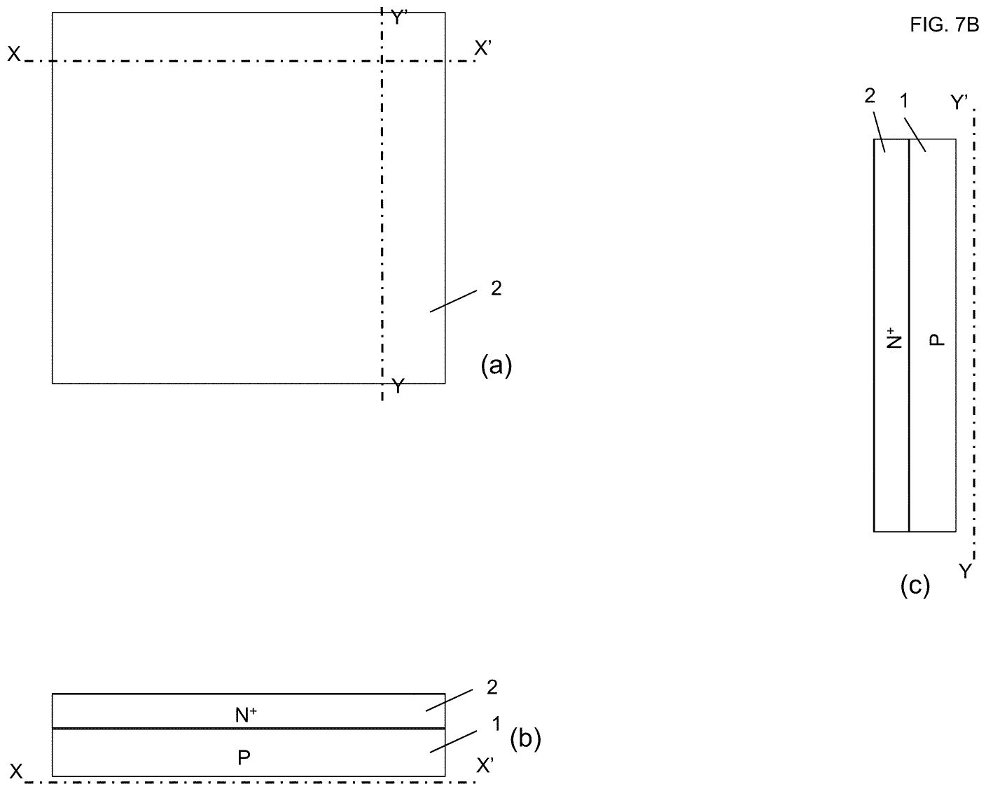

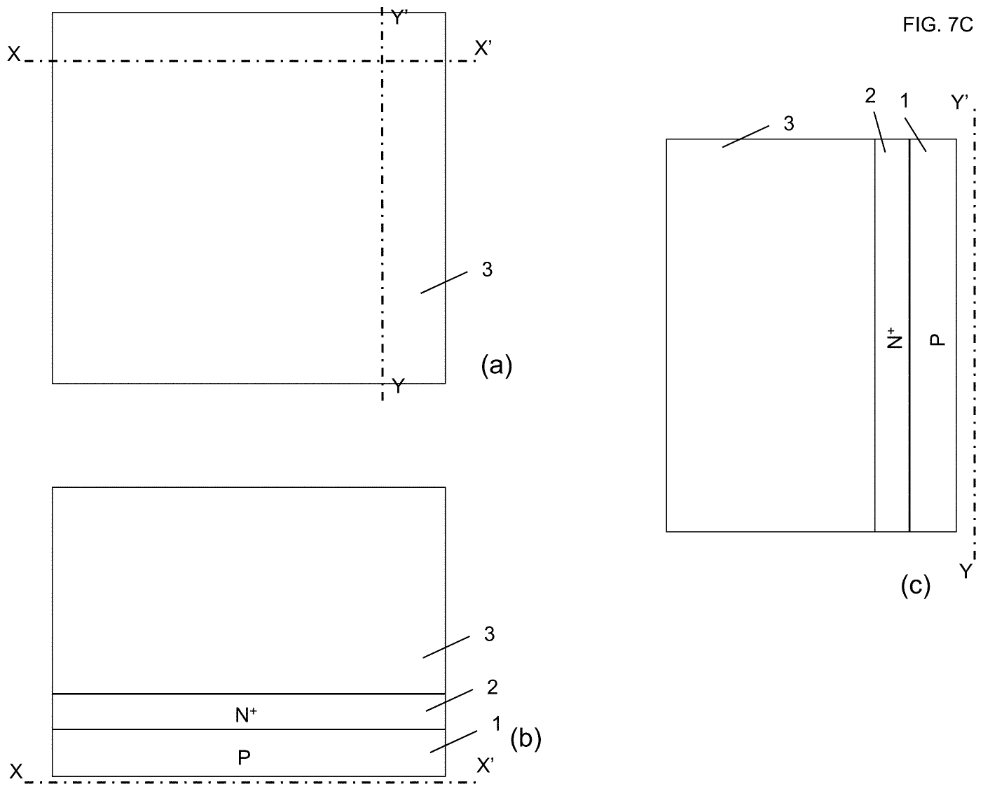

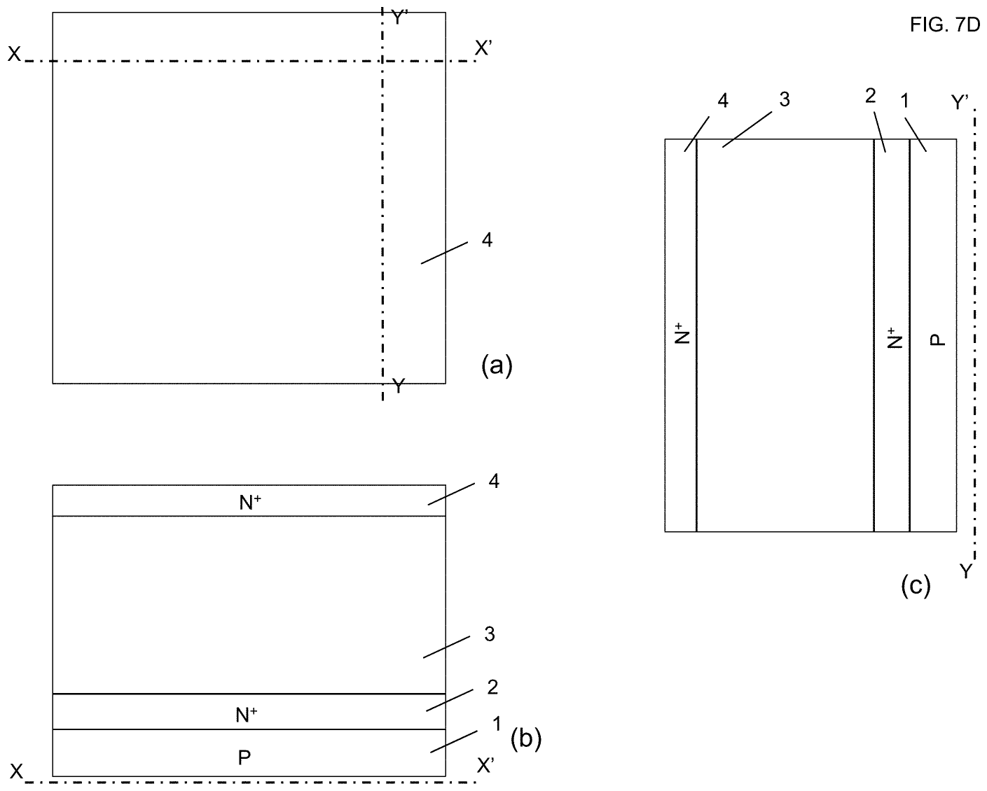

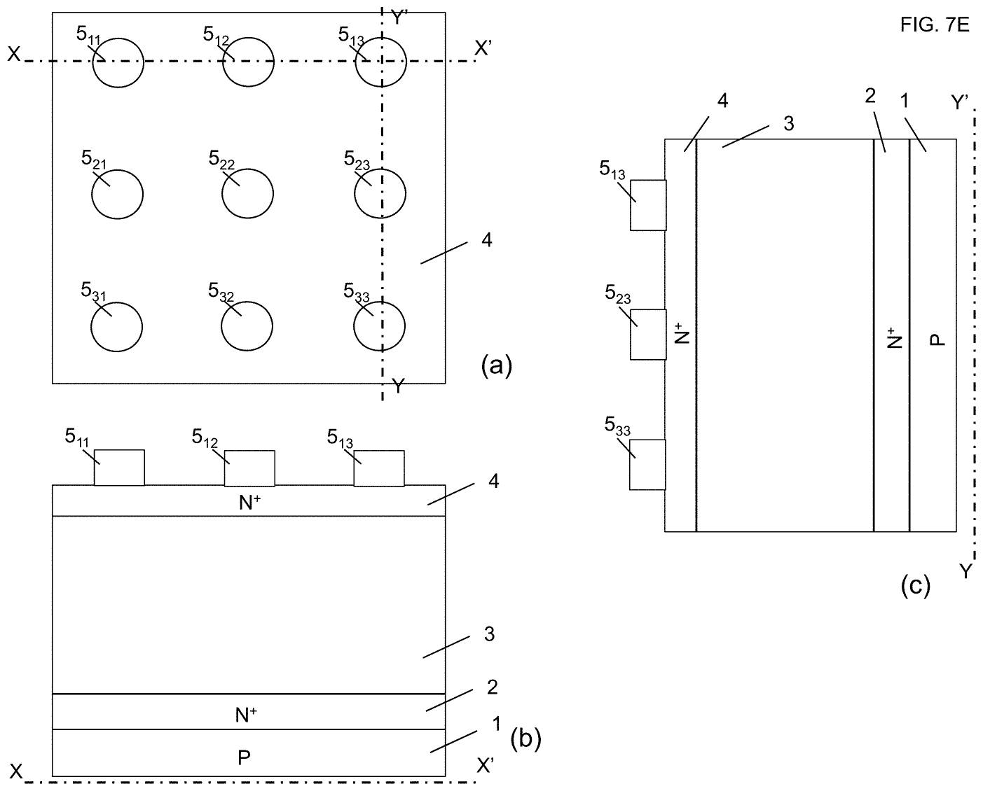

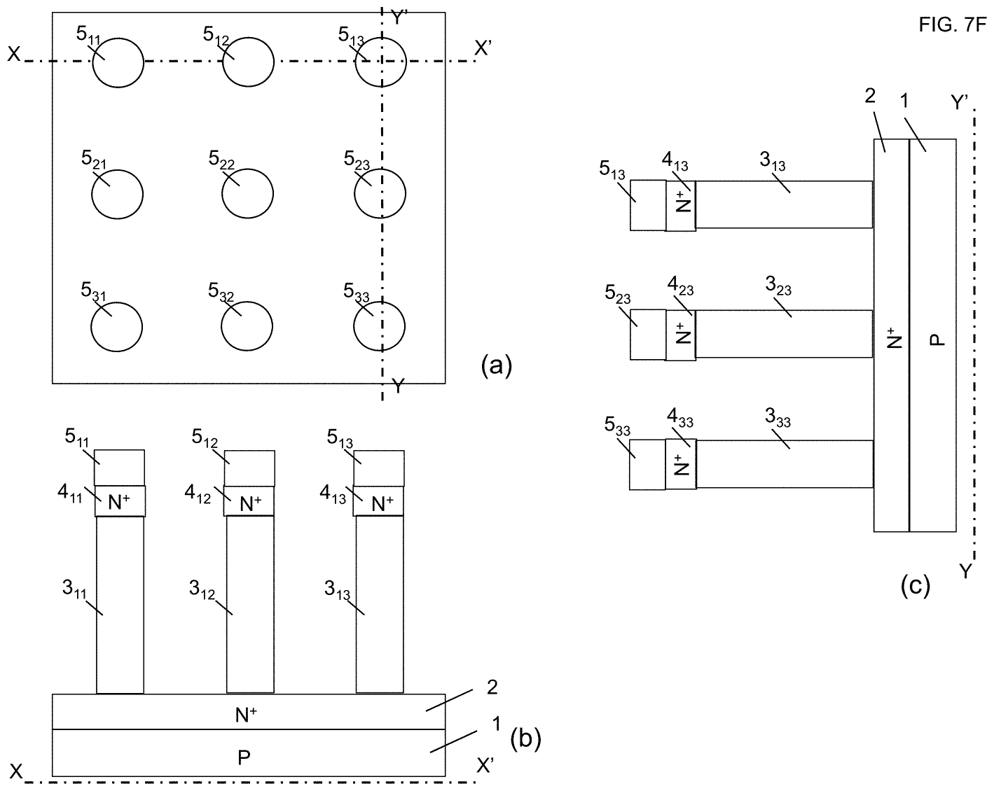

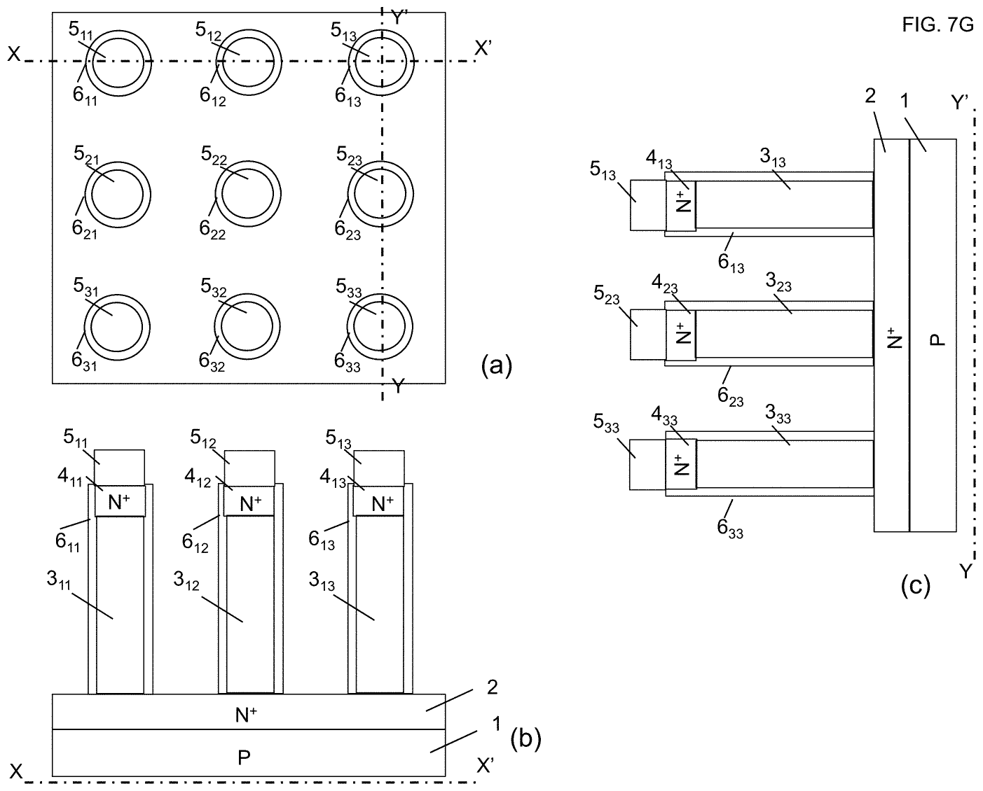

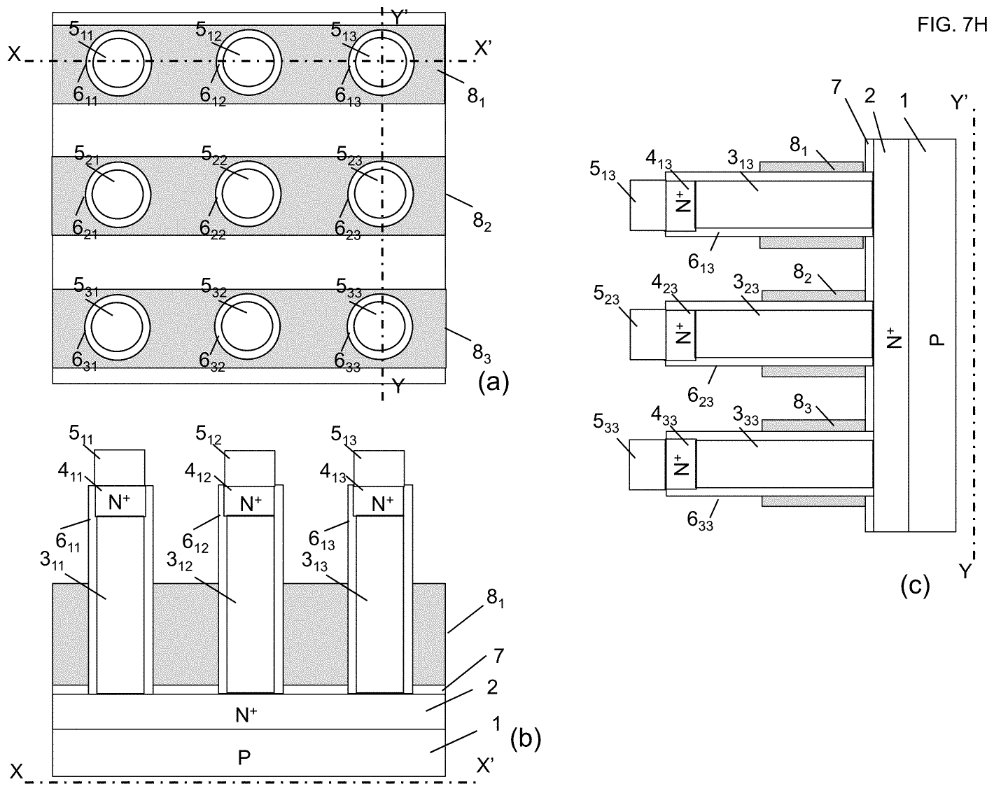

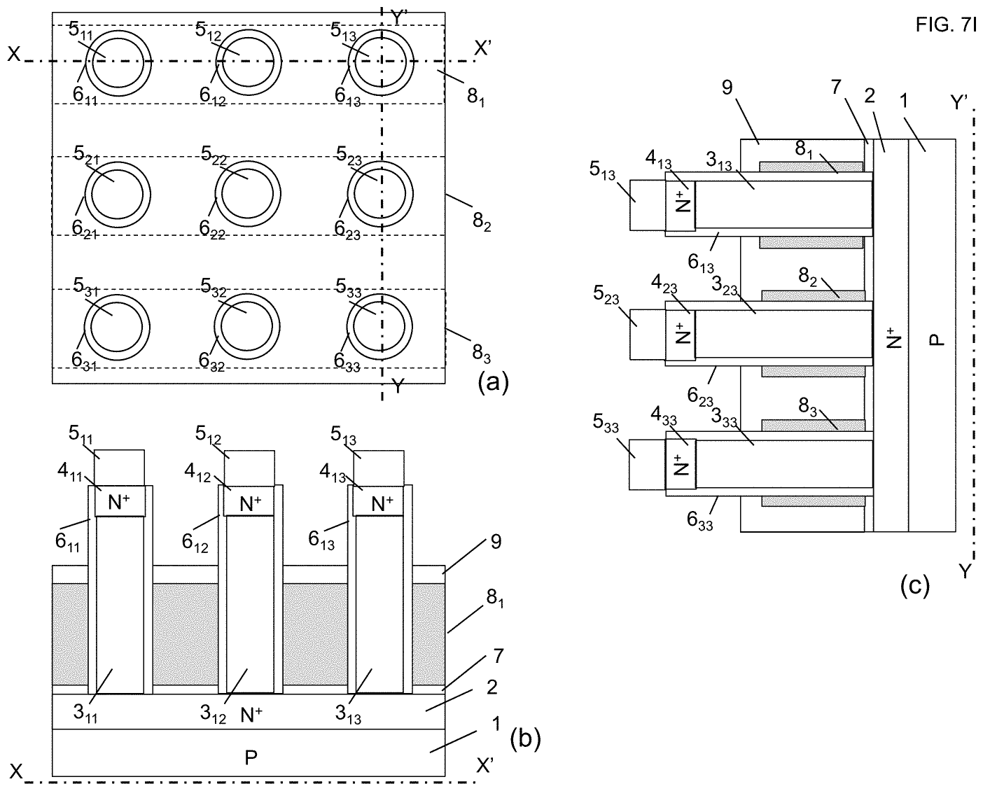

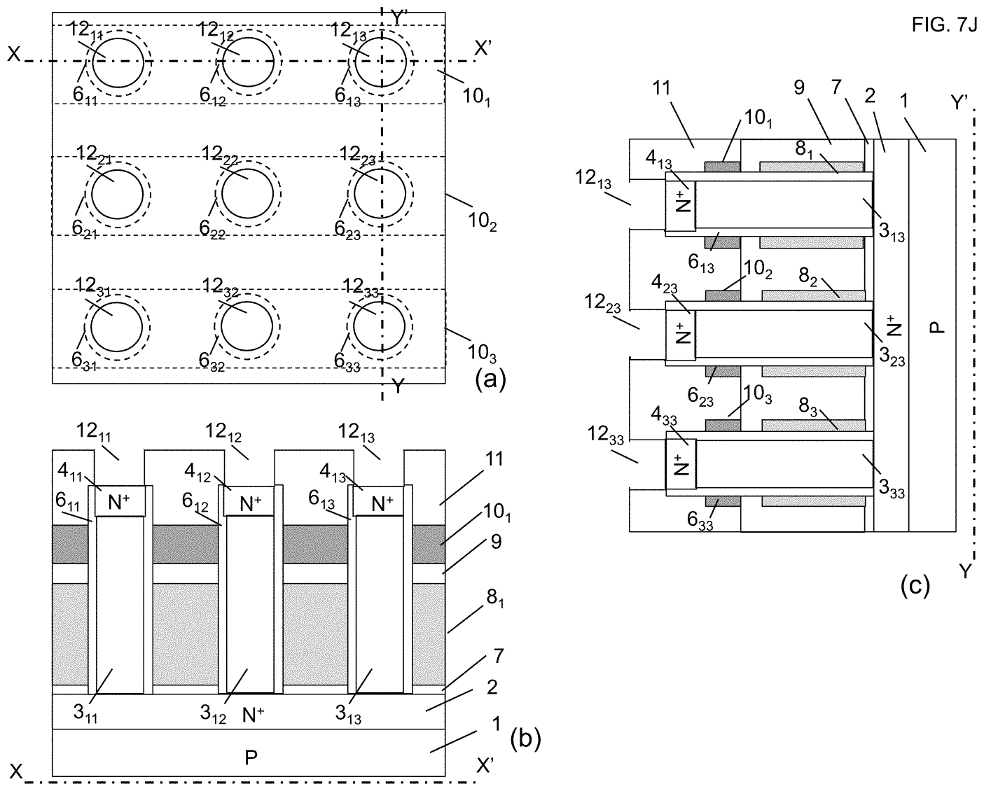

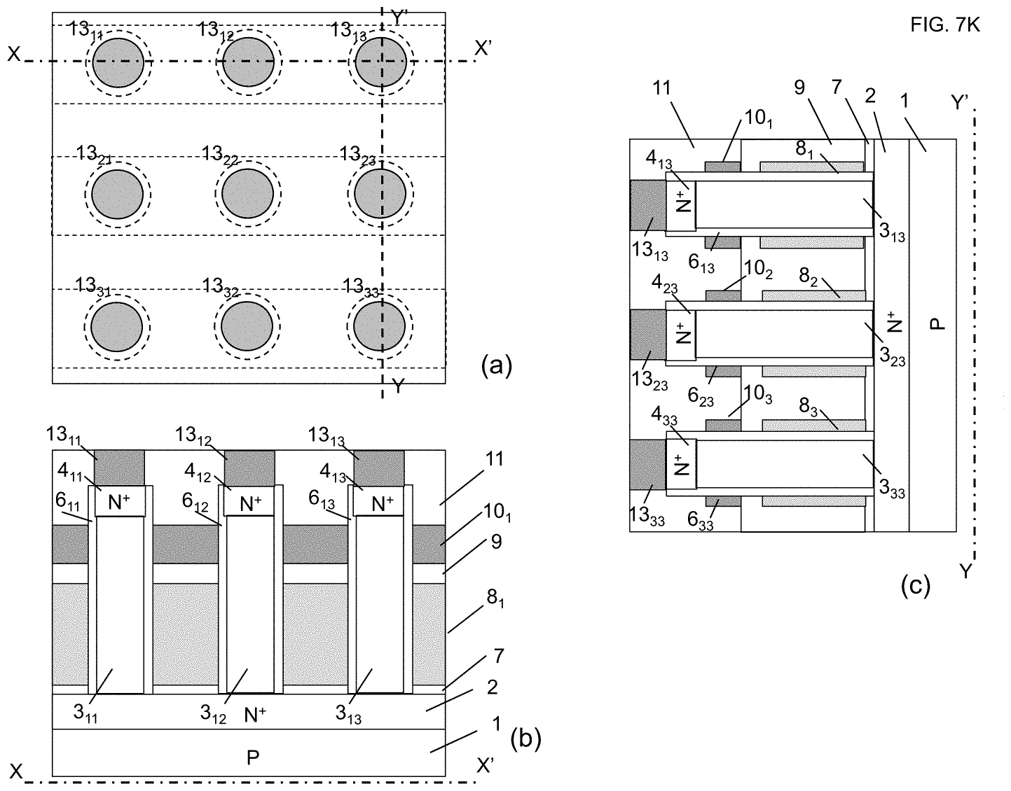

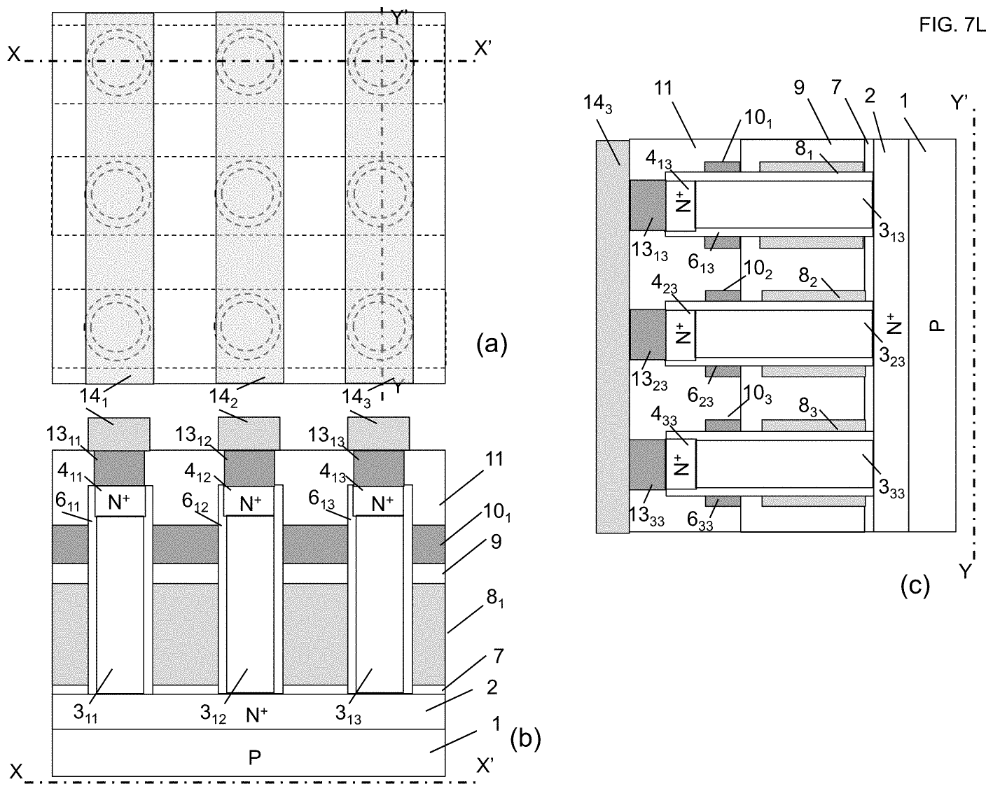

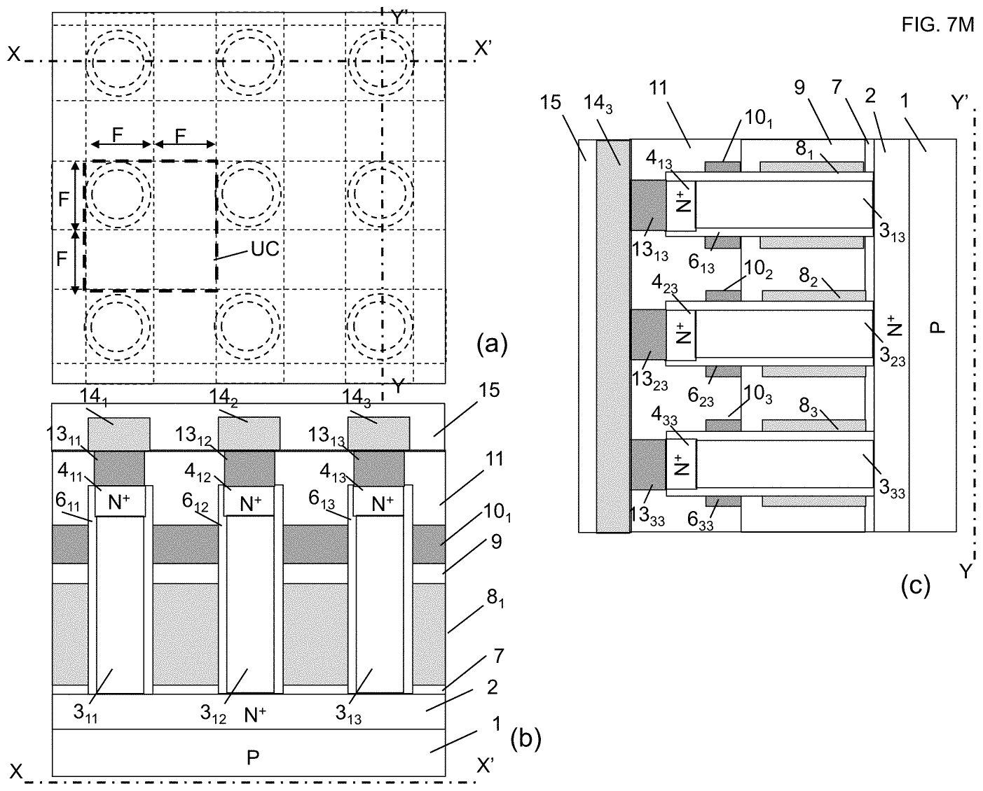

A method for manufacturing a dynamic flash memory according to a fourth embodiment will be described with reference to FIGS. 7AA to 7MC. FIGS. 7AA, 7BA, 7CA, 7DA, 7EA, 7FA, 7GA, 7HA, 7IA, 7JA, 7KA, 7LA, and 7MA are plan views, FIGS. 7AB, 7BB, 7CB, 7DB, 7EB, 7FB, 7GB, 7HB, 7IB, 7JB, 7KB, 7LB, and 7MB are vertical cross-sectional structural views taken along line X-X′ of FIGS. 7AA, 7BA, 7CA, 7DA, 7EA, 7FA, 7GA, 7HA, 7IA, 7JA, 7KA, 7LA, and 7MA, respectively, and FIGS. 7AC, 7BC, 7CC, 7DC, 7EC, 7FC, 7GC, 7HC, 7IC, 7JC, 7KC, 7LC, and 7MC are vertical cross-sectional structural views taken along line Y-Y′ of FIGS. 7AA, 7BA, 7CA, 7DA, 7EA, 7FA, 7GA, 7HA, 71A, 7JA, 7KA, 7LA, and 7MA, respectively. This embodiment describes the formation of a memory cell region composed of nine memory cells arranged in a matrix of three rows and three columns.

As illustrated in FIGS. 7AA to 7AC, a P-layer substrate 1 is prepared.

Then, as illustrated in FIGS. 7BA to 7BC, an N⁺ layer 2 (an example of a “first impurity layer” in the claims) is formed on the upper portion of the P-layer substrate 1.

Then, as illustrated in FIGS. 7CA to 7CC, a P layer 3 (an example of a “semiconductor layer” in the claims) is formed by epitaxial growth.

Then, as illustrated in FIGS. 7DA to 7DC, an N⁺ layer 4 is formed on the upper portion of the epitaxially grown P layer 3.

Then, as illustrated in FIGS. 7EA to 7EC, a mask material layer (not illustrated) is deposited on the upper portion of the N⁺ layer 4, and patterned mask material layers 5₁₁ to 5₃₃ (an example of a “first mask material layer” in the claims) are left in regions where Si pillars are to be formed. The mask material layers 5₁₁ to 5₃₃ may be formed by, for example, etching using an RIE (Reactive Ion Etching) method.

Then, as illustrated in FIGS. 7FA to 7FC, etching is performed up to the epitaxially grown P layer 3 using, for example, the RIE method such that the regions covered with the mask material layers 5₁₁ to 5₃₃ can be left to form P-layer Si pillars 3₁₁ to 3₃₃ (an example of a “semiconductor pillar” in the claims) having N⁺ layers 4₁₁ to 4₃₃ (an example of a “second impurity layer” in the claims) on top thereof.

Then, as illustrated in FIGS. 7GA to 7GC, hafnium oxide (HfO₂) layers 6₁₁ to 6₃₃ (an example of a “third insulating layer” in the claims) serving as gate insulating layers are formed by, for example, an ALD (Atomic Layer Deposition) method so as to surround the Si pillars 3₁₁ to 3₃₃. The HfO₂ layers 6₁₁ to 6₃₃ may be formed not only on the outer periphery portions of the P-layer Si pillars 3₁₁ to 3₃₃ but also over the N⁺ layer 2 so as to be connected to each other.

Then, as illustrated in FIGS. 7HA to 7HC, after a coating of a SiO₂ layer 7 is applied, the HfO₂ layers 6₁₁ to 6₃₃ are covered to form a TiN layer (not illustrated) serving as a gate conductor layer. Then, the TiN layer is etched by the RIE method to form TiN layers 8₁, 8₂, and 8₃ (an example of a “first gate conductor layer” in the claims), which are first gate conductor layers. The TiN layers 8₁, 8₂, and 8₃, which are the first gate conductor layers, serve as plate lines PL. Then, the portions of the HfO₂ layers 6₁₁ to 6₃₃ surrounded by the TiN layers 8₁, 8₂, and 8₃ each serve as the first gate insulating layer 103a (an example of a “first gate insulating layer” in the claims) in FIG. 1.

Then, as illustrated in FIGS. 7IA to 7IC, a coating of a SiO₂ layer 9 (an example of a “fourth insulating layer” in the claims) is applied. The SiO₂ layer 9 serves as an interlayer insulating layer between the plate line PL and the word line WL. The TiN layers 8₁, 8₂, and 8₃ and a TiN layer or another conductor layer may be formed at a bottom portion of the SiO₂ layer 9.

Then, as illustrated in FIGS. 7JA to 7JC, the HfO₂ layers 6₁₁ to 6₃₃ are covered to form a TiN layer (not illustrated) serving as a second gate conductor layer. Then, the TiN layer is etched by the RIE method to form TiN layers 10₁, 10₂, and 10₃ (an example of a “second gate conductor layer” in the claims). The TiN layers 10₁, 10₂, and 10₃, which are the second gate conductor layers, serve as word lines WL. Then, a coating of a SiO₂ layer 11 is applied. Then, the mask material layers 5₁₁ to 5₃₃ are removed by etching to form voids 12₁₁ to 12₃₃. Since the voids 12₁₁ to 12₃₃ are formed by removing the mask material layers 5₁₁ to 5₃₃, the voids 12₁₁ to 12₃₃ are formed by self-alignment with the P-layer Si pillars 3₁₁ to 333 and the N⁺ layers 4₁₁ to 4₃₃. The portions of the HfO₂ layers 6₁₁ to 6₃₃ surrounded by the TiN layers 10₁, 10₂, and 10₃ each serve as the second gate insulating layer 103b (an example of a “second gate insulating layer” in the claims) in FIG. 1.

Then, as illustrated in FIGS. 7KA to 7KC, voids 12₁₁ to 12₃₃ are filled with conductor layers, for example, tungsten W 13₁₁ to 13₃₃, by a damascene process.

Then, as illustrated in FIGS. 7LA to 7LC, for example, a conductor layer (not illustrated) of copper CU is formed. Then, the copper CU layer is etched by the RIE method to form copper CU layers 14_{1, 142,} and 143, which are wiring conductor layers connected to the tungsten W 13₁₁ to 13₃₃. The copper Cu layers 14₁, 14₂, and 14₃, which are wiring conductor layers, serve as bit lines BL. The copper CU layers 14_{1, 142,} and 143 may be conductor layers composed of a single layer or a plurality of layers of any other material. The tungsten W 1311 to 1333 and the copper CU layers 14₁, 14₂, and 14₃ may be formed simultaneously by other metallic conductor layers.

Finally, as illustrated in FIGS. 7MA to 7MC, a coating of a SiO₂ layer 15 serving as a protective film is applied, and a dynamic flash memory cell region is completed. In FIG. 7MA, the size of a one-cell region UC surrounded by dotted lines is given by 4F², where F represents the diameter of each of the Si pillars 3₁₁ to 333 and the distance between the Si pillars 3₁₁ to 3₃₃. In the present dynamic flash memory cell, the TiN layers 8₁, 8₂, and 8₃, which are connected to the plate lines PL, and the TiN layers 10₁, 10₂, and 10₃, which are connected to the word lines WL, extend in the same direction, namely, the direction of line X-X′. The copper Cu layers 14₁, 14₂, and 14₃, which are connected to the bit lines BL, extend in the direction of line Y-Y′ perpendicular to the word lines WL and the plate lines PL.

This embodiment has the following features.

### (Feature 1)

In this embodiment, as illustrated in FIGS. 7AA to 7MC, an N⁺ layer 2 is formed on the upper portion of a P-layer substrate 1. Then, a P layer 3 is formed by epitaxial growth, an N⁺ layer 4 is formed on the upper portion of the epitaxially grown P layer 3, a mask material layer is deposited on the upper portion of the N⁺ layer 4 and is etched by the RIE method such that patterned mask material layers 5₁₁ to 5₃₃ can be left in regions where Si pillars are to be formed to form Si pillars. Then, etching is performed up to the epitaxially grown P layer 3 using, for example, the RIE method such that the regions covered with the mask material layers 5₁₁ to 5₃₃ can be left to form P-layer Si pillars 3₁₁ to 3₃₃ having N⁺ layers 4₁₁ to 4₃₃ on top thereof. Accordingly, the P-layer Si pillars 3₁₁ to 333 including the N⁺ layers 2 and 4₁₁ to 4₃₃ in upper and lower portions thereof can be simultaneously formed. This leads to simplified manufacturing of the present dynamic flash memory.

### (Feature 2)

In this embodiment, for example, hafnium oxide (HfO₂) layers 6₁₁ to 6₃₃ serving as gate insulating layers are formed by the ALD method so as to surround the Si pillars 3₁₁ to 3₃₃. Then, after a coating of a SiO₂ layer 7 is applied, the HfO₂ layers 6₁₁ to 6₃₃ are covered to form a TiN layer serving as a first gate conductor layer. Then, the TiN layer is etched by the RIE method to form TiN layers 8₁, 8₂, and 8₃, which are first gate conductor layers. The TiN layers 8₁, 8₂, and 8₃, which are the first gate conductor layers, serve as plate lines PL. As a result, a one-cell region UC, which is given by 4F², is formed, where F represents a minimum processing size, which is the distance between the Si pillars 3₁₁ to 3₃₃.

### (Feature 3)

As illustrated in FIGS. 7JA to 7LC, since voids 12₁₁ to 12₃₃ are formed by removing the mask material layers 5₁₁ to 5₃₃, the voids 12₁₁ to 12₃₃, which are contact holes, are formed by self-alignment with the P-layer Si pillars 3₁₁ to 3₃₃ and the N⁺ layers 4₁₁ to 4₃₃. As a result, high integration of the present dynamic flash memory can be achieved.

### Fifth Embodiment

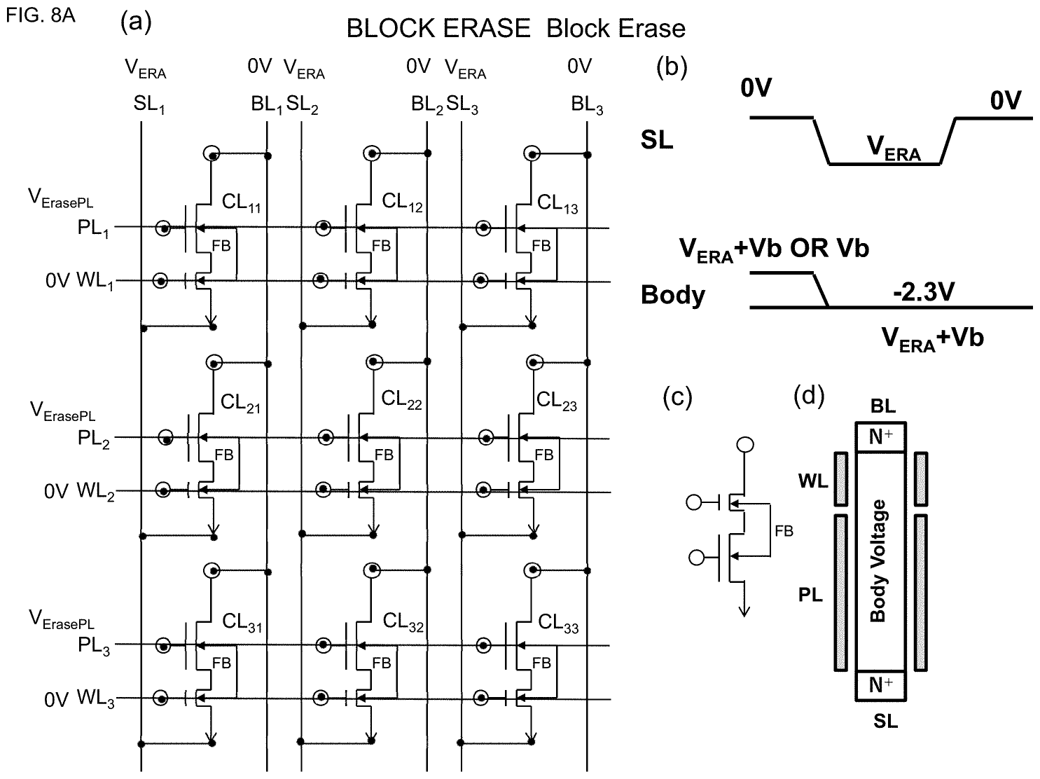

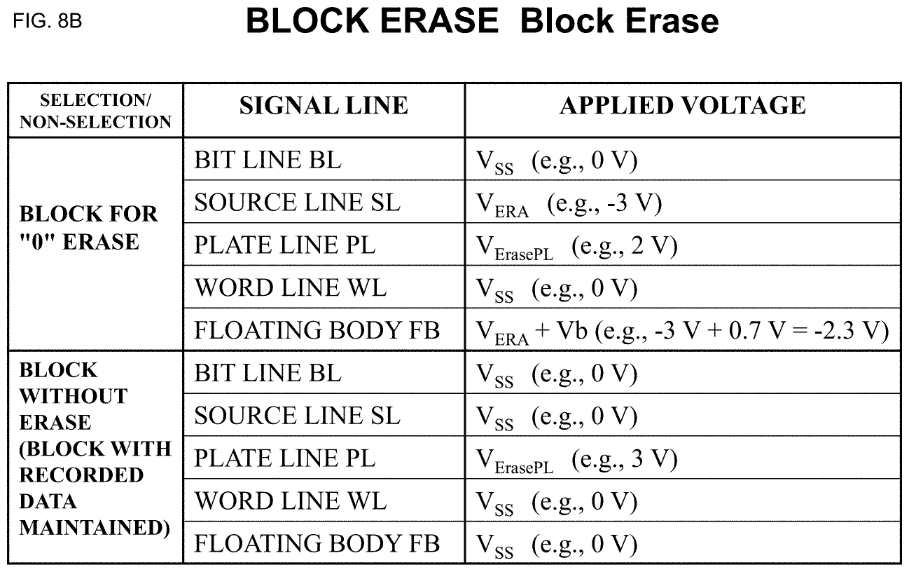

A block erase operation of a dynamic flash circuit according to a fifth embodiment will be described with reference to FIGS. 8AA to 8AD and FIG. 8B.

FIG. 8AA illustrates a circuit diagram of a memory block selected for a block erase. Here, a total of nine memory cells CL₁₁ to CL₃₃ arranged in a matrix of three rows and three columns are illustrated as memory cells. An actual memory block is larger than the illustrated matrix. The memory cells are connected to source lines SL₁ to SL₃, bit lines BL₁ to BL₃, plate lines PL₁ to PL₃, and word lines WL₁ to WL₃. As illustrated in FIGS. 8AB to 8AD and FIG. 8B, an erase voltage V_{ERA} is applied to the source lines SL₁ to SL₃ of a memory block selected for a block erase. At this time, the bit lines BL₁ to BL₃ are at V_{SS} and the word lines WL₁ to WL₃ are at V_{SS}. V_{SS} is, for example, 0 V. While a fixed voltage V_{ErasePL} is applied to the plate lines PL₁ to PL₃ regardless of whether block erase is selected, V_{ErasePL} may be applied to the plate lines PL₁ to PL₃ of a selected block, and V_{SS} may be applied to the plate lines PL₁ to PL₃ of an unselected block. The voltage setting of the signal lines is controlled in the way described above to set all the logical storage data “1” and “0” accumulated in the floating body FB of each memory cell to “0”. Accordingly, the logical storage data may be either in the write state “1” or the erase state “0”. The channel region 102 of the floating body in the erase state “0” has a potential of V_{ERA}+Vb. Here, for example, V_{ERA}=−3 V and Vb=0.7 V. Then, the potential of the channel region 102 of the floating body is −2.3 V. Vb is the built-in voltage across a PN junction between the N⁺ layer serving as the source line SL and the channel region 102 of the floating body and is about 0.7 V. When the channel region 102 is negatively biased to −2.3 V, the back-bias effect increases the threshold voltage of the second N-channel MOS transistor region at the input of the word line WL.

Erasing, which is performed in units of memory blocks, requires a cache memory for temporarily storing data of a memory block and a logical address/physical address conversion table of the memory block, which may be disposed in the dynamic flash memory device or in a system that handles the dynamic flash memory device.

This embodiment has the following features.

The erase voltage VER., is applied to the source lines SL₁ to SL₃ of a memory block selected for a block erase. As a result, all the logical storage data “1” and “0” accumulated in the channel region 102 of the floating body of each memory cell in the selected block are set to “0”. The channel region 102 in the erase state “0” has a potential of V_{ERA}+Vb. When the channel region 102 is negatively biased, the back-bias effect increases the threshold voltage of the second N-channel MOS transistor region to which the word line WL is input. Accordingly, the block erase operation can be easily implemented.

### Sixth Embodiment

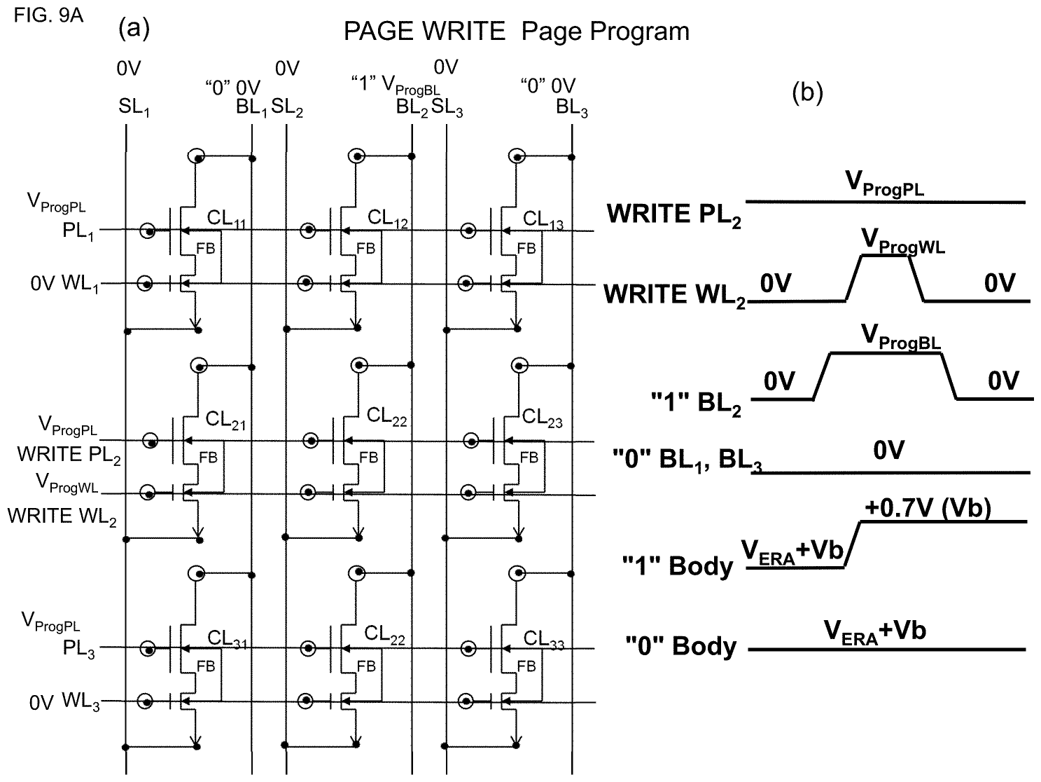

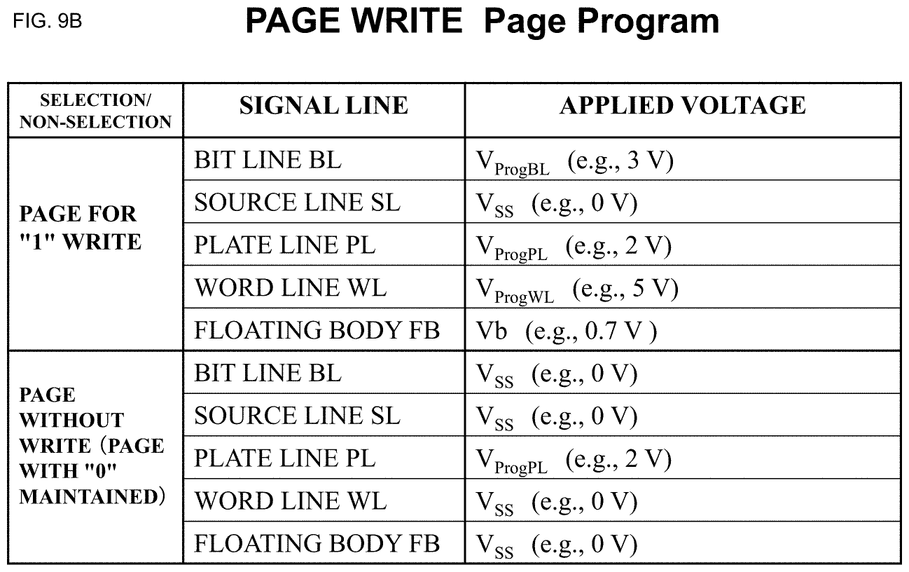

A page write operation of a dynamic flash circuit according to a sixth embodiment will be described with reference to FIGS. 9AA and 9AB and FIG. 9B.

FIG. 9AA illustrates a circuit diagram of a memory block selected for a page write. V_{ProgBL} is applied to the bit line BL₂ for writing “1”, and V_{SS} is applied to the bit lines BL₁ and BL₃ for maintaining the erase state “0” without performing writing. Here, for example, V_{ProgBL} is 3 V and V_{SS} is 0 V. V_{ProgWL} is applied to the word line WL₂ for performing a page write, and V_{SS} is applied to the word lines WL₁ and WL₃ for performing no page write. Here, for example, V_{ProgWL} is 5 V and V_{SS} is 0 V. V_{ProgPL} is applied to the plate lines PL₁ to PL₃ regardless of selection/non-selection of a page write. Here, for example, V_{ProgPL} is 2 V. The voltage setting of the signal lines is controlled in the way described above to perform a page write. In the memory cell CL₂₂, which is connected to the bit line BL₂ set at V_{ProgBL}, the word line WL2 set at V_{ProgWL}, and the plate line PL₂ set at V_{ProgPL}, a source-side impact ionization phenomenon occurs between two gate layers to which the word line WL₂ and the plate line PL₂ are input. As a result, of the pairs of electrons and positive holes generated by the source-side impact ionization phenomenon, the positive holes, which are majority carriers in the channel region 102, are accumulated in the channel region 102 of the floating body in the memory cell CL₂₂, whereby the voltage of the channel region 102 is increased to Vb and “1” writing is performed. Here, Vb is the built-in voltage across a PN junction between the source N⁺ layer to which the source line SL is connected and the channel region 102 and is about 0.7 V. When the channel region 102 is positively biased to 0.7 V, the back-bias effect decreases the threshold voltage of the second N-channel MOS transistor region to which the word line WL is input. Since V_{SS} is applied to the bit lines BL₁ and BL₃ connected to the memory cells CL₂₁ and CL₂₃, which are kept in the erase state without writing “1” for the same selected page, no current flows from the drain to the source of the memory cells CL₂₁ and CL₂₃, and no source-side impact ionization phenomenon occurs. In the memory cells CL₂₁ and CL₂₃, the logical storage data of the erase state “0” is maintained.

This embodiment has the following features.

In response to the start of the page write operation, V_{ProgBL} is applied to the bit line BL₂ for writing “1”, and V_{SS} is applied to the bit lines BL₁ and BL₃ for maintaining the erase state “0” without performing writing. In the memory cell CL₂₂, which is connected to the bit line BL₂ set at V_{ProgBL}, the word line WL₂ set at V_{ProgWL}, and the plate line PL₂ set at V_{ProgPL}, a source-side impact ionization phenomenon occurs between two gate layers to which the word line WL₂ and the plate line PL₂ are input. As a result, of the pairs of electrons and positive holes generated by the source-side impact ionization phenomenon, the positive holes, which are majority carriers in the channel region 102, are accumulated in the channel region 102 of the floating body in the memory cell CL₂₂, whereby the voltage of the channel region 102 is increased to Vb and “1” writing is performed. When the channel region 102 is positively biased, the back-bias effect decreases the threshold voltage of the second N-channel MOS transistor region to which the word line WL is input. As a result, since V_{SS} is applied to the bit lines BL₁ and BL₃ connected to the memory cells CL₂₁ and CL₂₃, which are kept in the erase state without writing “1” for the same selected page, no current flows from the drain to the source of the memory cells CL₂₁ and CL₂₃, and no source-side impact ionization phenomenon occurs. In the memory cells CL₂₁ and CL₂₃, the logical storage data of the erase state “0” is maintained.

### Seventh Embodiment

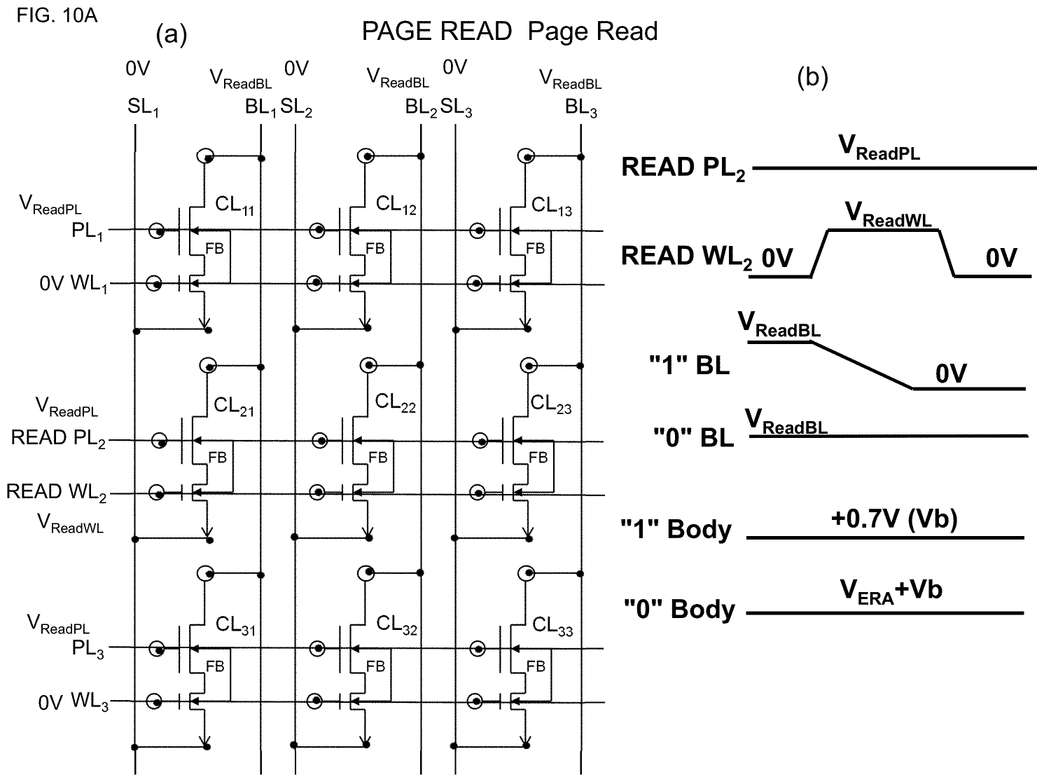

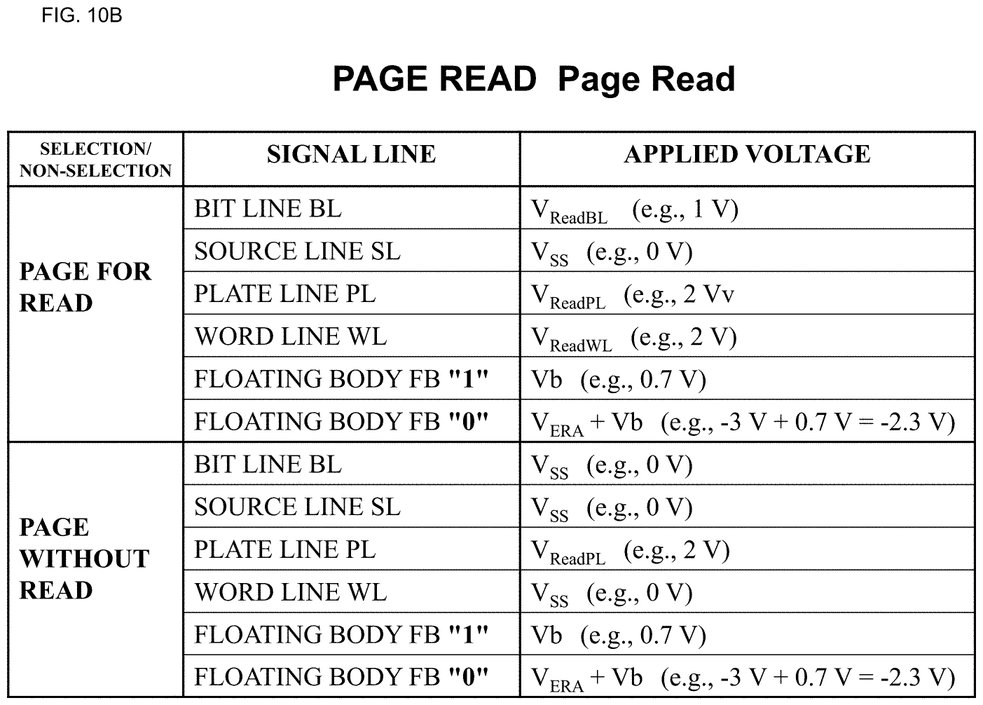

A page read operation of a dynamic flash circuit according to a seventh embodiment will be described with reference to FIGS. 10AA and 10AB and FIG. 10B.

V_{SS} is applied to the source lines SL₁ to SL₃, and V_{ReadBL} is applied to the bit lines BL₁ to BL₃. Here, for example, V_{SS} is 0 V and V_{ReadBL} is 1 V. V_{ReadWL} is applied to the selected word line WL₂ for performing a page read. Here, for example, V_{ReadWL} is 2 V. V_{ReadPL} is applied to the plate lines PL₁ to PL₃ regardless of selection/non-selection of a page read. Here, for example, V_{ReadPL} is 2 V. The voltage setting of the signal lines is controlled in the way described above to perform a page read. In a memory cell in the erase state “0” in which the potential of the channel region 102 is given by V_{ERA}+Vb, the threshold voltage is high, and no memory cell current flows. The bit line BL is kept at V_{ReadBL} without being discharged. In a memory cell in the write state “1” in which the potential of the channel region 102 is Vb, in contrast, the threshold voltage is low, and the memory cell current flows. The bit line BL is discharged and is changed from V_{ReadBL} to V_{SS}. The two potential states of the bit line BL are read by a sense amplifier to determine whether the logical storage data in the memory cell is “1” or “0” (not illustrated).

This embodiment has the following features.

In response to the start of the page read operation, in a memory cell in the erase state “0” in which the potential of the floating body FB is given by V_{ERA}+Vb, the threshold voltage is high, and no memory cell current flows. The bit line BL is kept at V_{ReadBL} without being discharged. In a memory cell in the write state “1” in which the potential of the floating body FB is Vb, in contrast, the threshold voltage is low, and the memory cell current flows. The bit line BL is discharged and is changed from V_{ReadBL} to V_{SS}. The two bit-line potential states are read by a sense amplifier. This makes it possible to determine whether the logical storage data in the memory cell is “1” or “0”.

### Eighth Embodiment

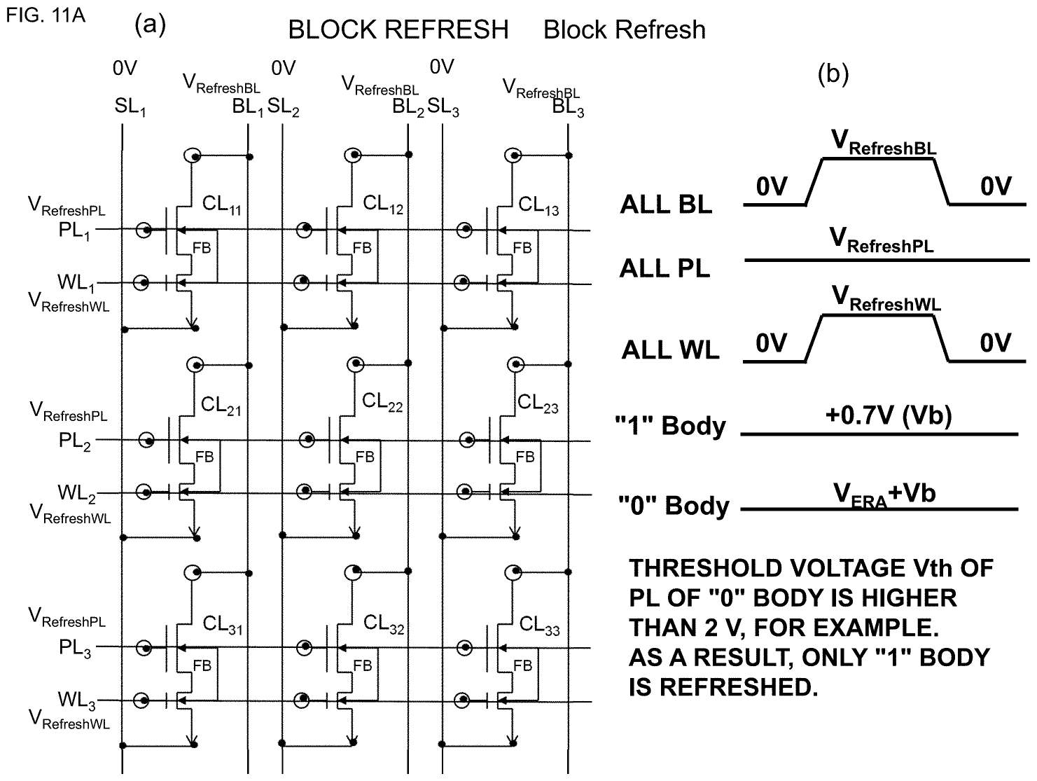

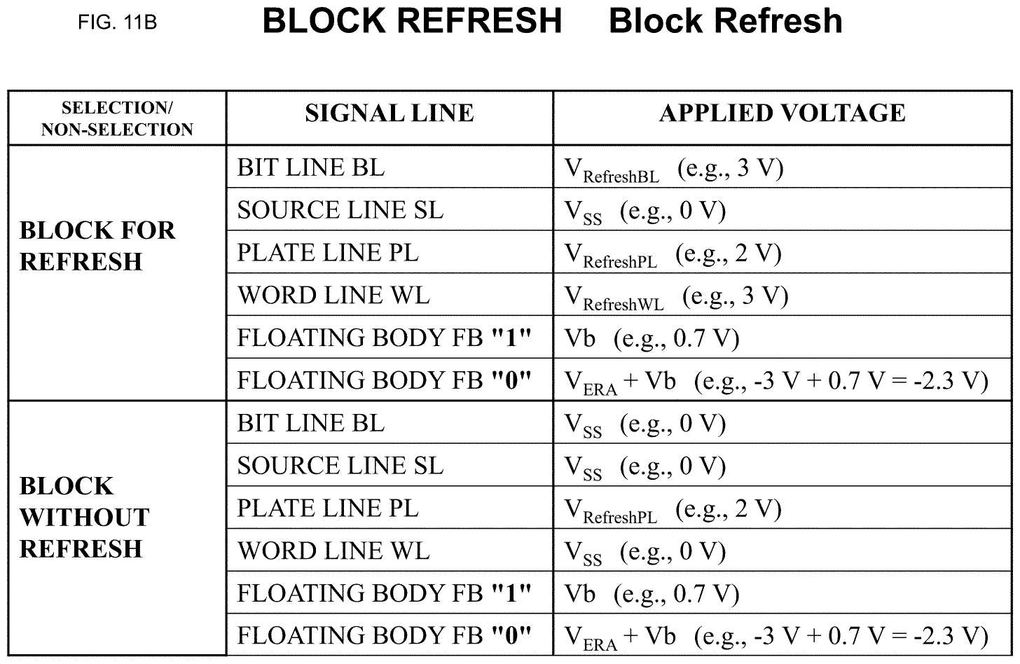

A block refresh operation of a dynamic flash circuit according to an eighth embodiment will be described with reference to FIGS. 11AA and 11AB and FIG. 11B.

As illustrated in FIGS. 11AA and 11AB, V_{SS} is applied to the source lines SL₁ to SL₃ of a selected memory block to be refreshed, and V_{RefreshBL} is applied to the bit lines BL₁ to BL₃ of the selected memory block. Here, for example, V_{SS} is 0 V and V_{RefreshBL} is 3 V. While a fixed voltage V_{RefreshPL} is applied to the plate lines PL₁ to PL₃ regardless of whether block refresh is selected, V_{RefreshPL} may be applied to the plate lines PL₁ to PL₃ of a selected block, and V_{SS} may be applied to the plate lines PL₁ to PL₃ of an unselected block. V_{RefreshWL} is applied to the word lines WL₁ to WL₃ of the memory block to be refreshed. Here, for example, V_{RefreshPL} is 2 V and V_{RefreshWL} is 3 V. The voltage setting of the signal lines is controlled in the way described above, whereby since the threshold voltages of the first N-channel MOS transistor region to which the plate line PL is connected and the second N-channel MOS transistor region to which the word line WL is connected are low at the logical storage data “1” accumulated in the channel region 102 of the floating body of the memory cell, a memory cell current flows even if the applied voltages are the voltages V_{RefreshWL} and V_{RefreshPL}, which are lower than the voltages for a page write. The source-side impact ionization phenomenon between the two gates generates positive holes, which are accumulated in the channel region 102. As a result, the memory cells in the write state “1” are refreshed in units of memory blocks. FIG. 11B summarizes an example of voltage conditions for the main node contacts at the time of a block refresh.

Although memory cells in the erase state “0” cannot be refreshed in units of memory blocks, memory block data is temporarily stored in a memory chip or in a cache in a system, and the memory block is subjected to block erase to rewrite the logical storage data to refresh the memory cells. Alternatively, a conversion table between a logical block address and a physical block address may be included in a memory chip or a system, and data after refresh may be stored at a physical block address different from the previous one.

This embodiment has the following features.

In response to the start of the block refresh operation, since the threshold voltages of the first N-channel MOS transistor region to which the plate line PL is connected and the second N-channel MOS transistor region to which the word line WL is connected are low at the logical storage data “1” accumulated in the channel region 102 of the floating body of the memory cell, a memory cell current flows even if the applied voltages are the voltages V_{RefreshWL} and V_{RefreshPL}, which are lower than the voltages for a page write. The source-side impact ionization phenomenon between the two gates generates positive holes, which are accumulated in the channel region 102 of the floating body. As a result, the memory cells in the write state “1” are refreshed in units of memory blocks.

### Ninth Embodiment

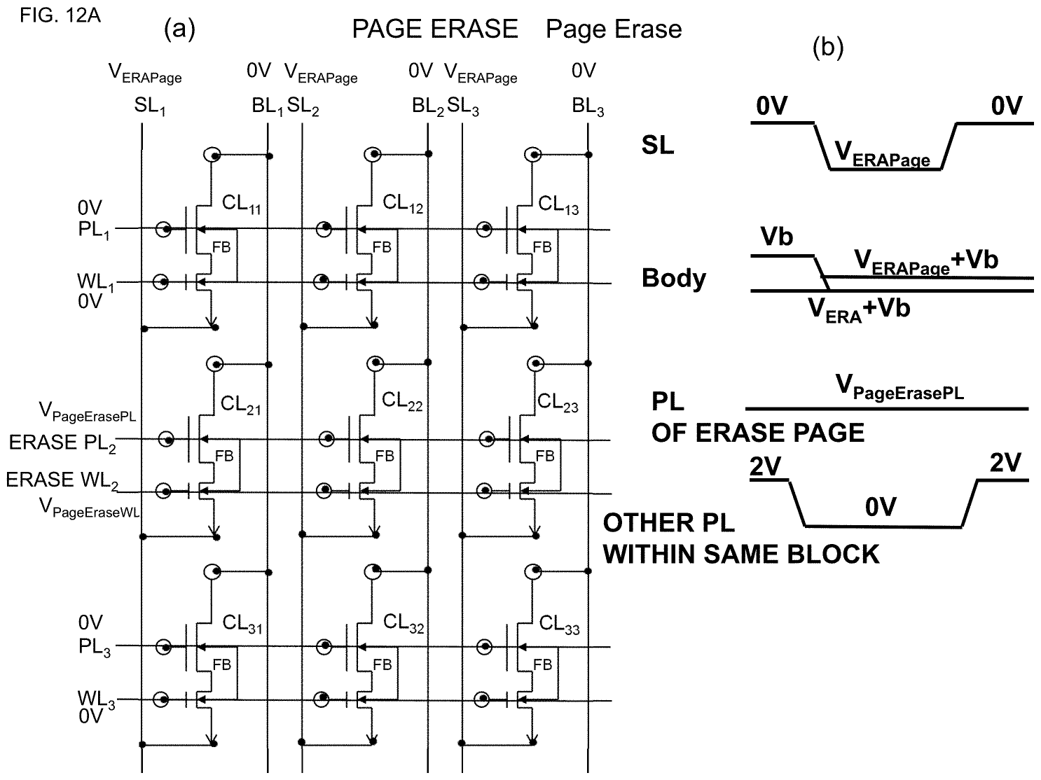

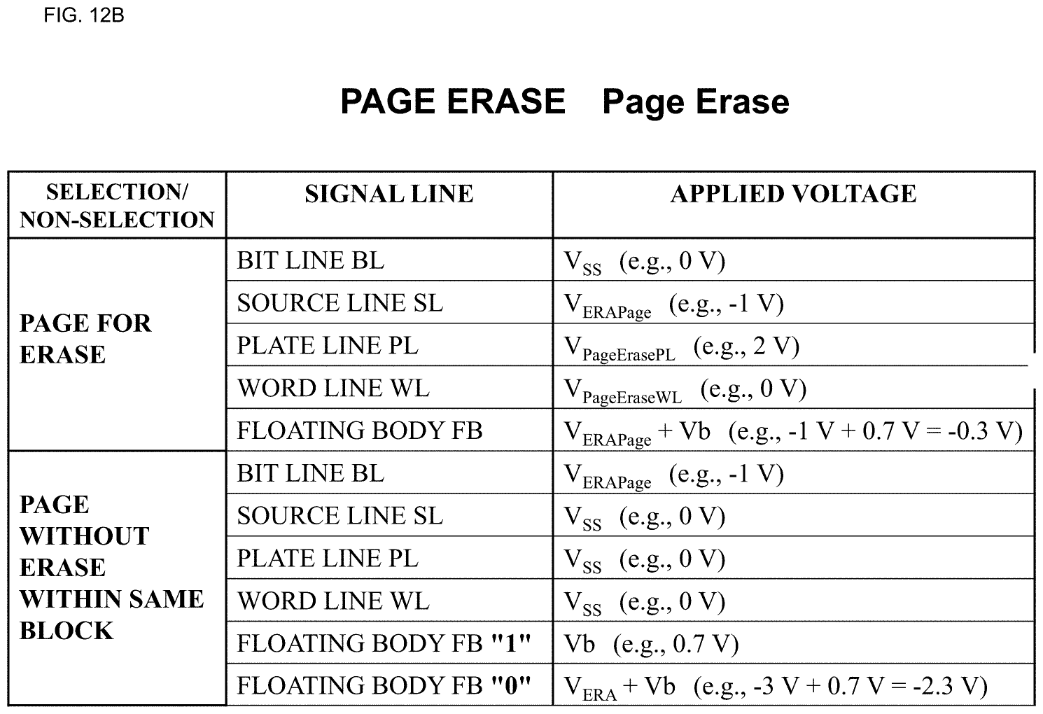

A page erase operation of a dynamic flash circuit according to a ninth embodiment will be described with reference to FIGS. 12AA and 12AB and FIG. 12B.

As illustrated in FIG. 12AA and FIG. 12AB, when the page erase operation is started, the voltages of the plate lines PL other than the plate line PL connected to a memory cell to be subjected to the page erase are decreased from the fixed voltage that is always applied to V_{SS}. Since the gate to which the plate line PL is connected has a large gate capacitance, the potential of the floating body FB of the memory cell in which the data “1” and “0” are stored is lowered due to the capacitive coupling. As a result, the data “1”, which has already been written, is protected from being rewritten by the page erase. Then, V_{PageErasePL} is applied only to the plate line PL₂ connected to the memory cell to be subjected to the page erase. V_{PageErasePL} is, for example, 2 V. At this time, V_{PageEraseWL} is applied to the word line WL₂ connected to the memory cell to be subjected to the page erase. V_{PageEraseWL} is equal to V_{SS} and is 0 V, for example. V_{ERAPage} is applied to the source lines SL₁ to SL₃. V_{ERAPage} is set to a voltage higher than the bit-line application voltage V_{ERA} for a block erase. For example, V_{ERA} is −3V, whereas V_{ERAPage} is −1 V. This is to protect the data in the memory cell already set to “1” write and “0” erase maintenance in the same block to be subjected to the page erase from being rewritten by the page erase.

After the page erase, the page write operation of the dynamic flash circuit according to the sixth embodiment illustrated in FIGS. 9AA and 9AB and FIG. 9B is performed, which makes it possible to write new data in the page after the page erase. FIG. 12B summarizes an example of voltage conditions for the main node contacts at the time of a page erase.

This embodiment has the following features.

In response to the start of the page erase operation, the voltages of the plate lines PL other than the plate line PL connected to a memory cell to be subjected to the page erase are decreased from the fixed voltage that is always applied to V_{SS}. Since the gate to which the plate line PL is connected has a large gate capacitance, the potential of the floating body FB of the memory cell in which the data “1” and “0” are stored is lowered due to the capacitive coupling. As a result, the data “1”, which has already been written, is protected from being rewritten by the page erase. Then, V_{PageErasePL} is applied only to the plate line PL₂ connected to the memory cell to be subjected to the page erase. V_{ERAPage} is applied to the source lines SL₁ to SL₃. This ensures that the page erasure is performed.

### Tenth Embodiment

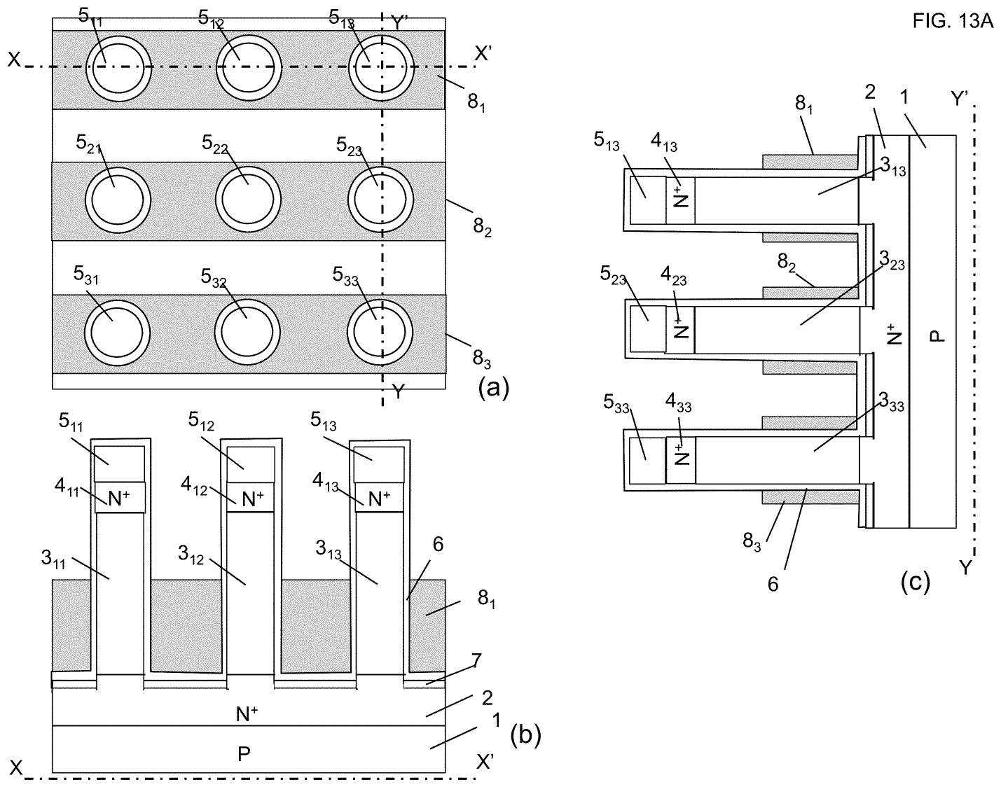

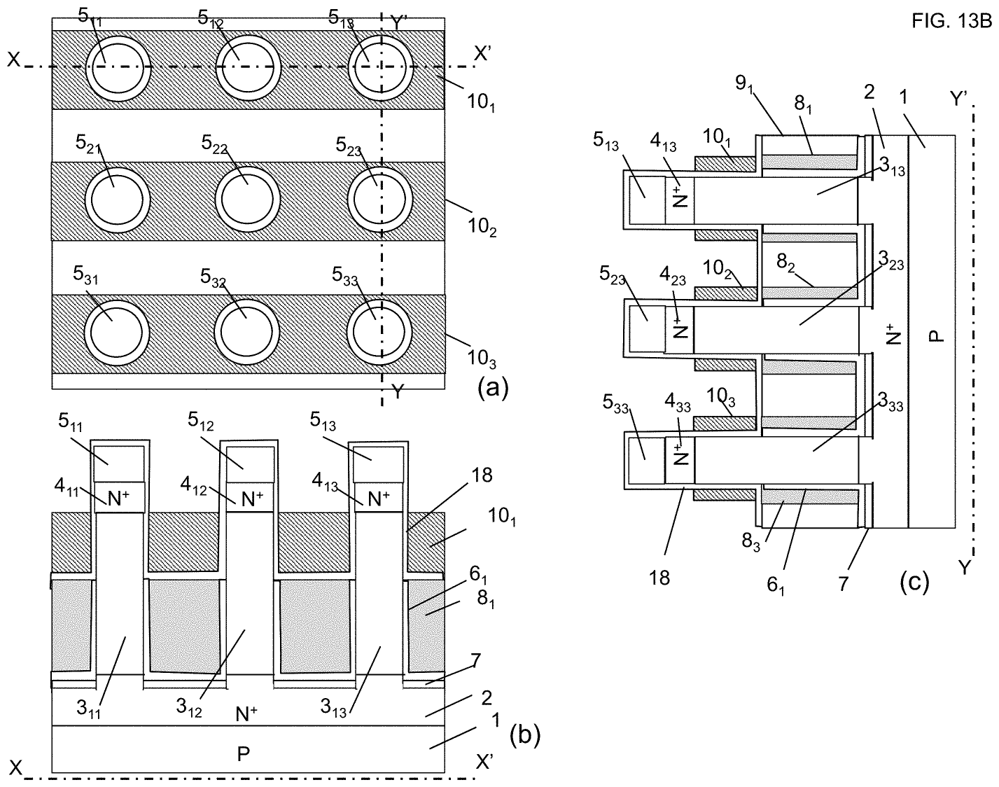

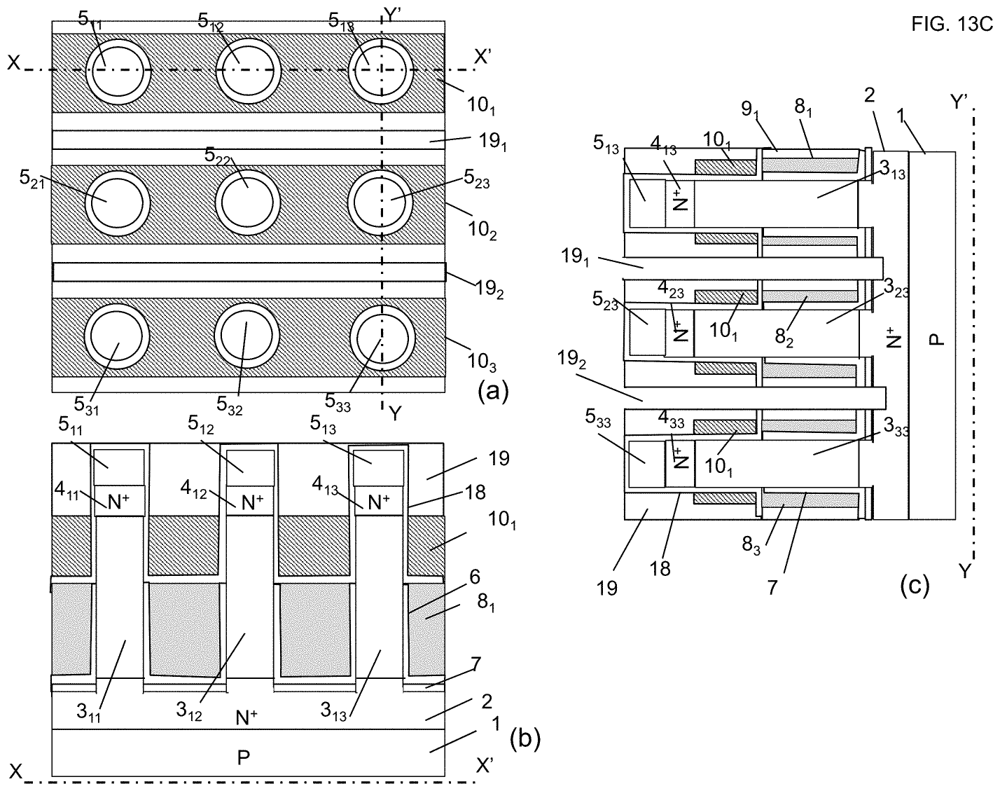

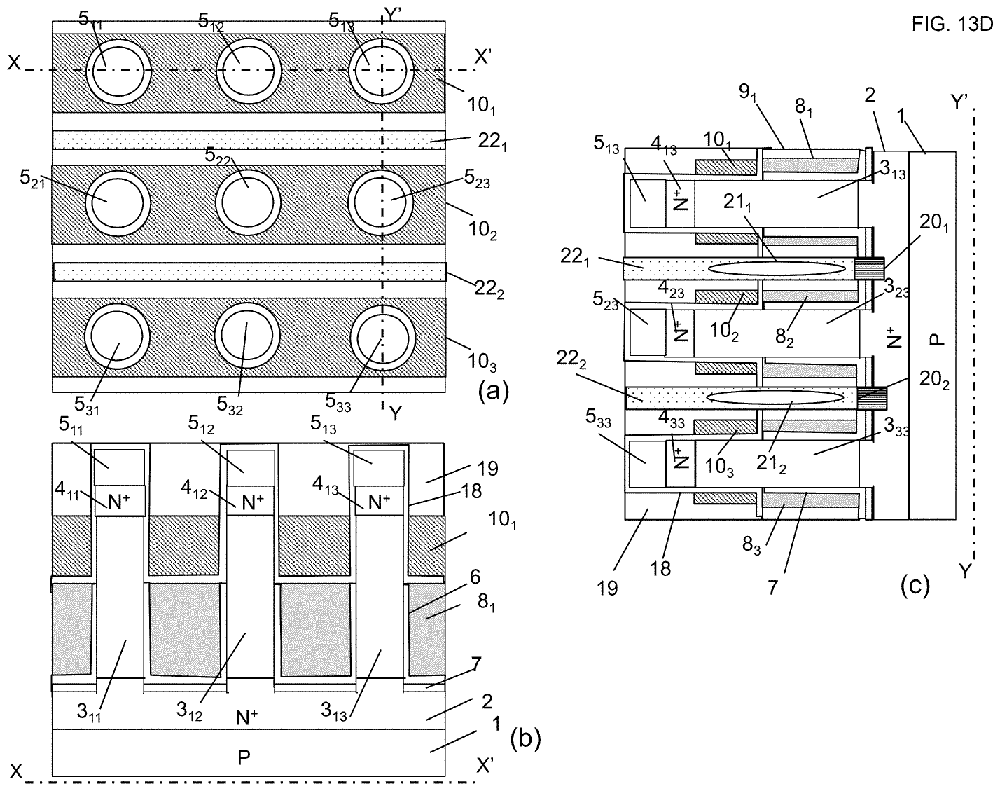

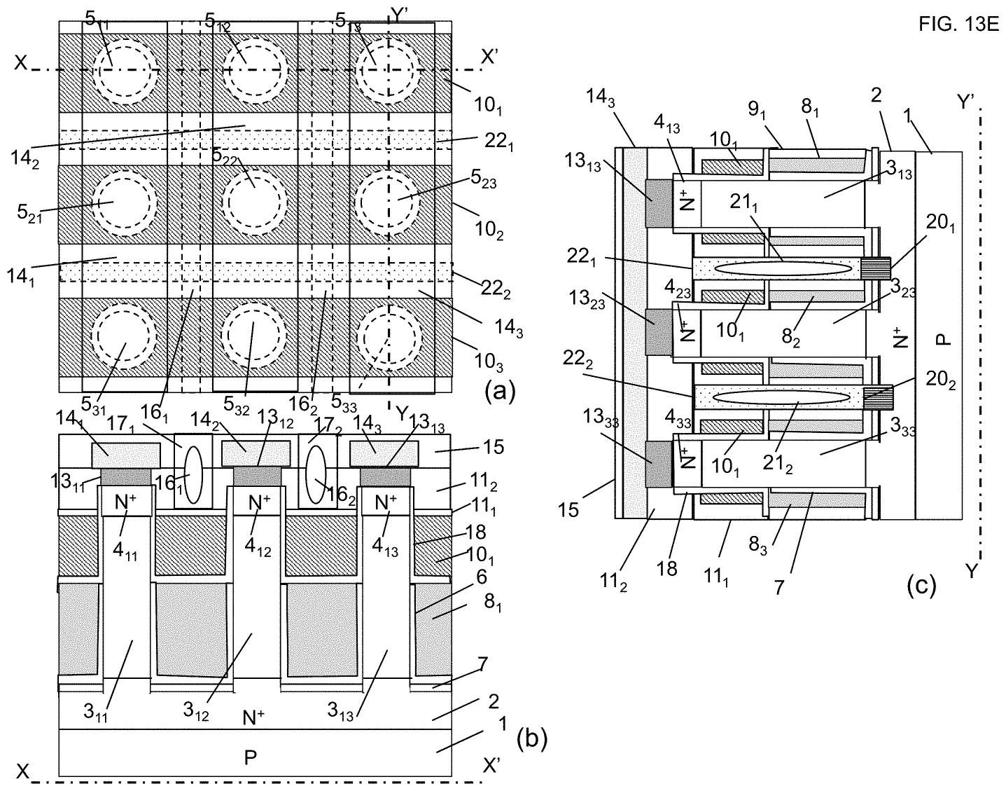

A method for manufacturing a dynamic flash memory according to a tenth embodiment will be described with reference to FIGS. 13AA to 13EC. FIGS. 13AA, 13BA, 13CA, 13DA, and 13EA are plan views, FIGS. 13AB, 13BB, 13CB, 13DB, and 13EB are vertical cross-sectional structural views taken along line X-X′ of FIGS. 13AA, 13BA, 13CA, 13DA, and 13EA, respectively, and FIGS. 13AC, 13BC, 13CC, 13DC, and 13EC are vertical cross-sectional structural views taken along line Y-Y′ of FIGS. 13AA, 13BA, 13CA, 13DA, and 13EA, respectively. This embodiment describes the formation of a memory cell region composed of nine memory cells arranged in a matrix of three rows and three columns. In an actual memory device, a plurality of dynamic flash memory cells are not necessarily arranged in a matrix of three rows and three columns but are two-dimensionally formed. In FIGS. 13AA to 13EC, components that are the same as or similar to those in FIGS. 7AA to 7MC are denoted by the same reference numerals.

The steps illustrated in FIGS. 7AA to 7FC are performed. Then, as illustrated in FIGS. 13AA to 13AC, after a SiO₂ layer 7 is formed, the entirety is coated with a HfO₂ layer 6 by, for example, the ALD method. Then, TiN layers 8₁, 8₂, and 8₃, which are first gate conductor layers, are formed so as to surround the HfO₂ layer 6 and extend in the direction of line X-X′ in the same manner as that illustrated in FIGS. 7HA to 7HC.

Then, as illustrated in FIGS. 13BA to 13BC, a SiO₂ layer 91 is formed on the outer periphery portions of the TiN layers 8₁, 8₂, and 8₃. Then, the entire portions of the HfO₂ layer 6 above the upper ends of the TiN layers 8₁, 8₂, and 8₃ are removed to form a HfO₂ layer 6₁, which is a second gate insulating layer. Then, the entirety is coated with a HfO₂ layer 18. Then, as in the step illustrated in FIGS. 7JA to 7JC, TiN layers 10₁, 10₂, and 10₃, which are second gate conductor layers, are formed so as to extend in the direction of line X-X′. Before the formation of the HfO₂ layer 18, cleaning reduces the thickness of the portions of the Si pillars 3₁₁ to 3₃₃ above the upper end of the HfO₂ layer 61 of the Si pillars 3₁₁ to 3₃₃. Alternatively, after the exposed surfaces of the Si pillars 3₁₁ to 3₃₃ are oxidized to form a thin oxide film, a step of removing the thin oxide film may be performed.

Then, as illustrated in FIGS. 13CA to 13CC, a SiO₂ layer 19 whose upper surface is positioned at the upper surfaces of the mask material layers 5₁₁ to 5₃₃ is formed using a CVD (Chemical Vapor Deposition) method and a CMP (Chemical Mechanical Polish) method. Then, contact holes 19₁ and 19₂ extending in the direction of line X-X′ between the TiN layers 8₁, 8₂, and 8₃ in plan view are formed in the N⁺ layer 2.

Then, as illustrated in FIGS. 13DA to 13DC, W layers 20₁ and 20₂ are formed at the bottom portions of the contact holes 19₁ and 19₂ so as to be in contact with the N⁺ layer 2. Then, SiO₂ layers 22₁ and 2₂₂ including voids 21₁ and 21₂ extending in the direction of X-X′ are formed on top of the W layers 20₁ and 20₂. The W layers 20₁ and 20₂ may not necessarily be formed.

Then, steps similar to those illustrated in FIGS. 71A to 7KC are performed to form, as illustrated in FIGS. 13EA to 13EC, a SiO₂ layer 111 surrounding the TiN layers 101, 10₂, and 10₃ and a SiO₂ layer 11₂ covering the N⁺ layers 4₁₁ to 4₃₃. Then, W layers 13₁₁ to 13₃₃ are formed on top of the N⁺ layers 4₁₁ to 4₃₃. Then, for example, Cu layers 14₁, 14₂, and 14₃ serving as the bit lines BL are formed by a damascene method. A SiO₂ layer 15 is formed on the outer periphery portions of the Cu layers 14₁, 14₂, and 14₃. Then, insulating layers 17₁ and 17₂ are formed between the Cu layers 14₁, 14₂, and 14₃ in plan view so as to extend in the direction of Y-Y′. The insulating layers 17₁ and 17₂ includes voids 16₁ and 16₂ between the side surfaces of the N⁺ layers 4₁₁ to 4₃₃, the W layers 13₁₁ to 13₃₃, and the Cu layers 14₁, 14₂, and 14₃. As a result, a dynamic flash memory cell is formed on the P-layer substrate 1.

The SiO₂ layers 22₁ and 22₂ including the voids 2₁₁ and 21₂ may be formed of low-dielectric-constant material layers not including the voids 2₁₁ and 2₁₂. Alternatively, the SiO₂ layers 22₁ and 22₂ may be formed of other insulating material layers.

The upper ends of the voids 21₁ and 21₂ in the vertical direction are desirably at positions lower than the positions of the upper ends of the TiN layers 10₁, 10₂, and 10₃ corresponding to the second gate conductor layers. Alternatively, the upper ends of the voids 21₁ and 21₂ in the vertical direction may be at positions lower than the positions of the upper ends of the TiN layers 8₁, 8₂, and 8₃ corresponding to the first gate conductor layers.

The voids 16₁ and 16₂ may be formed so as to face the side surface of any one layer or two continuous layers among the W layers 13₁₁ to 13₃₃ and the Cu layers 14₁ to 14₃.

This embodiment has the following features.

### (Feature 1)

In the fourth embodiment, as illustrated in FIGS. 7GA to 7JC, the HfO₂ layers 6₁₁ to 6₃₃ serving as gate insulating layers are formed so as to be connected between the N⁺ layers 4₁₁ to 4₃₃ at the top portions of the Si pillars 3₁₁ to 3₃₃ and the N⁺ layer 2 at the bottom portions of the Si pillars 3₁₁ to 3₃₃. Accordingly, the gate insulating layers of the PL-line gate TiN layers 8₁, 8₂, and 8₃ and the WL-line gate TiN layers 10₁, 10₂, and 10₃ are formed of the same HfO₂ layers 6₁₁ to 6₃₃. In this embodiment, in contrast, the PL-line gate conductor layers 8₁, 8₂, and 8₃, the WL-line gate conductor layers 10₁, 10₂, and 10₃, and the gate insulating layers 6 and 18 are separately formed. As a result, for example, the film thicknesses and the materials of the gate insulating layer 6 and the gate insulating layer 18 can be separately selected to more effectively make the capacitance C_{PL} between the PL line and the floating body larger than the capacitance C_{WL} between the WL line and the floating body. This contributes to a more stable dynamic flash memory operation.

### (Feature 2)

In the fourth embodiment, as illustrated in FIGS. 7IA to 7IC, the SiO₂ layer 9 is formed as an interlayer insulating layer between the PL-line gate TiN layers 8₁, 8₂, and 8₃ and the WL-line gate TiN layers 10₁, 10₂, and 10₃. The SiO₂ layer 9 is formed by, for example, after forming the TiN layers 8₁, 8₂, and 8₃ in FIGS. 7HA to 7HC, applying a coating of a SiO₂ layer to the entirety, polishing it by the CMP method until its upper surface is positioned at the positions of the upper surfaces of the mask material layers 5₁₁ to 5₃₃, and etching it back by RIE. In this embodiment, in contrast, as illustrated in FIGS. 13BA to 13BC, the interlayer insulating layer corresponding to the SiO₂ layer 9 is formed such that the HfO₂ layer 18 is formed as a second gate insulating layer and is also formed as an interlayer insulating layer corresponding to the SiO₂ layer 9. This simplifies the manufacturing process.

### (Feature 3)

As illustrated in FIGS. 13CA to 13CC and FIGS. 13DA to 13DC, the contact holes 19₁ and 19₂ have formed therein the voids 21₁ and 21₂ and the W layers 20₁ and 20₂. As a result, the voids 21₁ and 21₂ and the W layers 20₁ and 20₂ are formed in a self-aligned manner. The W layers 20₁ and 20₂ reduce the resistance of the region of the N⁺ layer 2 corresponding to the SL line and contributes to a more stable dynamic flash memory operation. The voids 21₁ and 21₂ can reduce the parasitic capacitance between the PL-line TiN layers 8₁, 8₂, and 8₃ and between the WL-line TiN layers 10₁, 10₂, and 10₃. The reduction in parasitic capacitance can contribute to an increase in the operation margin of the dynamic flash memory. Further, the self-aligned formation of the voids 21₁ and 21₂ and the W layers 20₁ and 20₂ contributes to the high integration of the dynamic flash memory. Instead of the W layers 20₁ and 20₂ being formed in the memory cell region, an SL-line metal wiring portion to be connected to the N⁺ layer 2 may be formed around the memory cell region. In this case, the SL-line resistance increases compared to the case where the W layers 20₁ and 20₂ are used. However, the effect of reducing the parasitic capacitance between the PL-line TiN layers 8₁, 8₂, and 8₃ and between the WL-line TiN layers 10₁, 10₂, and 10₃ remains unchanged, and no need exists to improve the accuracy of the manufacturing process for ensuring the connection of the W layers 20₁ and 20₂ to the N⁺ layer 2. As described above, it is possible to select whether to form the W layers 20₁ and 20₂ in consideration of reduction in SL-line resistance and facilitation of the manufacturing process.

### (Feature 4)

The voids 16₁ and 16₂ formed between the side surfaces of the N⁺ layers 4₁₁ to 4₃₃, the W layers 13₁₁ to 13₃₃, and the Cu layers 14₁ to 14₃ illustrated in FIGS. 13EA to 13EC can reduce the parasitic capacitance between the bit lines BL. This contributes to a more stable dynamic flash memory operation.

### Eleventh Embodiment

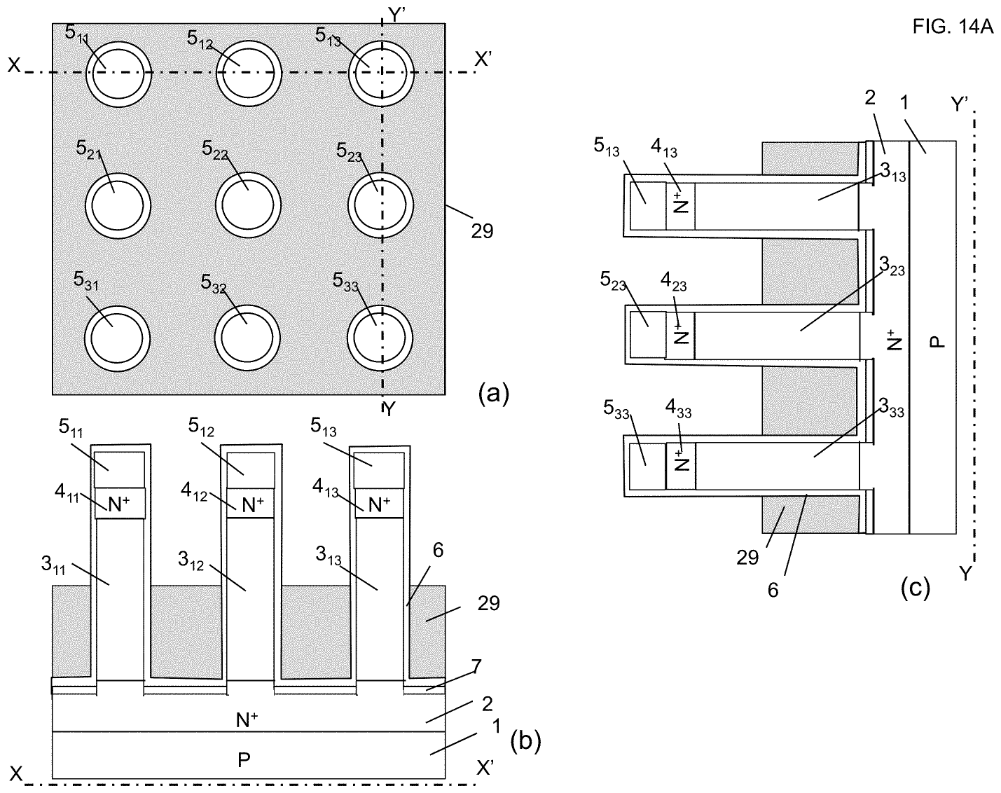

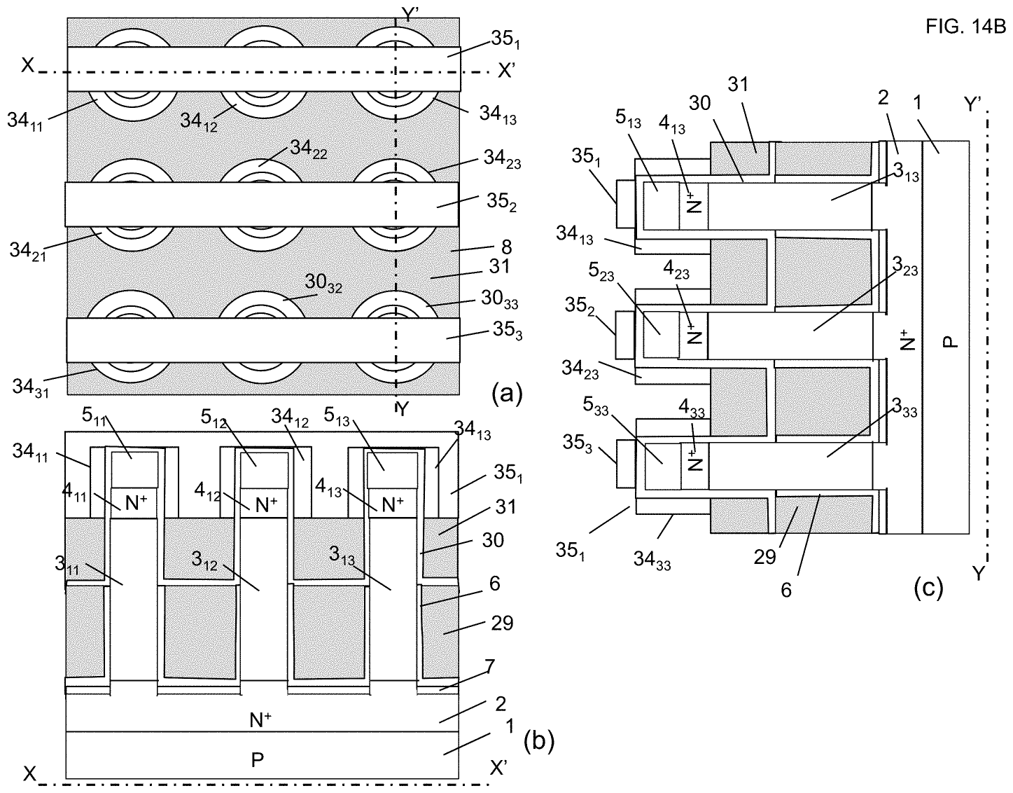

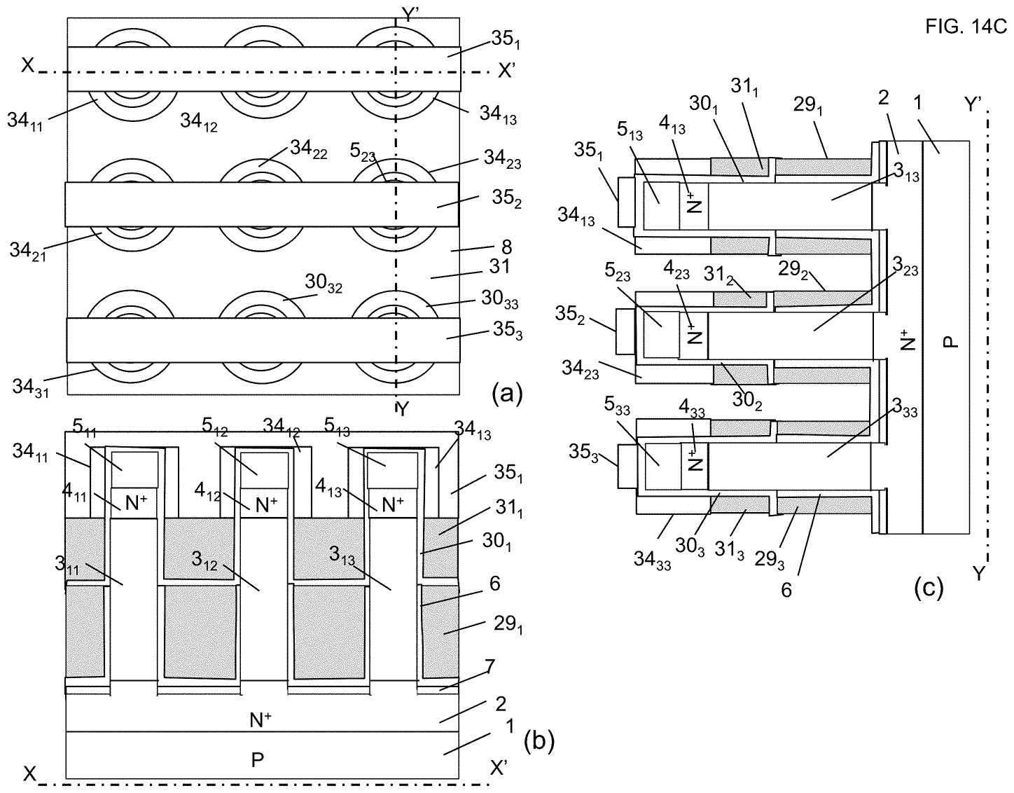

A method for manufacturing a dynamic flash memory according to an eleventh embodiment will be described with reference to FIGS. 14AA to 14CC. FIGS. 14AA, 14BA, and 14CA are plan views, FIGS. 14AB, 14BB, and 14CB are vertical cross-sectional structural views taken along line X-X′ of FIGS. 14AA, 14BA, and 14CA, respectively, and FIGS. 14AC, 14BC, and 14CC are vertical cross-sectional structural views taken along line Y-Y′ of FIGS. 14AA, 14BA, and 14CA, respectively. This embodiment describes the formation of a memory cell region composed of nine memory cells arranged in a matrix of three rows and three columns. In an actual memory device, a plurality of dynamic flash memory cells are not necessarily arranged in a matrix of three rows and three columns but are two-dimensionally formed. In FIGS. 14AA to 14CC, components that are the same as or similar to those in FIGS. 7AA to 7MC or FIGS. 13AA to 13EC are denoted by the same reference numerals.

The steps before the TiN layers 8₁, 8₂, and 8₃ illustrated in FIGS. 13AA to 13AC are formed are performed to form, as illustrated in FIGS. 14AA to 14AC, a TiN layer 29 (an example of a “first conductor layer” in the claims) that surrounds the Si pillars 3₁₁ to 3₃₃ and is continuous.

Then, as illustrated in FIGS. 14BA to 14BC, the entirety is covered to form a HfO₂ layer 30 (an example of a “second gate insulating layer” in the claims). Then, the HfO₂ layer 30 is covered to form a TiN layer 31 (an example of a “second conductor layer” in the claims) having an upper surface positioned near the lower ends of the N⁺ layers 4₁₁ to 4₃₃ in the vertical direction. The TiN layer 31 is formed so as to surround the Si pillars 3₁₁ to 3₃₃ and so as to be continuous in the same manner as the TiN layer 29. Then, the entirety is coated with a SiN layer (not illustrated) by the CVD method. Then, the SiN layer is etched by the RIE method to form SiN layers 34₁₁ to 34₃₃ (an example of a “second mask material layer” in the claims) surrounding the side surfaces of the N⁺ layers 4₁₁ to 4₃₃ and the mask material layers 5₁₁ to 5₃₃. In this case, the SiN layers 34₁₁ to 34₃₃ are formed in self-alignment with the N⁺ layers 4₁₁ to 4₃₃ and the mask material layers 5₁₁ to 5₃₃. Then, a mask material layer 3₅₁ (an example of a “third mask material layer” in the claims) connected to the Si pillars 3₁₁ to 3₃₃ and extending in the direction of line X-X′ (an example of a “first direction” in the claims) in plan view, a mask material layer 35₂ connected to the Si pillars 3₂₁ to 3₂₃, and a mask material layer 3₅₃ connected to the Si pillars 3₃₁ to 3₃₃ are formed. The SiN layers 34₁₁ to 34₃₃ may be formed of other materials functioning as an etching mask material layer. The mask material layers 35₁, 35₂, and 35₃ are desirably formed so as to be located inside the outer peripheral edges of the SiN layers 34₁₁ to 34₃₃ in the direction of Y-Y′ (an example of a “second direction” in the claims).

Then, as illustrated in FIGS. 14CA to 14CC, the TiN layer 31, the HfO₂ layer 30, and the TiN layer 29 are etched by the RIE method by using the SiN layers 34₁₁ to 34₃₃, the mask material layer 35₁, the mask material layer 35₂, and the mask material layer 35₃ as a mask to form TiN layers 29₁, 29₂, and 29₃, HfO₂ layers 30₁, 30₂, and 30₃, and TiN layers 31₁, 31₂, and 313 extending in the direction of X-X′. Then, the steps illustrated in FIGS. 13CA to 13EC are performed to form a dynamic flash memory on top of the P-layer substrate 1.

The Si pillars 3₁₁ to 3₃₃ can be arranged in close proximity to each other in the direction of line X-X′ in plan view such that adjacent SiN layers among the SiN layers 34₁₁ to 34₃₃ are connected to each other to form TiN layers 31₁, 31₂, and 31₃, which continuously extend in the direction of line X-X′, without forming the mask material layers 35₁, 35₂, and 35₃.

In FIGS. 14AA to 14AC and FIGS. 14BA to 14BC, a low-resistance material layer made of doped poly-Si or the like containing a large amount of donor or accepter impurity may be used instead of the TiN layer 29. Alternatively, instead of the TiN layer 29, a multi-layer structure having a thin TiN layer and a doped poly-Si layer stacked on top of the thin TiN layer may be used. This also applies to the formation of the TiN layer 31. When a doped poly-Si layer is used, the upper surface of the doped poly-Si layer may be oxidized to form an oxide insulating layer, which insulates the TiN layer 29 from the TiN layer 31. This oxidization process is performed after the upper portions of the Si pillars 3₂₁ to 3₂₃ above the SiO₂ layer 6 are exposed to form a gate HfO₂ insulating layer. At the same time, an insulating layer between the first and second gate conductor layers can be formed. After the gate SiO₂ insulating layer is formed, the HfO₂ layer 30 may be formed by the ALD method.

This embodiment has the following features.

### (Feature 1)

In this embodiment, the TiN layer 31, the HfO₂ layer 30, and the TiN layer 29 are etched by the RIE method by using the SiN layers 34₁₁ to 34₃₃ and the mask material layers 35₁, 35₂, and 35₃, which are formed in self-alignment with the Si pillars 3₁₁ to 33₃, as a mask to form the TiN layers 29₁, 29₂, and 293, the HfO₂ layers 30₁, 30₂, and 30₃, and the TiN layers 31₁, 31₂, and 31₃ extending in the direction of X-X′. In this case, since the SiN layers 34₁₁ to 34₃₃ are formed in self-alignment with the Si pillars 3₁₁ to 33₃, the TiN layers 29₁, 29₂, and 29₃ connected to the plate lines PL and the TiN layer 31₁, 31₂, and 31₃ connected to the word lines WL are formed so as to have predetermined work functions and uniform thicknesses. As a result, the variations in the characteristics of the dynamic flash memory cells formed at the Si pillars 3₁₁ to 3₃₃ can be suppressed, and, at the same time, high integration can be achieved.

### (Feature 2)

The mask material layers 35₁, 35₂, and 35₃ are formed so as to be located inside the outer peripheral edges of the SiN layers 34₁₁ to 34₃₃ in the direction of Y-Y′, which allows the SiN layers 34₁₁ to 34₃₃ in portions formed in self-alignment with the Si pillars 3₁₁ to 3₃₃ to be formed between the TiN layers 31₁, 31₂, and 31₃ in the direction of Y-Y′. As a result, a high density of dynamic flash memory cells in the direction of Y-Y′ can be achieved.

### (Feature 3)

The Si pillars 3₁₁ to 3₃₃ can be arranged in close proximity to each other in the direction of line X-X′ in plan view such that adjacent SiN layers among the SiN layers 34₁₁ to 34₃₃ are connected to each other to form TiN layers 31₁, 31₂, and 31₃, which continuously extend in the direction of line X-X′, without forming the mask material layers 35₁, 35₂, and 35₃. As a result, a high density of dynamic flash memory cells in the direction of X-X′ can be achieved.

### Twelfth Embodiment

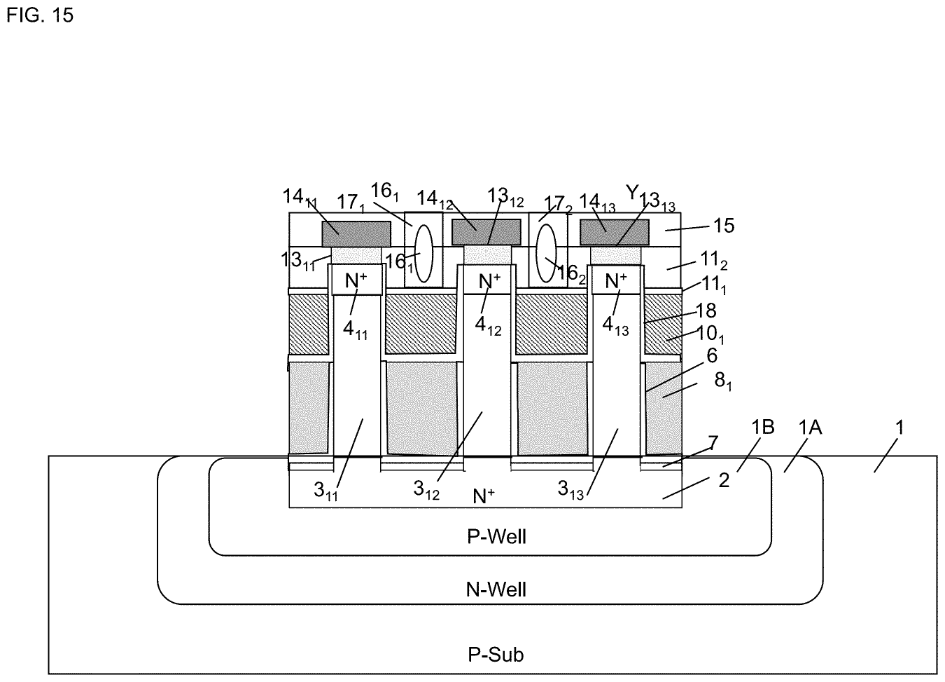

A method for manufacturing a two-layer well structure to be disposed in a P-layer substrate 1 of a dynamic flash memory according to a twelfth embodiment will be described with reference to FIG. 15.

In FIG. 15, for example, phosphorus P and arsenic As are ion-implanted into the P-layer substrate 1 to form an N-well layer 1A. Then, for example, boron B is ion-implanted into the N-well layer 1A to form a P-well layer 1B. This two-layer well structure is a measure for enabling the application of a negative bias to the source line SL when the dynamic flash memory of the present application is in erase operation. The two-layer well structure described above prevents the negative bias of the source line SL from affecting PN junctions and transistor circuits in other peripheral circuits.

Then, the steps illustrated in FIGS. 7BA to 7FC and the steps illustrated in FIGS. 13AA to 13EC are performed.

This embodiment has the following features.

In the erase operation of the dynamic flash memory of the present application, the source line SL is negatively biased. The two-layer well structure in the P-layer substrate 1 in the memory cell region can shield other circuits from the negative bias.

### Other Embodiments

While a Si pillar is formed in the present invention, a semiconductor pillar composed of any other semiconductor material may be used. The same applies to the other embodiments according to the present invention.

In the first embodiment, the N⁺ layers 101a and 101b serving as the source and the drain may be formed of layers made of Si containing a donor impurity or any other semiconductor material. The N⁺ layers 101a and 101b serving as the source and the drain may be formed of different semiconductor material layers. The same applies to the other embodiments according to the present invention.

The N⁺ layers 4₁₁ to 4₃₃, which are formed at the top portions of the Si pillars 3₁₁ to 33₃, according to the fourth embodiment are implemented using the N⁺ layer 4 formed on the upper portion of the P layer 3 by epitaxial crystal growth. Alternatively, the N⁺ layers 4₁₁ to 4₃₃ may be formed after the TiN layers 10₁, 10₂, and 10₃ are formed. Likewise, after the Si pillars 3₁₁ to 3₃₃ are formed, the N⁺ layer 2 to be connected to the bottom portions of the Si pillars 3₁₁ to 3₃₃ may be formed by, for example, an ion implantation method or any other method. The same applies to the other embodiments according to the present invention.

In the fourth embodiment, furthermore, as illustrated in FIGS. 7GA to 7GC, the hafnium oxide (HfO₂) layers 6₁₁ to 6₃₃ serving as gate insulating layers are formed so as to surround the Si pillars 3₁₁ to 3₃₃. Alternatively, other material layers including an organic material or an inorganic material composed of a single layer or a plurality of layers may be used as long as the material meets the object of the present invention. The same applies to the other embodiments according to the present invention.

In the fourth embodiment, furthermore, as illustrated in FIGS. 7EA to 7EC, a mask material layer is deposited on the upper portion of the N⁺ layer 4, and the patterned mask material layers 5₁₁ to 5₃₃ are left in the regions where the Si pillars are to be formed. Alternatively, the mask material layer may be a SiO₂ layer, an aluminum oxide (Al₂O₃, AlO) layer, a SiO₂ layer, or any other material layer including an organic material or an inorganic material composed of a single layer or a plurality of layers as long as the material meets the object of the present invention. The same applies to the other embodiments according to the present invention.

In the fourth embodiment, furthermore, the mask material layers 5₁₁ to 5₃₃ are formed such that the upper surfaces and the bottom portions thereof are located at the same positions in the vertical direction. Alternatively, the upper surfaces and the bottom portions of the mask material layers 5₁₁ to 5₃₃ may be located at different positions in the vertical direction as long as the object of the present invention is met. The same applies to the other embodiments according to the present invention.

In the fourth embodiment, furthermore, the thickness and shape of the mask material layers 5₁₁ to 5₃₃ are changed by polishing by CMP, RIE etching, and cleaning. This change causes no problem as long as the object of the present invention is met. The same applies to the other embodiments according to the present invention.

In the fourth embodiment, furthermore, the material of the various wiring metal layers WL, PL, BL, and SL may be not only metal but also a conductive material such as an alloy or a semiconductor material containing a large amount of acceptor or donor impurity, and may be formed as a single layer or a combination of a plurality of layers of such materials. The same applies to the other embodiments according to the present invention.

In the fourth embodiment, furthermore, a TiN layer is used as a gate conductor layer. The TiN layer may be a material layer composed of a single layer or a plurality of layers as long as the material meets the object of the present invention. The TiN layer can be formed of a conductor layer such as a single metal layer or a plurality of metal layers having at least a desired work function. Another conductive layer such as a W layer may be formed outside the TiN layer, for example. In this case, the W layer serves as a metal wiring layer connecting the gate metal layers. Instead of the W layer, a single metal layer or a plurality of metal layers may be used. Further, the hafnium oxide (HfO₂) layers 6₁₁ to 6₃₃ serving as gate insulating layers, which are formed so as to surround the Si pillars 3₁₁ to 3₃₃ as the gate insulating layers, may be other material layers each composed of a single layer or a plurality of layers. The same applies to the other embodiments according to the present invention.

In the fourth embodiment, each of the Si pillars 3₁₁ to 3₃₃ has a circular shape in plan view. The shape of some or all of the Si pillars 3₁₁ to 3₃₃ in plan view may be a circle, an ellipse, a shape elongated in one direction, or the like. Also in a logic circuit region formed away from the dynamic flash memory cell region, Si pillars having different shapes in plan view can be formed in a mixed manner in the logic circuit region in accordance with the logic circuit design. The same applies to the other embodiments according to the present invention.

In the fourth embodiment, after the Si pillars 3₁₁ to 3₃₃ are formed in FIGS. 7FA to 7FC, an alloy layer of metal, silicide, and the like may be formed on the upper surface of the N⁺ layer 2 along the outer periphery portions of the Si pillars 3₁₁ to 3₃₃. Alternatively, a metal layer or an alloy layer extending in one direction may be disposed in contact with the N⁺ layer 2. The N⁺ layer 2 may be separated into, for example, an N⁺ layer for the Si pillars 3₁₁, 3₂₁, and 3₃₁, an N⁺ layer for the Si pillars 3₁₂, 3₂₂, and 3₃₂, and an N⁺ layer for the Si pillars 3₁₃, 3₂₃, and 3₃₃ by, for example, STI (Shallow Trench Isolation). In this case, the N⁺ layer at the bottom portions of the Si pillars 3₁₁, 3₂₁, and 3₃₁, the N⁺ layer at the bottom portions of the Si pillars 3₁₂, 3₂₂, and 3₃₂, and the N⁺ layer at the bottom portions of the Si pillars 3₁₃, 3₂₃, and 3₃₃ can be driven independently. In this case, it is necessary to form a low-resistance metal or alloy layer to be connected to these N⁺ layers. The same applies to the other embodiments according to the present invention.

In the fourth embodiment, dynamic flash memory cells are formed on top of the P-layer substrate 1. Alternatively, an SOI (Silicon On Insulator) substrate may be used instead of the P-layer substrate 1. Alternatively, a substrate formed of any other material functioning as a substrate may be used. The same applies to the other embodiments according to the present invention.

The first embodiment describes a dynamic flash memory cell in which the N⁺ layers 101a and 101b having conductivity of the same polarity are provided in the upper and lower portions of the Si pillar 100 to form the source and the drain. The present invention is also applicable to a tunnel device including a source and a drain having different polarities. The same applies to the other embodiments according to the present invention.

In the fourth embodiment, as illustrated in FIGS. 7FA to 7FC, after the N⁺ layers 4₁₁ to 4₃₃ are formed, the hafnium oxide (HfO₂) layers 6₁₁ to 6₃₃ serving as gate insulating layers are formed so as to surround the Si pillars 3₁₁ to 33₃, a TiN layer is etched by the RIE method to form the TiN layers 8₁, 8₂, and 8₃, which are first gate conductor layers, and a TiN layer is etched by the RIE method to form the TiN layers 10₁, 10₂, and 10₃, which are second gate conductor layers. Alternatively, the N⁺ layers 4₁₁ to 4₃₃ may be formed after the HfO₂ layers 6₁₁ to 6₃₃ serving as gate insulating layers are formed so as to surround the Si pillars 3₁₁ to 33₃, a TiN layer is etched by the RIE method to form the TiN layers 8₁, 8₂, and 8₃, which are first gate conductor layers, and the TiN layers 10₁, 10₂, and 10₃, which are second gate conductor layers, are formed. The same applies to the other embodiments according to the present invention.

In the fourth embodiment, as illustrated in FIGS. 7CA to 7CC, the P layer 3 is formed by epitaxial growth. Alternatively, after a thin single-crystal Si layer is formed by the ALD method, a P⁺ layer containing an acceptor impurity may be formed by epitaxial crystal growth. The thin single-crystal Si layer is a material layer for obtaining the P layer 3 having good crystallinity. Any other single material layer or a plurality of material layers for obtaining the P layer 3 having good crystallinity may be used.

While a HfO₂ layer is used as a gate insulating layer in the fourth embodiment, any other material layer composed of a single layer or a plurality of layers may be used. The same applies to the other embodiments according to the present invention.

In the first embodiment and the fifth embodiment, at the time of the erase operation, the source line SL is negatively biased to extract the positive holes in the floating body FB. The erase operation may be performed with the bit line BL negatively biased instead of the source line SL or with the source line SL and the bit line BL negatively biased. The same applies to the other embodiments according to the present invention.

Further, in FIGS. 7AA to 7MC and FIGS. 13AA to 13EC, the Si pillars 3₁₁ to 3₃₃ are arranged in a square lattice in plan view. Alternatively, the Si pillars 3₁₁ to 3₃₃ may be arranged in an orthorhombic lattice. The same applies to the other embodiments according to the present invention.

In FIGS. 13DA to 13DC, the W layers 20₁ and 20₂ are disposed in contact with the N⁺ layer 2. Alternatively, the W layers are not disposed adjacent to the Si pillars 3₁₁ to 3₃₃, but may be disposed outside a region where the plurality of Si pillars are disposed in plan view. The same applies to the other embodiments according to the present invention.

Various embodiments and modifications can be made to the present invention without departing from the broad spirit and scope of the present invention. The embodiments described above are for explaining an example of the present invention, and do not limit the scope of the present invention. The embodiments and modifications described above can be combined as desired. Some of the components may be removed as necessary from the embodiments described above to form other embodiments within scope of the technical idea of the present invention.

### INDUSTRIAL APPLICABILITY

A method for manufacturing a memory device using an SGT according to the present invention provides a high-density and high-performance memory device, or dynamic flash memory.

1. A method for manufacturing a memory device using a semiconductor element, the memory device being configured to control voltages to be applied to a first gate conductor layer, a second gate conductor layer, a first impurity layer, and a second impurity layer to perform a data write operation, a data read operation, and a data erase operation, the method comprising the steps of:
forming a first mask material layer on top of a semiconductor layer;
etching the semiconductor layer by using the first mask material layer as a mask to form a first semiconductor pillar standing in a vertical direction;
forming a first gate insulating layer surrounding a side surface of the first semiconductor pillar;
forming the first gate conductor layer, the first gate conductor layer surrounding a side surface of the first gate insulating layer and having an upper surface positioned below a top portion of the first semiconductor pillar;
forming a second gate insulating layer connected to the first gate insulating layer and surrounding an upper side surface of the first semiconductor pillar;
forming the second gate conductor layer so as to surround a side surface of the second gate insulating layer;
forming the first impurity layer before or after forming the first semiconductor pillar such that the first impurity layer is connected to a bottom portion of the first semiconductor pillar; and
forming the second impurity layer at the top portion of the first semiconductor pillar before or after forming the first semiconductor pillar.

2. The method for manufacturing a memory device according to claim 1, further comprising the steps of:
forming a third insulating layer so as to surround the first semiconductor pillar;
forming the first gate conductor layer such that the first gate conductor layer surrounds the third insulating layer in a lower portion of the first semiconductor pillar;
forming a fourth insulating layer surrounding the first gate conductor layer and having an upper end surface located above the first gate conductor layer; and
forming the second gate conductor layer such that the second gate conductor layer surrounds the third insulating layer in an upper portion of the first semiconductor pillar, wherein
portion of the third insulating layer that is surrounded by the first gate conductor layer comprises the first gate insulating layer, and a portion of the third insulating layer that is surrounded by the second gate conductor layer comprises the second gate insulating layer.

3. The method for manufacturing a memory device according to claim 1, further comprising the step of:
after forming the first gate conductor layer, forming the second gate insulating layer such that the second gate insulating layer surrounds an exposed portion of the first semiconductor pillar above the upper surface of the first gate conductor layer in the vertical direction and is connected to the upper surface of the first gate conductor layer.

4. The method for manufacturing a memory device according to claim 1, further comprising the steps of:
forming the first gate insulating layer and a first conductor layer surrounding the first gate insulating layer;
forming the second gate insulating layer so as to surround an upper surface of the first conductor layer and a portion of the first semiconductor pillar above the first conductor layer;
forming a second conductor layer surrounding the side surface of the second gate insulating layer and having an upper surface positioned near a lower end of the second impurity layer;
forming a second mask material layer surrounding side surfaces of the second impurity layer and the first mask material layer; and
etching the second conductor layer, the second gate insulating layer, and the first conductor layer by using the first mask material layer and the second mask material layer as a mask, wherein
the etched first conductor layer serves as the first gate conductor layer, and the etched second conductor layer serves as the second gate conductor layer.

5. The method for manufacturing a memory device according to claim 4, further comprising the step of:
oxidizing a surface layer of the first conductor layer to form a first oxide layer.

6. The method for manufacturing a memory device according to claim 4, further comprising the steps of:
after forming the first conductor layer, exposing the side surface of the first semiconductor pillar; and
oxidizing a surface layer of the first conductor layer to form a first oxide layer, and simultaneously oxidizing the exposed surface layer of the first semiconductor pillar to form a second oxide layer.

7. The method for manufacturing a memory device according to claim 6, further comprising the step of:
after forming the first oxide layer and the second oxide layer, forming a fifth insulating layer covering the first oxide layer and the second oxide layer, wherein
the second gate insulating layer is formed of the second oxide layer and the fifth insulating layer.

8. The method for manufacturing a memory device according to claim 4, further comprising the steps of:
forming a third mask material layer such that the third mask material layer is laid on top of the second mask material layer in plan view and extends in a first direction in plan view; and
etching the second conductor layer, the second gate insulating layer, and the first conductor layer by using the first mask material layer, the second mask material layer, and the third mask material layer as a mask.

9. The method for manufacturing a memory device according to claim 8, wherein
the third mask material layer has an outer periphery that is located inside an outer periphery of the second mask material layer in a second direction perpendicular to the first direction in plan view.

10. The method for manufacturing a memory device according to claim 1, further comprising the steps of:
after forming the second gate conductor layer, forming a sixth insulating layer surrounding side surfaces of the second impurity layer and the first mask material layer;
etching the first mask material layer by using the sixth insulating layer as a mask to form a first contact hole in an upper surface of the second impurity layer; and
forming a first wiring conductor layer connected to an upper surface of the sixth insulating layer and the second impurity layer through the first contact hole.

11. The method for manufacturing a memory device according to claim 10, wherein
the first wiring conductor layer is formed to be perpendicular to the second gate conductor layer in plan view.

12. The method for manufacturing a memory device according to claim 1, further comprising the steps of:
forming a second contact hole such that the second contact hole is adjacent to the first gate conductor layer and the second gate conductor layer in plan view, extends in parallel to the first gate conductor layer and the second gate conductor layer in plan view, and has a bottom portion in contact with the first impurity layer; and
forming a third conductor layer at the bottom portion of the second contact hole.

13. The method for manufacturing a memory device according to claim 12, further comprising the step of:
forming a seventh insulating layer in the second contact hole on top of the third conductor layer, the seventh insulating layer having or not having a void.

14. The method for manufacturing a memory device according to claim 13, wherein
the seventh insulating layer comprises a low-dielectric-constant material layer.

15. The method for manufacturing a memory device according to claim 10, further comprising the steps of:
forming an eighth insulating layer surrounding side surfaces of the second impurity layer and the first wiring conductor layer;
forming a third contact hole in the eighth insulating layer so as to be adjacent to the second impurity layer and the first wiring conductor layer; and
forming a ninth insulating layer in the third contact hole, the ninth insulating layer having or not having a void.

16. The method for manufacturing a memory device according to claim 15, wherein
the eighth insulating layer comprises a low-dielectric-constant material layer.

17. The method for manufacturing a memory device according to claim 1, wherein
the first gate conductor layer and the second gate conductor layer are formed such that one of the first gate conductor layer and the second gate conductor layer is connected to a plate line and the other of the first gate conductor layer and the second gate conductor layer is connected to a word line.

18. The method for manufacturing a memory device according to claim 1, wherein
the first gate conductor layer, the second gate conductor layer, the first impurity layer, and the second impurity layer are formed so that the voltages to be applied to the first gate conductor layer, the second gate conductor layer, the first impurity layer, and the second impurity layer are controlled to perform the data write operation for holding, in the first semiconductor pillar, positive holes or electrons serving as majority carriers in the first semiconductor pillar, the positive holes or electrons being generated by an impact ionization phenomenon or a gate induced drain leakage current, and to perform the data erase operation for discharging, from within the first semiconductor pillar, the positive holes or electrons serving as majority carriers in the first semiconductor pillar.
